(19) United States
(12) Patent Application Publication
(10) Pub. No.: US 2024/0258371 A1
(43) Pub. Date: Aug. 1, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventors: Nobuyuki OTSUBO, Kyoto (JP); Kosaku ADACHI, Kyoto (JP)

(73) Assignee: ROHM CO., LTD., Kyoto (JP)

(21) Appl. No.: 18/403,162

(22) Filed: Jan. 3, 2024

(30) Foreign Application Priority Data
Jan. 31, 2023 (JP) 2023-013048
Feb. 9, 2023 (JP) 2023-018722
Dec. 11, 2023 (JP) 2023-208723

(51) Int. Cl. H01L 29/06; H01L 21/764

(52) U.S. Cl. CPC H01L 29/0649; H01L 21/764

(57) ABSTRACT

A semiconductor device includes a semiconductor chip that has a first principal surface and a second principal surface located on a side opposite to a side of the first principal surface and an element isolation portion that is formed on the side of the first principal surface of the semiconductor chip and that demarcates an active region. The element isolation portion includes a trench formed on the side of the first principal surface of the semiconductor chip, a first insulating film formed on a side surface of the trench, a second insulating film formed inside the trench inwardly from the first insulating film with an air gap between the first insulating film and the second insulating film, and a buried conductor that is covered by the second insulating film and that is connected to the semiconductor chip at a bottom portion of the trench.

### RELATED APPLICATIONS

This application corresponds to Japanese Patent Application No. 2023-13048 filed in the Japan Patent Office on Jan. 31, 2023, Japanese Patent Application No. 2023-18722 filed in the Japan Patent Office on Feb. 9, 2023, and Japanese Patent Application No. 2023-208723 filed in the Japan Patent Office on Dec. 11, 2023, the entire disclosures of which are incorporated herein by reference.

### TECHNICAL FIELD

The present disclosure relates to a semiconductor device and a method of manufacturing a semiconductor device.

### BACKGROUND

Patent Literature 1 (Japanese Patent Application Publication No. 2021-002623) discloses a semiconductor device provided with a region isolation structure including a DTI (deep trench isolation) structure.

The region isolation structure includes a trench formed in a principal surface of a semiconductor chip, an insulating film covering a side surface of the trench, and polysilicon buried in the trench with the insulating film between the polysilicon and the trench. The polysilicon is electrically connected to a high concentration region of an impurity region through a bottom wall of the trench.

### BRIEF DESCRIPTION OF THE DRAWINGS

FIG. 1 is a schematic plan view of a semiconductor device according to a first embodiment of the present disclosure.

FIG. 2 is an enlarged view of region II shown in FIG. 1.

FIG. 3 is a view showing cross section III-III shown in FIG. 2.

FIG. 4 is a cross-sectional enlarged view of a main portion of a structure shown in FIG. 3.

FIG. 5A to FIG. 5M correspond to FIG. 4, and are views showing a part of a process of manufacturing a semiconductor device according to a first embodiment of the present disclosure.

FIG. 6 corresponds to FIG. 4, and is a cross-sectional enlarged view of a main portion of a semiconductor device according to a second embodiment of the present disclosure.

FIG. 7A to FIG. 7D correspond to FIG. 6, and are views showing a part of a process of manufacturing the semiconductor device according to the second embodiment of the present disclosure.

FIG. 8 corresponds to FIG. 4, and is a cross-sectional view shown to describe a first modification of the present disclosure.

FIG. 9 is a plan view shown to describe a second modification of the present disclosure.

FIG. 10 is a schematic plan view of a semiconductor device according to a third embodiment of the present disclosure.

FIG. 11 is an enlarged view of region XI shown in FIG. 10.

FIG. 12 is a view showing cross section XII-XII shown in FIG. 11.

FIG. 13 is a cross-sectional enlarged view of a main portion of a structure shown in FIG. 12.

FIG. 14A to FIG. 14M correspond to FIG. 13, and are views showing a part of a process of manufacturing the semiconductor device according to the third embodiment of the present disclosure.

FIG. 15 corresponds to FIG. 13, and is a cross-sectional enlarged view of a main portion of a semiconductor device according to a fourth embodiment of the present disclosure.

FIG. 16 corresponds to FIG. 13, and is a cross-sectional enlarged view of a main portion of a semiconductor device according to a fifth embodiment of the present disclosure.

FIG. 17A to FIG. 17I correspond to FIG. 16, and are views showing apart of a process of manufacturing the semiconductor device according to the fifth embodiment of the present disclosure.

FIG. 18 is a cross-sectional view shown to describe a first modification that is a modification of a second insulating film of the present disclosure.

FIG. 19 is a plan view shown to describe a second modification that is a modification of an element isolation portion of the present disclosure.

FIG. 20 is a view showing cross section XX-XX shown in FIG. 19.

FIG. 21 is a plan view shown to describe a third modification that is a modification of the element isolation portion of the present disclosure.

FIG. 22 is a view showing cross section XXII-XXII shown in FIG. 21.

### DESCRIPTION OF EMBODIMENTS

### First and Second Preferred Embodiments

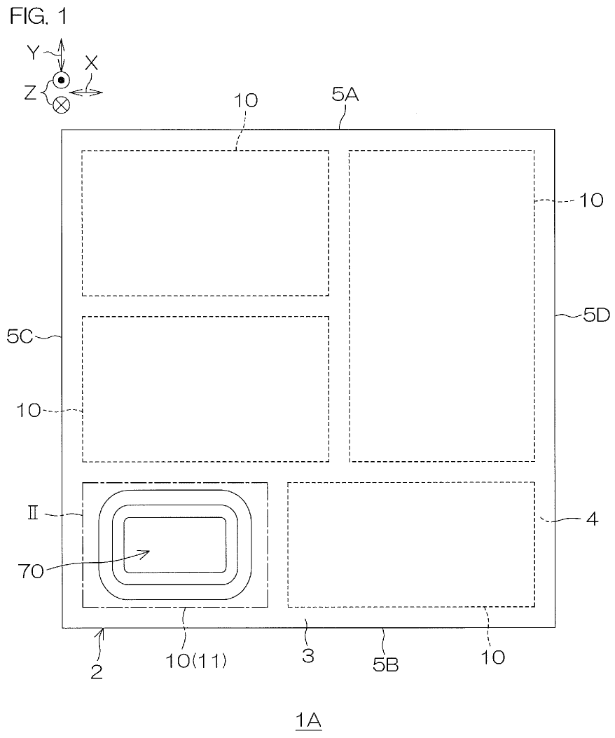

FIG. 1 is a schematic plan view of a semiconductor device 1A according to a first embodiment of the present disclosure.

Referring to FIG. 1, the semiconductor device 1A includes a rectangular parallelepiped shaped semiconductor chip 2. In this embodiment, the semiconductor chip 2 is made of a Si (silicon) chip. The semiconductor chip 2 has a first principal surface 3 on one side, a second principal surface 4 on the other side, and first to fourth side surfaces 5A to 5D that connect the first principal surface 3 and the second principal surface 4.

The first principal surface 3 and the second principal surface 4 are each formed in a quadrangular shape in a plan view seen from their normal directions Z (hereinafter, referred to simply as a “plan view”). The normal direction Z is also a thickness direction of the semiconductor chip 2. The first side surface 5A and the second side surface 5B extend in a first direction X along the first principal surface 3, and face each other in a second direction Y that intersects the first direction X (in detail, perpendicularly intersects the first direction X). The third side surface 5C and the fourth side surface 5D extend in the second direction Y, and face each other in the first direction X.

The semiconductor device 1A includes a plurality of device regions 10 formed at the first principal surface 3. The device regions 10 are regions in which various functional devices are formed by use of regions inside the semiconductor chip 2, respectively. The device regions 10 are each demarcated in an inward portion of the first principal surface 3 at a distance from the first to fourth side surfaces 5A to 5D in a plan view. The device region 10 is optional in number, in disposition, and in shape, and is not limited to a specific number, to a specific disposition, and to a specific shape.

The functional devices may each include at least one among a semiconductor switching device, a semiconductor rectifying device, and a passive device. The semiconductor switching device may include at least one among JFET (Junction Field Effect Transistor), MISFET (Metal Insulator Semiconductor Field Effect Transistor), BJT (Bipolar Junction Transistor), and IGBT (Insulated Gate Bipolar Junction Transistor).

The semiconductor rectifying device may include at least one among a pn junction diode, a pin junction diode, a Zener diode, a Schottky barrier diode, and a fast recovery diode. The passive device may include at least one among a resistor, a capacitor, an inductor, and a fuse. In this embodiment, the device regions 10 include at least one active region 11.

The active region 11 is a region in which a plurality of transistor devices are formed. An electric current flows in a lateral direction of the semiconductor chip 2 in the active region 11 when a source-drain interval of the semiconductor device 1A is in an electrically conductive state (when turned on). The active region 11 is, for example, a quadrilateral shape in a plan view.

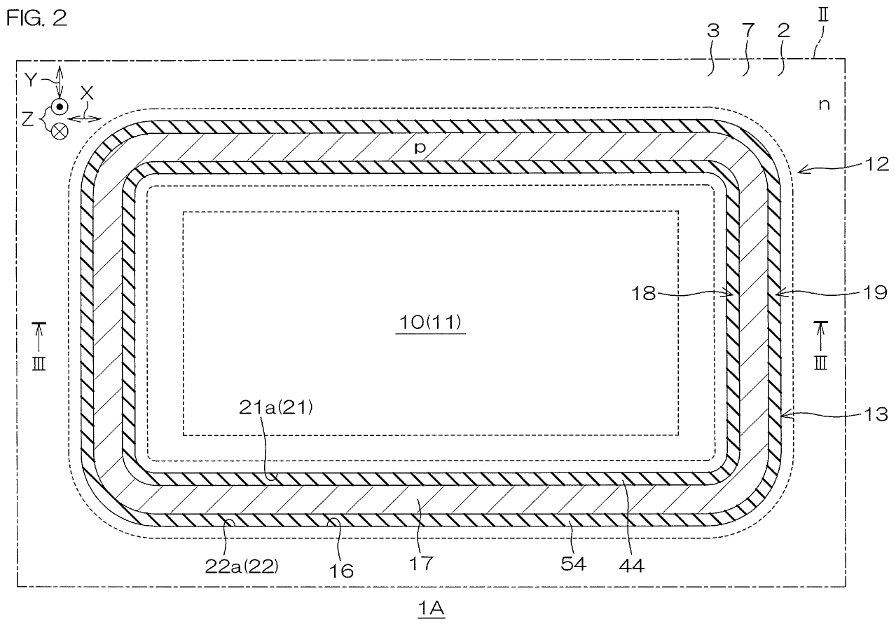

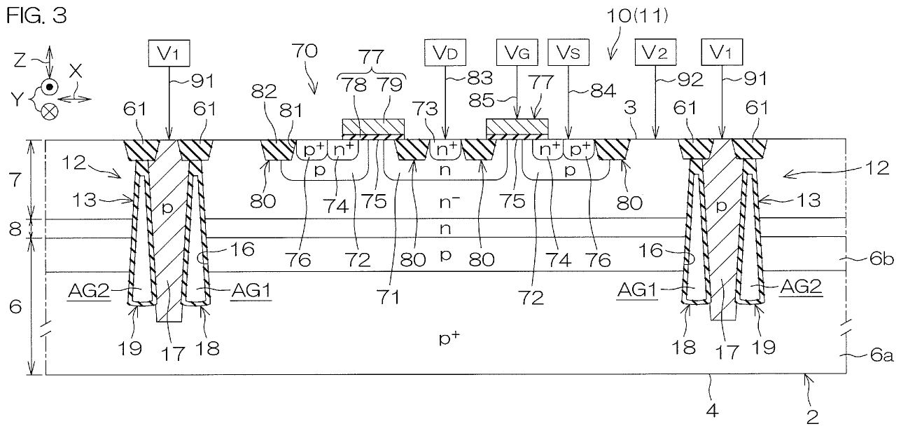

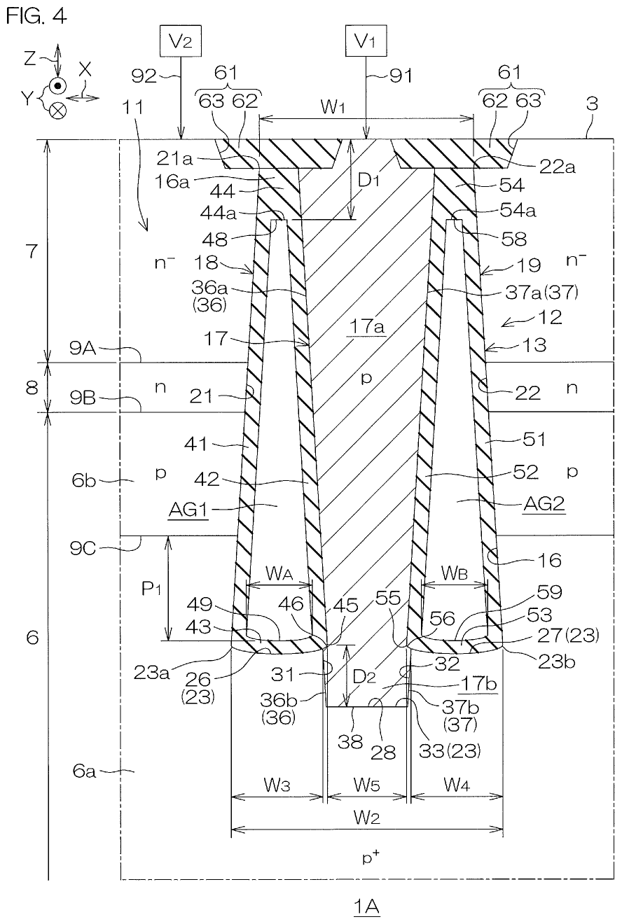

FIG. 2 is an enlarged view of region II shown in FIG. 1. FIG. 3 is a view showing cross section III-III shown in FIG. 2. FIG. 4 is a cross-sectional enlarged view of a main portion of a structure shown in FIG. 3.

Referring to FIG. 3, the semiconductor chip 2 includes a p-type (first conductivity type) first impurity region 6 in a region located on the second principal surface 4 side. The first impurity region 6 may be referred to as a “base region.” The first impurity region 6 extends in a layer shape that follows the second principal surface 4, and is exposed from a part of the second principal surface 4 and from a part of the first to fourth side surfaces 5A to 5D. The first impurity region 6 has a concentration gradient in which a p-type impurity concentration on the first principal surface 3 side is lower than a p-type impurity concentration on the second principal surface 4 side. In detail, the first impurity region 6 has a laminated structure including a p-type high concentration region 6a and a p-type low concentration region 6b that are laminated in that order from the second principal surface 4 side.

The high concentration region 6a has a comparatively high p-type impurity concentration. The p-type impurity concentration of the high concentration region 6a may be not less than 1×10¹⁷ cm⁻³ and not more than 1×10²¹ cm⁻³. The high concentration region 6a may include boron (B) as a p-type impurity. The high concentration region 6a may have a thickness of not less than 50 μm and not more than 500 μm. In this embodiment, the high concentration region 6a is made of a p-type semiconductor substrate (Si substrate).

The low concentration region 6b has a p-type impurity concentration lower than the high concentration region 6a, and is laminated on the high concentration region 6a. The p-type impurity concentration of the low concentration region 6b may be not less than 1×10¹⁴ cm⁻³ and not more than 1×10¹⁷ cm⁻³. The low concentration region 6b may include boron (B) as a p-type impurity. The low concentration region 6b has a thickness less than the thickness of the high concentration region 6a. The thickness of the low concentration region 6b may be not less than 1 μm and not more than 20 μm. In this embodiment, the low concentration region 6b is made of a p-type epitaxial layer (Si epitaxial layer).

Referring to FIG. 3, the semiconductor chip 2 includes an n-type (second conductivity type) second impurity region 7 formed in a region located on the first principal surface 3 side. The second impurity region 7 extends in a layer shape that follows the first principal surface 3, and is exposed from a part of the first principal surface 3 and from a part of the first to fourth side surfaces 5A to 5D. The n-type impurity concentration of the second impurity region 7 may be not less than 1×10¹⁴ cm⁻³ and not more than 1×10¹⁷ cm⁻³. The second impurity region 7 may have a thickness of not less than 5 μm and not more than 30 μm. The second impurity region 7 may have an n-type impurity concentration that is uniform in the thickness direction, or may have a concentration gradient in which the n-type impurity concentration becomes higher toward the first principal surface 3. The second impurity region 7 may be made of an n-type epitaxial layer (Si epitaxial layer).

The semiconductor chip 2 includes an n-type (second conductivity type) buried region 8 that is buried between the first impurity region 6 and the second impurity region 7. In other words, the first impurity region 6, the buried region 8, and the second impurity region 7 are laminated in that order from the second principal surface 4 side. The buried region 8 is electrically connected to the first impurity region 6 and to the second impurity region 7. The buried region 8 extends in a layer shape that follows the second impurity region 7. The buried region 8 is exposed from a part of the first to fourth side surfaces 5A to 5D. The n-type impurity concentration of the buried region 8 may be not less than 1×10¹⁶ cm⁻³ and not more than 1×10²¹ cm⁻³. The buried region 8 may have a thickness of not less than 0.1 μm and not more than 5 μm. The buried region 8 may be made of an n-type epitaxial layer (Si epitaxial layer).

Referring to FIG. 2 and FIG. 3, the semiconductor chip 2 includes an element isolation portion 12 that is formed on the first principal surface 3 side and demarcates the active region 11. The element isolation portion 12 is annular in a plan view, and, in detail, is rectangularly annular. More concretely, the element isolation portion 12 has a rectangularly annular shape having corner portions (four corners) each of which is curved in a circular arc shape in a plan view.

The element isolation portion 12 includes a first trench structure 13 formed on the first principal surface 3 side of the semiconductor chip 2. The first trench structure 13 includes an inner peripheral wall on the active region 11 side, an outer peripheral wall on the other side of the inner peripheral wall (peripheral edge side of the semiconductor chip 2), and a bottom wall connecting the inner peripheral wall and the outer peripheral wall. The bottom wall of the first trench structure 13 may have a flat surface parallel to the first principal surface 3. The bottom wall of the first trench structure 13 may be formed in a curved shape toward the second principal surface 4.

The first trench structure 13 includes a trench 16, a buried conductor 17, a first insulating portion 18, and a second insulating portion 19. The buried conductor 17 is buried in the trench 16. Referring to FIG. 2, the trench 16 is formed on the first principal surface 3 side so as to demarcate the active region 11. In this embodiment, the trench 16 is annular in a plan view (in this embodiment, rectangularly annular). More concretely, the trench 16 has corner portions (four corners) each of which is curved in a circular arc shape in a plan view.

Referring to FIG. 4, the trench 16 penetrates through the second impurity region 7 and through the buried region 8 so as to reach the first impurity region 6. In detail, the trench 16 extends from the first principal surface 3 toward the second principal surface 4 side so as to reach the high concentration region 6a of the first impurity region 6, and penetrates through the second impurity region 7, through the buried region 8, and through the low concentration region 6b of the first impurity region 6.

The trench 16 includes a first side surface (side surface, side surface on one side) 21 on the active region 11 side, a second side surface (side surface, side surface on the other side) 22 on the side opposite to the active region 11 side, and a bottom surface (bottom portion) 23 that connects the first side surface 21 and the second side surface 22. In this embodiment, the first side surface 21 is an inner peripheral surface of the annular trench 16, and the second side surface 22 is an outer peripheral surface of the annular trench 16.

The trench 16 is formed in a tapered shape whose width becomes smaller from the bottom surface 23 of the trench 16 toward the first principal surface 3 in a cross-sectional view. The trench 16 has a first width W₁ in open ends 21a and 22a. The first width W₁ is a width in a direction perpendicular to a direction in which the trench 16 extends in a plan view. The first width W₁ may be not less than 0.5 μm and not more than 10 μm. Preferably, the first width W₁ is not less than 2 μm and not more than 4 μm. The bottom surface 23 of the trench 16 has a second width W₂. The second width W₂ is a width in a direction perpendicular to the direction in which the trench 16 extends in a plan view. The second width W₂ is wider than the first width W₁ (second width W₂>first width W₁).

The first side surface 21 of the trench 16 is formed so as to straddle the second impurity region 7, the buried region 8, the low concentration region 6b, and the high concentration region 6a. The first side surface 21 is contiguous to the second impurity region 7, to the buried region 8, to the low concentration region 6b, and to the high concentration region 6a. The first side surface 21 is an inclined surface that advances to a more outward side of the trench 16 (toward the active region 11 side) in proportion to an approach to the second principal surface 4. In other words, in the first side surface 21, a halfway portion in a depth direction of the trench 16 becomes more convex outwardly from the trench 16 (toward the active region 11 side) than the open end 21a in a cross-sectional view. In this embodiment, an end portion 23a on the outside of the bottom surface 23 (active region 11 side) is located on a more outward side (active region 11 side) than the open end 21a.

The second side surface 22 of the trench 16 is formed so as to straddle the second impurity region 7, the buried region 8, the low concentration region 6b, and the high concentration region 6a. The second side surface 22 is contiguous to the second impurity region 7, to the buried region 8, to the low concentration region 6b, and to the high concentration region 6a. The second side surface 22 is an inclined surface that advances to a more outward side of the trench 16 (toward the side opposite to the active region 11 side) in proportion to an approach to the second principal surface 4. In other words, in the second side surface 22, a halfway portion in the depth direction of the trench 16 becomes more convex outwardly from the trench 16 (toward the side opposite to the active region 11 side) than the open end 22a of the second side surface 22 in a cross-sectional view. In this embodiment, an end portion 23b of the outside of the bottom surface 23 (side opposite to the active region 11 side) is located on a more outward side (side opposite to the active region 11 side) than the open end 22a.

The bottom surface 23 includes a first lateral bottom surface 26, a second lateral bottom surface 27, and a central bottom surface 28. The central bottom surface 28 connects the first lateral bottom surface 26 and the second lateral bottom surface 27. The first lateral bottom surface 26 is formed on the active region 11 side with respect to the central bottom surface 28. The second lateral bottom surface 27 is formed on the side opposite to the first lateral bottom surface 26 with respect to the central bottom surface 28. The first lateral bottom surface 26 and the second lateral bottom surface 27 are placed such that the central bottom surface 28 is sandwiched between the first lateral bottom surface 26 and the second lateral bottom surface 27 in the direction perpendicular to the direction in which the trench 16 extends in a plan view. The central bottom surface 28 extends along the direction in which the trench 16 extends. The central bottom surface 28 is a concept including a bottom surface 33, a first groove side surface 31, and a second groove side surface 32 described later. A bottom groove is formed by the bottom surface 33, the first groove side surface 31, and the second groove side surface 32.

The first lateral bottom surface 26 extends along the direction in which the trench 16 extends. In this embodiment, the first lateral bottom surface 26 is formed in an endless annular shape over the entire periphery of the annular trench 16. In the example of FIG. 4, the shape of the first lateral bottom surface 26 is a round shape that swells toward the second principal surface 4 side in a cross-sectional view. The first lateral bottom surface 26 has a third width W₃. The third width W₃ is a width in a direction perpendicular to the direction in which the trench 16 extends in a plan view. The first lateral bottom surface 26 is formed in the high concentration region 6a. The first lateral bottom surface 26 is contiguous to the high concentration region 6a. The first lateral bottom surface 26 may have a flat surface parallel to the first principal surface 3.

The second lateral bottom surface 27 extends along the direction in which the trench 16 extends. In this embodiment, the second lateral bottom surface 27 is formed in an endless annular shape over the entire periphery of the annular trench 16, and surrounds the annular first lateral bottom surface 26. In the example of FIG. 4, the shape of the second lateral bottom surface 27 is a round shape that swells toward the second principal surface 4 side in a cross-sectional view. The second lateral bottom surface 27 is placed at the same depth position as the first lateral bottom surface 26. A lower end portion of the second lateral bottom surface 27 has the same depth as a lower end portion of the first lateral bottom surface 26. A shallowest part of the second lateral bottom surface 27 has the same depth as a shallowest part of the first lateral bottom surface 26. The second lateral bottom surface 27 has a fourth width W₄. The fourth width W₄ is a width in the direction perpendicular to the direction in which the trench 16 extends in a plan view. The fourth width W₄ is the same as the third width W₃. The second lateral bottom surface 27 is formed in the high concentration region 6a. The second lateral bottom surface 27 is contiguous to the high concentration region 6a. The second lateral bottom surface 27 may have a flat surface parallel to the first principal surface 3.

The central bottom surface 28 is formed in a tapered shape whose width becomes larger from the bottom surface 33 toward the first principal surface 3. The first groove side surface 31 and the second groove side surface 32 are formed in the high concentration region 6a. The first groove side surface 31 and the second groove side surface 32 are contiguous to the high concentration region 6a.

The bottom surface 33 is formed at a position that is deeper than both the first lateral bottom surface 26 and the second lateral bottom surface 27 with regard to the depth direction of the trench 16. In the example of FIG. 4, the bottom surface 33 has a flat surface parallel to the first principal surface 3. The bottom surface 33 may have around shape that swells toward the second principal surface 4 side in a cross-sectional view. The bottom surface 33 is formed in the high concentration region 6a. The bottom surface 33 is contiguous to the high concentration region 6a.

The buried conductor 17 is buried in the trench 16. The buried conductor 17 is polysilicon. In this embodiment, this polysilicon is doped-polysilicon to which a p-type (first conductivity type) impurity (for example, boron (B)) has been added. The buried conductor 17 includes a main body portion 17a and a protruding portion 17b that protrudes from a lower end of the main body portion 17a toward the second principal surface 4 side. The main body portion 17a of the buried conductor 17 is a part closer to the first principal surface 3 than both the first lateral bottom surface 26 and the second lateral bottom surface 27 in the trench 16 with regard to the depth direction of the trench 16. The protruding portion 17b is a part that protrudes toward the bottom surface 33 side with respect to both the first lateral bottom surface 26 and the second lateral bottom surface 27, and is a part buried in the central bottom surface 28 of the bottom surface 23.

The buried conductor 17 includes a first sidewall 36 on the active region 11 side, a second sidewall 37 on the side opposite to the first sidewall 36, and a bottom wall (bottom portion) 38. The distance between the first sidewall 36 and the second sidewall 37 becomes larger toward the first principal surface 3, and, as a result, the buried conductor 17 is formed in a tapered shape.

The first sidewall 36 includes an upper part 36a that is a constituent of the sidewall of the main body portion 17a and a lower part 36b that is a constituent of the sidewall of the protruding portion 17b. The upper part 36a is an inclined wall that advances to a more inward side of the trench 16 (toward the side opposite to the active region 11 side) in proportion to an approach to the second principal surface 4. The lower part 36b is parallel to the upper part 36a on a more outward side of the trench 16 (on the active region 11 side) than the upper part 36a by one step. The upper part 36a and the lower part 36b are continuous with each other through a connection wall formed near the first lateral bottom surface 26 between the upper part 36a and the lower part 36b. The first sidewall 36 of the buried conductor 17 has a stepped portion 46 at a boundary portion between the upper part 36a and the lower part 36b in the depth direction of the trench 16. This stepped portion 46 may be an endless annular stepped portion formed over the entirety of the annular trench 16. Hence, the buried conductor 17 has a shape in which the protruding portion 17b swells sidewardly with respect to the main body portion 17a. The lower part 36b is an inclined surface that advances to a more inward side of the trench 16 (toward the side opposite to the active region 11 side) in proportion to an approach to the second principal surface 4. The lower part 36b is contiguous to the first groove side surface 31 of the central bottom surface 28. The lower part 36b is contiguous to the high concentration region 6a in the first groove side surface 31.

The second sidewall 37 includes an upper part 37a that is a constituent of the sidewall of the main body portion 17a and a lower part 37b that is a constituent of the sidewall of the protruding portion 17b. The upper part 37a is an inclined wall that advances to a more outward side of the trench 16 (toward the active region 11 side) in proportion to an approach to the second principal surface 4. The lower part 37b protrudes to a more outward side of the trench 16 (toward the side opposite to the active region 11 side) than the upper part 37a by one step, and is parallel to the upper part 37a. The upper part 37a and the lower part 37b are continuous with each other through a connection wall formed near the second lateral bottom surface 27—between the upper part 37a and the lower part 37b. The second sidewall 37 of the buried conductor 17 has a stepped portion 56 at a boundary portion between the upper part 36a and the lower part 36b in the depth direction of the trench 16. This stepped portion 56 may be an endless annular stepped portion formed over the entirety of the annular trench 16. Hence, the buried conductor 17 has a shape in which the protruding portion 17b swells sidewardly with respect to the main body portion 17a. The lower part 37b is an inclined surface that advances to a more inward side of the trench 16 (toward the active region 11 side) in proportion to an approach to the second principal surface 4. The lower part 37b is contiguous to the second groove side surface 32 of the central bottom surface 28. The lower part 37b is contiguous to the high concentration region 6a in the second groove side surface 32.

The bottom wall 38 of the buried conductor 17 forms a bottom wall of the protruding portion 17b. The bottom wall 38 is contiguous to the bottom surface 33 of the central bottom surface 28. The bottom wall 38 is contiguous to the high concentration region 6a in the bottom surface 33. That is, the buried conductor 17 is electrically connected to the high concentration region 6a in the lower part 36b, in the lower part 37b, and in the bottom wall 38. This makes it possible to make the contact area larger than in a case in which the buried conductor 17 is electrically connected to the high concentration region 6a only in the bottom wall 38.

The first trench structure 13 includes the first insulating portion 18 as described above. The first insulating portion 18 insulates the buried conductor 17 and the first side surface 21 of the trench 16 in the trench 16. The first insulating portion 18 includes a first insulating film 41, a second insulating film 42, a third insulating film 43, an upper insulating film 44, and an air gap AG1. The buried conductor 17 and a region located on the active region 11 side with respect to the first trench structure 13 are electrically insulated from each other by means of the first insulating portion 18.

The first insulating film 41 is formed on the first side surface 21 of the trench 16. The first insulating film 41 covers the first side surface 21 of the trench 16. The first insulating film 41 is inclined so as to advance to a more outward side of the trench 16 (toward the active region 11 side) in proportion to an approach to the second principal surface 4. The first insulating film 41 may be an oxide film. The oxide film may be silicon oxide (SiO₂), or may be tetraethyl orthosilicate (TEOS).

The second insulating film 42 covers the upper part 36a of the first sidewall 36 of the buried conductor 17. The second insulating film 42 is inclined so as to advance to a more inward side of the trench 16 (toward the side opposite to the active region 11 side) in proportion to an approach to the second principal surface 4. The second insulating film 42 may be an oxide film. The oxide film may be silicon oxide (SiO₂), or may be tetraethyl orthosilicate (TEOS).

The third insulating film 43 covers the first lateral bottom surface 26 of the trench 16. The third insulating film 43 is flat and is parallel to the first principal surface 3. The third insulating film 43 may be an oxide film. The oxide film may be silicon oxide (SiO₂), or may be tetraethyl orthosilicate (TEOS). In the example of FIG. 4, an inner end 45 of the third insulating film 43 (end portion on the side opposite to the active region 11 side) is located on a more inward side (side opposite to the active region 11 side) than the first groove side surface 31 of the central bottom surface 28. The stepped portion 46 that demarcates the upper part 36a and the lower part 36b is formed at the first sidewall 36 of the buried conductor 17. The inner end 45 is fitted to the stepped portion 46.

The upper insulating film 44 connects the first insulating film 41 and the second insulating film 42 in an upper portion 16a of the trench 16. The upper insulating film 44 closes an upper portion of the air gap AG1. In the example of FIG. 4, a lower end 44a of the upper insulating film 44 is located closer to the first principal surface 3 side than a boundary part 9A between the second impurity region 7 and the buried region 8. A first depth D₁ of the lower end 44a of the upper insulating film 44 may be 0.01 μm to 30 μm. The first insulating film 41 and the second insulating film 42 are connected only in the upper portion 16a of the trench 16, and are not connected to each other in other halfway portions in the depth direction of the trench 16.

The air gap AG1 is a sealed space demarcated by the first insulating film 41, by the second insulating film 42, by the third insulating film 43, and by the upper insulating film 44, and houses air in the inside. The air gap AG1 is formed in a tapered shape whose width becomes smaller from the first lateral bottom surface 26 toward the first principal surface 3. The air gap AG1 is sandwiched between the first insulating film 41 and the second insulating film 42 in the direction perpendicular to the direction in which the trench 16 extends in a plan view. In other words, the second insulating film 42 is formed inside the trench 16 inwardly from the first insulating film 41 (side opposite to the active region 11 side) with the air gap AG1 between the second insulating film 42 and the first insulating film 41. The air gap AG1 has a width W_{A}. The width W_{A} is a width in the direction perpendicular to the direction in which the trench 16 extends in a lower end 49 of the air gap AG1 in a plan view. The width W_{A} may be 1/300 to ½ times as large as the depth of the trench 16.

The air gap AG1 is formed so as to be interposed among the buried conductor 17, the second impurity region 7, the buried region 8, the low concentration region 6b, and the high concentration region 6a. In this embodiment, the air gap AG1 is sandwiched between the buried conductor 17 and the buried region 8. In this embodiment, the air gap AG1 is sandwiched between the buried conductor 17 and the low concentration region 6b.

In the example of FIG. 4, the distance between an upper end 48 of the air gap AG1 and the first principal surface 3 is shorter than the distance between the upper end 48 of the air gap AG1 and the boundary part 9A between the buried region 8 and the second impurity region 7. The distance between the upper end 48 and the first principal surface 3 may be longer than the distance between the upper end 48 and the boundary part 9A.

In the example of FIG. 4, the lower end 49 of the air gap AG1 is located closer to the second principal surface 4 side than a boundary part 9B between the buried region 8 and the first impurity region 6. In this embodiment, the lower end 49 of the air gap AG1 is located closer to the second principal surface 4 side than a boundary part 9C between the low concentration region 6b and the high concentration region 6a. A first amount of protrusion P₁ of the lower end 49 from the boundary part 9C may be larger than a second depth D₂ of the central bottom surface 28. The first amount of protrusion P₁ of the lower end 49 from the boundary part 9C may be smaller than the second depth D₂ of the central bottom surface 28. The lower end 49 of the air gap AG1 is located closer to the first principal surface 3 side than the bottom wall 38 of the buried conductor 17 (i.e., the bottom wall 38 of the protruding portion 17b).

The first trench structure 13 includes the second insulating portion 19 as described above. The second insulating portion 19 insulates the buried conductor 17 and the second side surface 22 of the trench 16 in the trench 16. The second insulating portion 19 includes a first insulating film 51, a second insulating film 52, a third insulating film 53, an upper insulating film 54, and an air gap AG2. The buried conductor 17 and a region located on the side opposite to the active region 11 side with respect to the first trench structure 13 are electrically insulated from each other by means of the second insulating portion 19.

The first insulating film 51 is formed on the second side surface 22 of the trench 16. The first insulating film 51 covers the first side surface 21 of the trench 16. The first insulating film 51 is inclined so as to advance to a more outward side of the trench 16 (toward the side opposite to the active region 11 side) in proportion to an approach to the second principal surface 4. The first insulating film 51 may be an oxide film. The oxide film may be silicon oxide (SiO₂), or may be tetraethyl orthosilicate (TEOS).

The second insulating film 52 covers the upper part 37a of the second sidewall 37 of the buried conductor 17. The second insulating film 52 is inclined so as to advance to a more inward side of the trench 16 (toward the active region 11 side) in proportion to an approach to the second principal surface 4. The second insulating film 52 may be an oxide film. The oxide film may be silicon oxide (SiO₂), or may be tetraethyl orthosilicate (TEOS).

The third insulating film 53 covers the second lateral bottom surface 27 of the trench 16. The third insulating film 53 is flat and is parallel to the first principal surface 3. The third insulating film 53 may be an oxide film. The oxide film may be silicon oxide (SiO₂), or may be tetraethyl orthosilicate (TEOS). In the example of FIG. 4, an inner end 55 (end portion on the active region 11 side) of the third insulating film 53 is located on a more inward side (active region 11 side) than the second groove side surface 32 of the central bottom surface 28. The stepped portion 56 that demarcates the upper part 37a and the lower part 37b is formed at the second sidewall 37 of the buried conductor 17. The inner end 55 is fitted to the stepped portion 56.

The interval between the inner end 55 of the third insulating film 53 and the inner end 45 of the third insulating film 43 has a fifth width W₅. The fifth width W₅ is a width in the direction perpendicular to the direction in which the trench 16 extends in a plan view. The fifth width W₅ may be wider than the third width W₃ and than the fourth width W₄. The fifth width W₅ may be narrower than the third width W₃ and than the fourth width W₄.

The upper insulating film 54 connects the first insulating film 51 and the second insulating film 52 in the upper portion 16a of the trench 16. The upper insulating film 54 closes an upper portion of the air gap AG2. In the example of FIG. 4, a lower end 54a of the upper insulating film 54 is located closer to the first principal surface 3 side than the boundary part 9A between the second impurity region 7 and the buried region 8. The depth of the lower end 54a of the upper insulating film 54 may be the same as the first depth D₁ of the lower end 44a of the upper insulating film 44. The first insulating film 51 and the second insulating film 52 are connected only in the upper portion of the trench 16, and are not connected to each other in other halfway portions in the depth direction of the trench 16.

The air gap AG2 is a sealed space demarcated by the first insulating film 51, by the second insulating film 52, by the third insulating film 53, and by the upper insulating film 54, and houses air in the inside. The air gap AG2 is formed in a tapered shape whose width becomes smaller from the second lateral bottom surface 27 toward the first principal surface 3. The air gap AG2 is sandwiched between the first insulating film 51 and the second insulating film 52 in the direction perpendicular to the direction in which the trench 16 extends in a plan view. In other words, the second insulating film 52 is formed inside the trench 16 inwardly from the first insulating film 51 (the active region 11 side) with the air gap AG2 between the second insulating film 52 and the first insulating film 51. The air gap AG2 has a width W_{B}. The width W_{B} is a width in the direction perpendicular to the direction in which the trench 16 extends in a lower end 59 of the air gap AG2 in a plan view. The width W_{B} may be 1/300 to ½ times as large as the depth of the trench 16.

The air gap AG2 is formed so as to be interposed among the buried conductor 17, the second impurity region 7, the buried region 8, the low concentration region 6b, and the high concentration region 6a. In detail, the air gap AG2 is sandwiched between the buried conductor 17 and the buried region 8. The air gap AG2 is sandwiched between the buried conductor 17 and the low concentration region 6b.

In the example of FIG. 4, the distance between an upper end 58 of the air gap AG2 and the first principal surface 3 is shorter than the distance between the upper end 58 of the air gap AG2 and the boundary part 9A between the buried region 8 and the second impurity region 7. The distance between the upper end 58 and the first principal surface 3 may be longer than the distance between the upper end 58 and the boundary part 9A.

In the example of FIG. 4, the lower end 59 of the air gap AG2 is located closer to the second principal surface 4 side than the boundary part 9B between the buried region 8 and the first impurity region 6. In this embodiment, the lower end 59 of the air gap AG2 is located closer to the second principal surface 4 side than the boundary part 9C between the low concentration region 6b and the high concentration region 6a. The amount of protrusion of the lower end 59 from the boundary part 9C is the same as the first amount of protrusion P₁ of the lower end 49 from the boundary part 9C. The lower end 59 of the air gap AG2 is located closer to the first principal surface 3 side than the bottom wall 38 of the buried conductor 17.

Referring to FIG. 3 and FIG. 4, the semiconductor device 1A includes a plurality of second trench structures 61 formed at the first principal surface 3. In FIG. 2, the second trench structure 61 is omitted, and is not shown. The second trench structures 61 may be referred to as STI structures (shallow trench isolation) structures. The second trench structures 61 are each formed at a distance from each other so as to cover the sidewalls 36 and 37 of the trench 16 and so as to expose the buried conductor 17.

The second trench structures 61 are formed at a distance from the buried region 8 toward the first principal surface 3 side. That is, the second trench structures 61 are formed within the thickness range of the second impurity region 7. The second trench structure 61 extends along the first trench structure 13 in a plan view. In this embodiment, the second trench structure 61 is formed in an annular shape (in this embodiment, rectangularly annular shape) extending along the first trench structure 13 in a plan view.

Each of the second trench structures 61 includes a shallow trench 62 and a buried insulator 63. The shallow trench 62 is formed at a position at which the shallow trench 62 overlaps with the sidewalls 36 and 37 of the trench 16, and exposes the second impurity region 7, the upper insulating films 44 and 54, and the buried conductor 17.

The buried insulator 63 is buried in the shallow trench 62. In the shallow trench 62, the buried insulator 63 is contiguous to the second impurity region 7, the upper insulating films 44 and 54, and the buried conductor 17. The buried insulator 63 may include at least one among oxide films of silicon oxide, etc., and nitride films of silicon nitride, etc.

Referring to FIG. 3, the semiconductor device 1A includes a planar-gate type MISFET cell 70 that is an example of the functional device formed in the active region 11. In FIG. 2, the MISFET cell 70 is omitted, and is not shown. The MISFET cell 70 can employ any one form of HV (high voltage)-MISFET cell (for example, not less than 100 V and not more than 1000 V), MV (middle voltage)-MISFET cell (for example, not less than 30 V and not more than 100 V), and LV (low voltage)-MISFET cell (for example, not less than 1 V and not more than 30 V) in accordance with the largeness of a drain-source voltage. In this embodiment, an example in which the MISFET cell 70 is an HV-MISFET cell will be described, and yet this does not denote that the form of the MISFET cell 70 is limited to the HV-MISFET cell.

The MISFET cell 70 includes at least one n-type first well region 71 (in this embodiment, one first well region 71), at least one p-type second well region 72 (in this embodiment, a plurality of p-type second well regions 72), at least one n-type drain region 73 (in this embodiment, one n-type drain region 73), at least one n-type source region 74 (in this embodiment, a plurality of n-type source regions 74), at least one p-type channel region 75 (in this embodiment, a plurality of p-type channel regions 75), at least one p-type contact region 76 (in this embodiment, a plurality of p-type contact regions 76), and at least one planar gate structure 77 (in this embodiment, a plurality of planar gate structures 77) in a cross-sectional view.

The first well region 71 is formed at a surficial portion of the second impurity region 7 in the active region 11. The first well region 71 has an n-type impurity concentration higher than the second impurity region 7. The second well regions 72 are formed at the surficial portion of the second impurity region 7 at a distance from the first well region 71 in the active region 11. The second well region 72 that is one of the second well regions 72 is formed at a distance from the first well region 71 to one side in the first direction X, and the other second well region 72 is formed at a distance from the first well region 71 to the other side in the first direction X.

The drain region 73 is formed at a surficial portion of the first well region 71 at a distance inwardly from the peripheral edge of the first well region 71. The source regions 74 are each formed at a surficial portion of a corresponding one of the second well regions 72 at a distance inwardly from the peripheral edge of the corresponding second well region 72. The channel regions 75 are each formed between the second impurity region 7 and the source region 74 in the surficial portion of the corresponding second well region 72. The contact regions 76 are each formed at the surficial portion of the corresponding second well region 72 at a distance inwardly from the peripheral edge of the corresponding second well region 72. The contact regions 76 adjoin a corresponding one of the source regions 74.

The planar gate structures 77 are each formed on the first principal surface 3 so as to cover a corresponding one of the channel regions 75, and controls the on/off of the corresponding channel region 75. In this embodiment, the planar gate structures 77 are each formed so as to straddle the first well region 71 and the corresponding source region 74.

The planar gate structures 77 include a gate insulating film 78 and a gate electrode 79 laminated in that order from the first principal surface 3 side. The gate insulating film 78 may include silicon oxide (SiO₂), or may include a tetraethyl orthosilicate (TEOS). Preferably, the gate insulating film 78 includes a silicon oxide film made of an oxide of the semiconductor chip 2. Preferably, the gate electrode 79 includes polysilicon. The gate electrode 79 may include either one or both of an n-type region and a p-type region formed in the polysilicon.

Referring to FIG. 3, the semiconductor device 1A includes a plurality of third trench structures 80 formed at the first principal surface 3. In FIG. 2, the third trench structure 80 is omitted, and is not shown. The third trench structures 80 may be referred to as STI structures. In this embodiment, the third trench structures 80 are formed at a distance from each other so as to demarcate the drain region 73 from other regions and so as to demarcate outer edge portions of the second well regions 72 from other regions.

In this embodiment, the third trench structures 80 are formed at a distance from the buried region 8 to the first principal surface 3 side. That is, the third trench structures 80 are formed in the thickness range of the second impurity region 7.

Each of the third trench structures 80 includes a shallow trench 81 and a buried insulator 82. The shallow trench 81 is dug down from the first principal surface 3 toward the second principal surface 4. The buried insulator 82 is buried in the shallow trench 81. The buried insulator 82 may include at least either one of silicon oxide and silicon nitride.

In the active region 11, a drain potential V_{D} is given to the drain region 73 through a drain contact electrode 83. In FIG. 3, the drain contact electrode 83 is shown by being simplified by an arrow. The drain potential V_{D} is a positive device potential in the active region 11. A source potential Vs less than the drain potential V_{D} is given to the source region 74 through a source contact electrode 84. In FIG. 3, the source contact electrode 84 is shown by being simplified by an arrow. A gate potential VG is given to the gate electrode 79 through a gate contact electrode 85. In FIG. 3, the gate contact electrode 85 is shown by being simplified by an arrow.

A first potential V₁ is given to the buried conductor 17 through a contact electrode 91. In FIG. 3, the contact electrode 91 is shown by being simplified by an arrow. The first potential V₁ given to the buried conductor 17 is given to the high concentration region 6a through the buried conductor 17. Hence, the high concentration region 6a is fixed at the same electric potential as the buried conductor 17. Preferably, the first potential V₁ is a potential equal to or less than the drain potential V_{D} (preferably, less than the drain potential V_{D}). That is, preferably, the first potential V₁ is less than a maximal device potential. The first potential V₁ may be a reference potential that serves as a criterion for a circuit operation or a ground potential. Preferably, the first potential V₁ is a ground potential.

A second potential V₂ is given to a region demarcated between the first trench structure 13 and the active region 11 in the semiconductor chip 2 through a second contact electrode 92. In FIG. 3 and FIG. 4, the second contact electrode 92 is shown by being simplified by an arrow. Preferably, the second potential V₂ is a potential equal to or less than the drain potential V_{D}(preferably, less than the drain potential V_{D}). Preferably, the second potential V₂ is less than a maximal device potential. The second potential V₂ may be equal to or more than the first potential V₁ (V₁<V₂). The second potential V₂ may exceed the first potential V₁ (V₁<V₂). The second potential V₂ may be a reference potential or a ground potential.

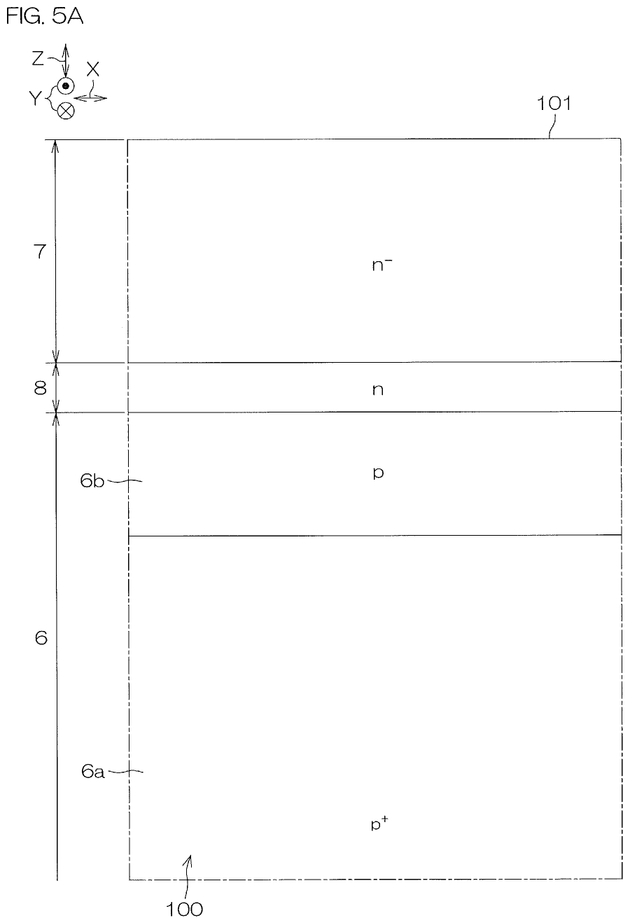

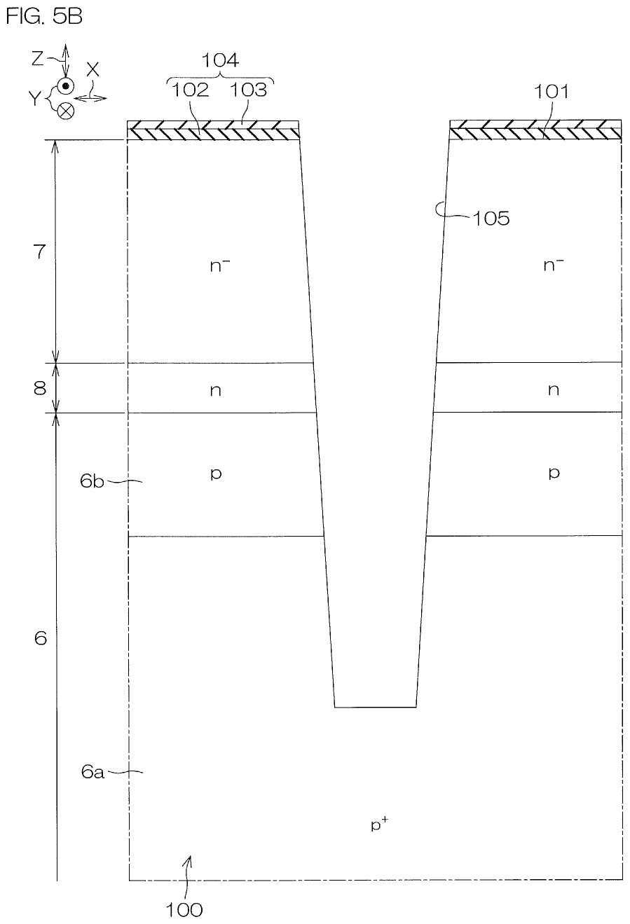

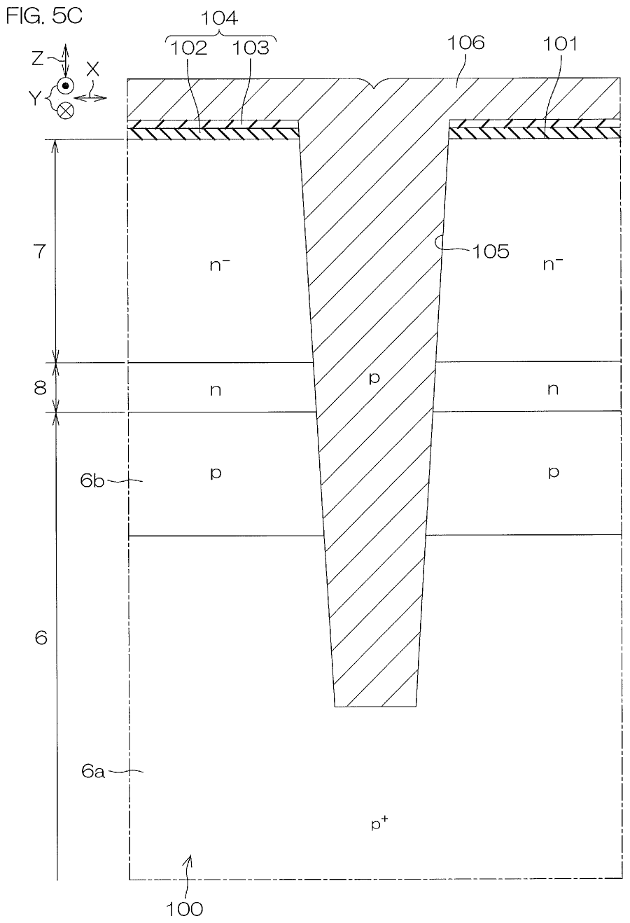

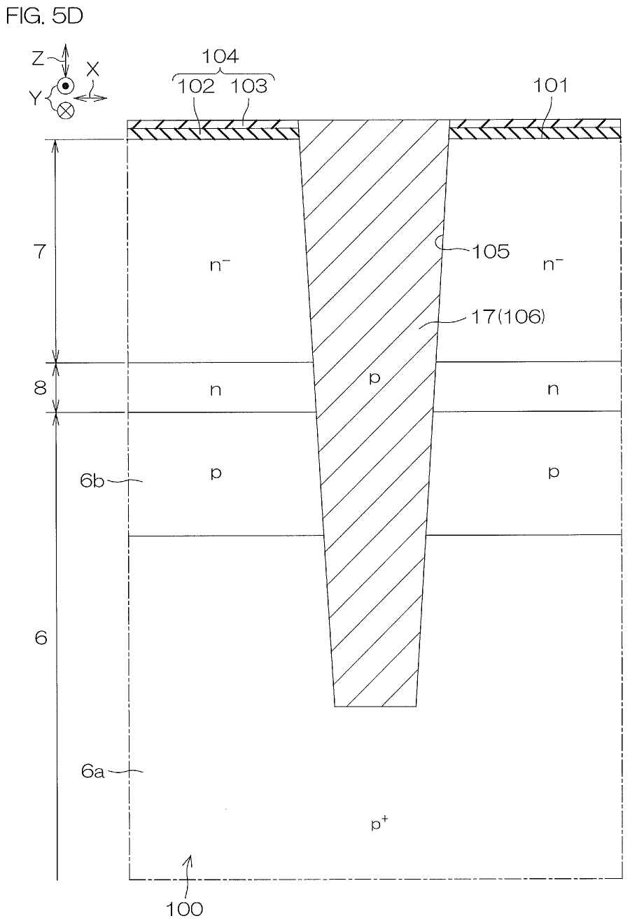

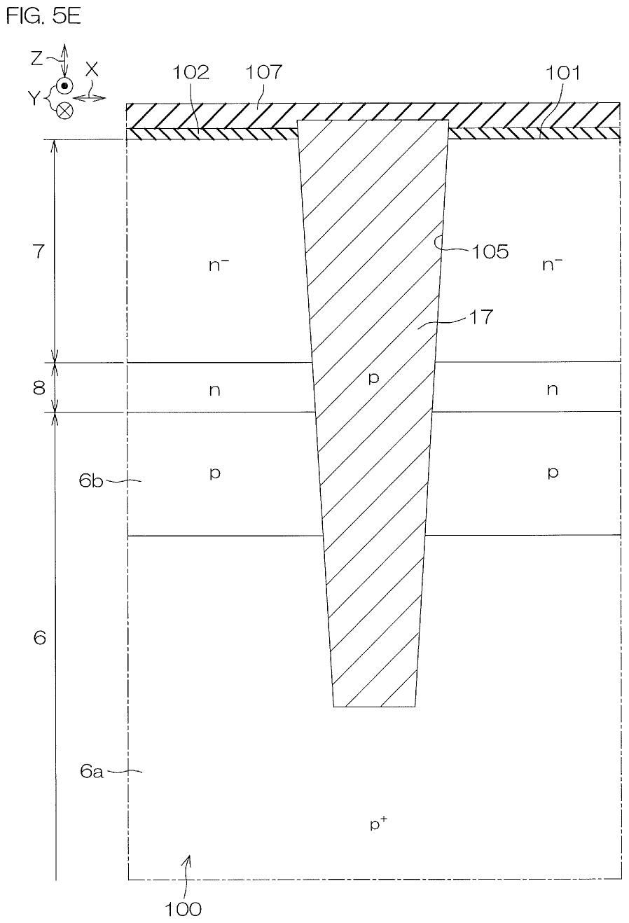

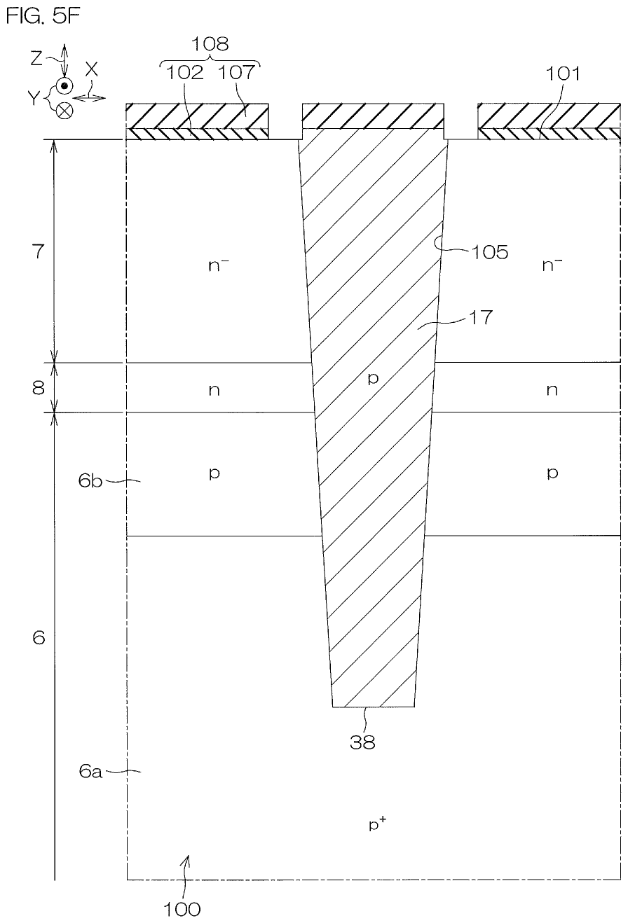

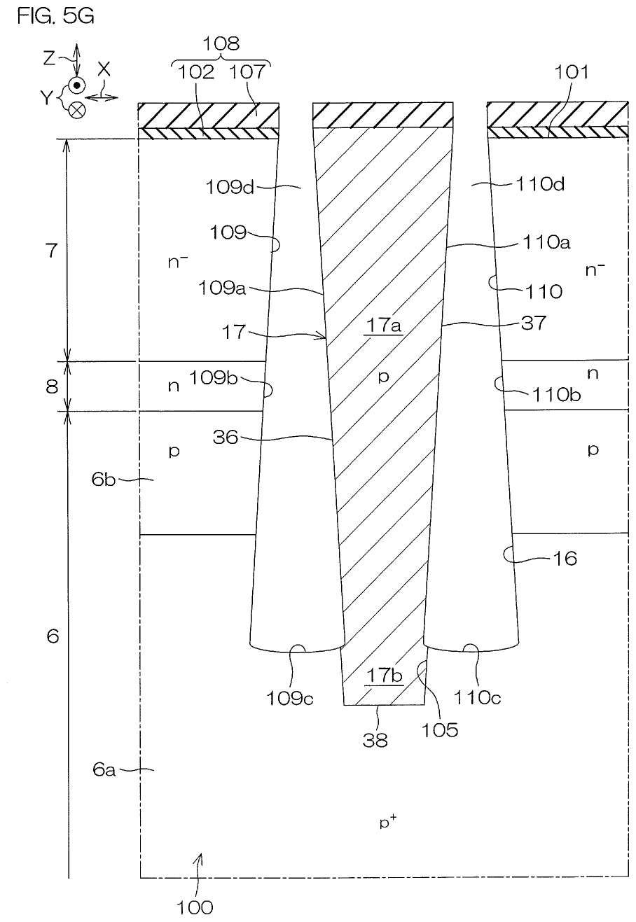

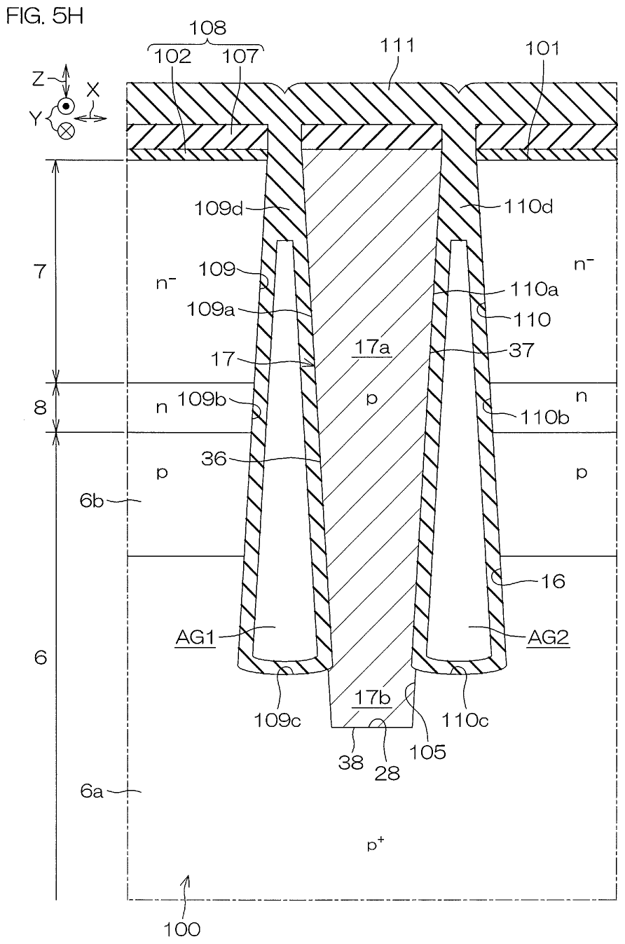

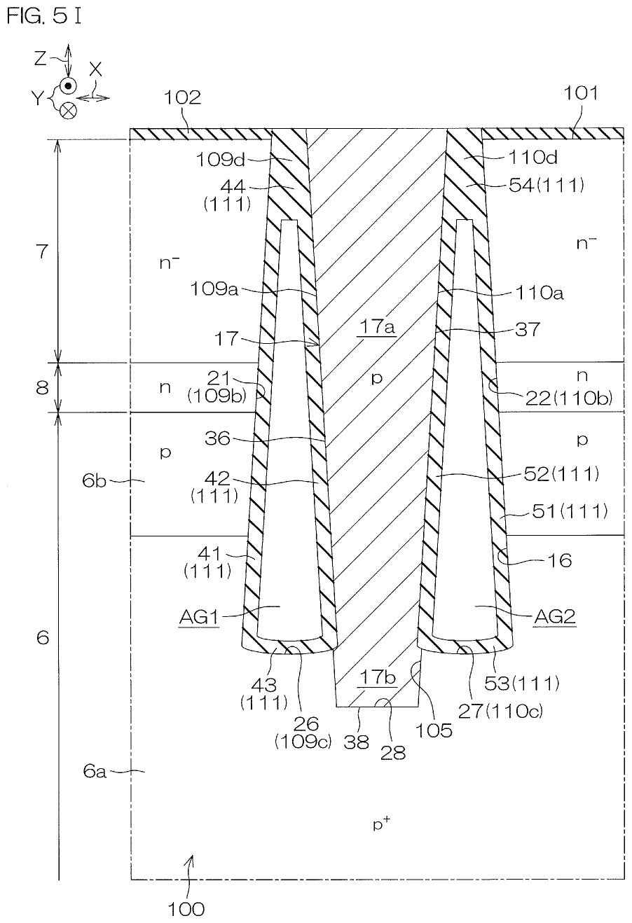

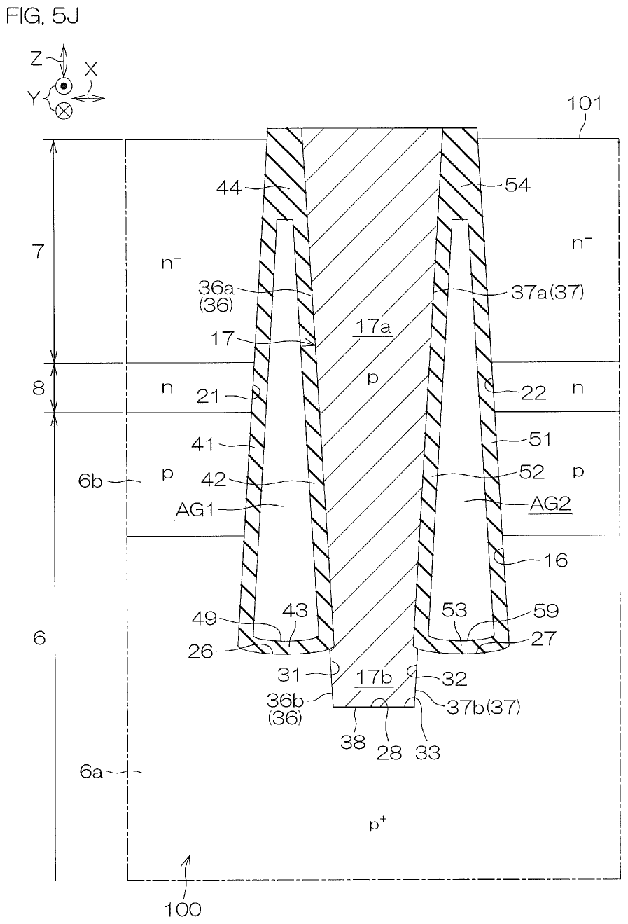

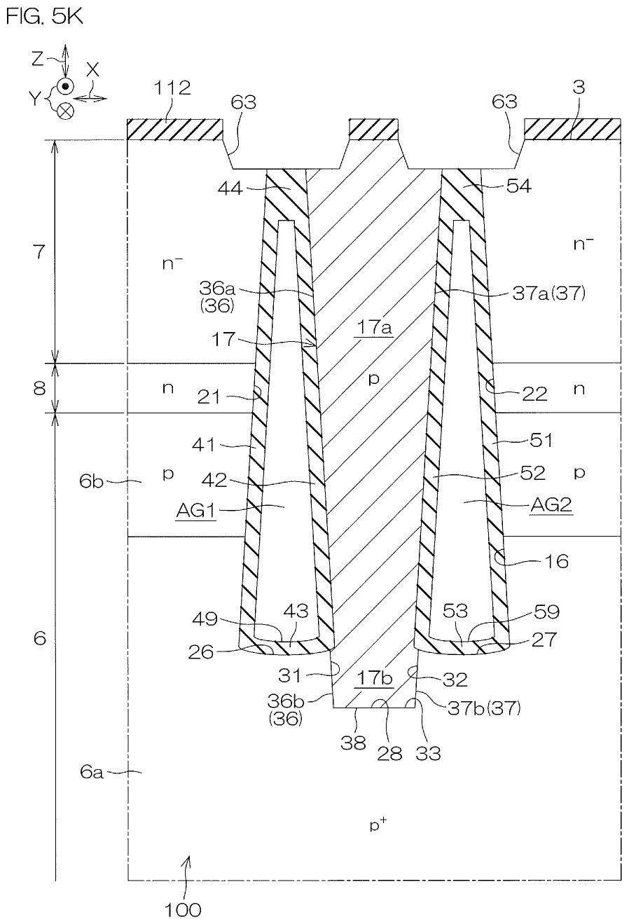

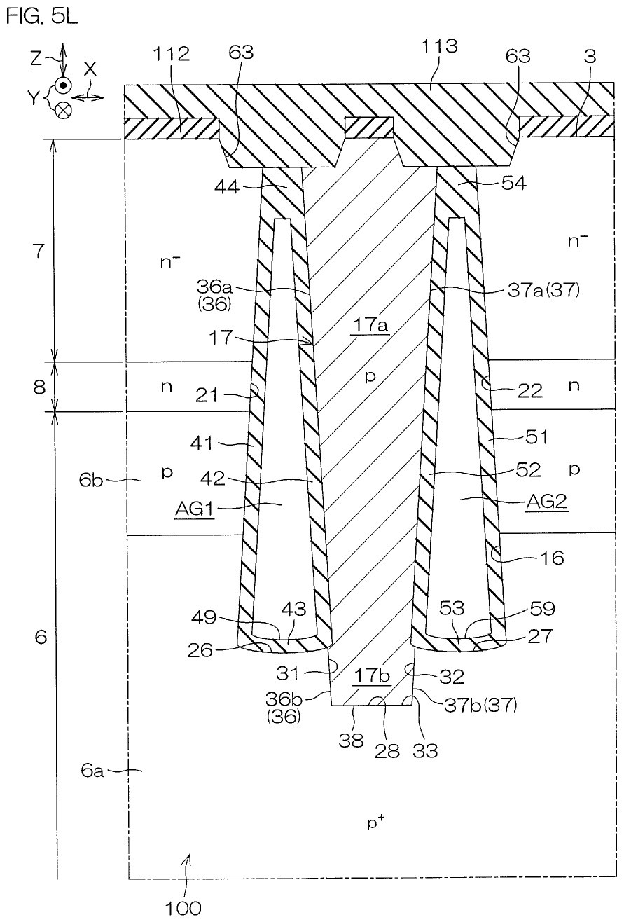

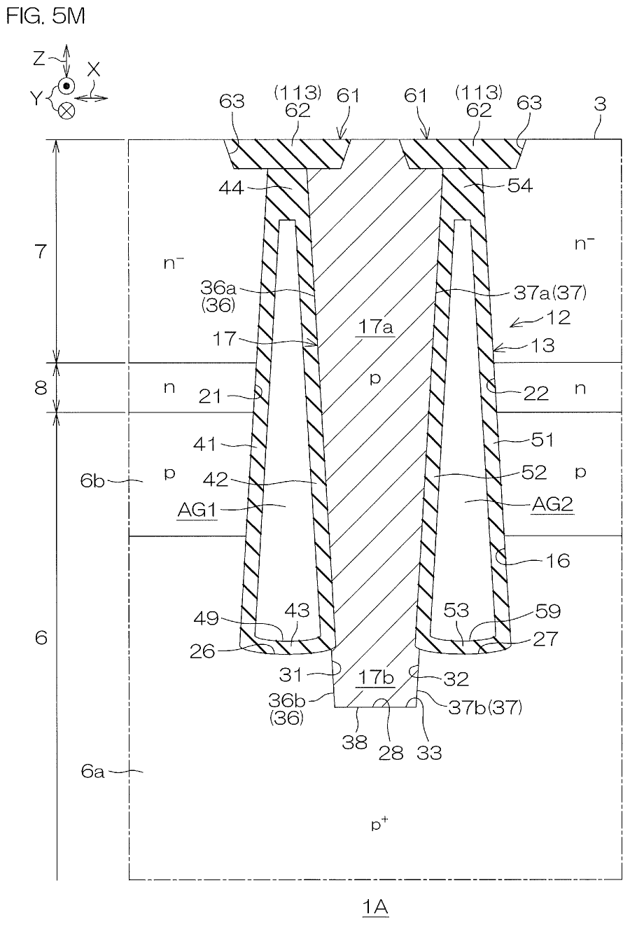

FIG. 5A to FIG. 5M are views shown to describe a process of manufacturing the semiconductor device 1A according to the first embodiment of the present disclosure, and are longitudinal sectional views of a part corresponding to FIG. 4.

Referring to FIG. 5A, a semiconductor wafer 100 that serves as a base of the semiconductor chip 2 is prepared to manufacture the semiconductor device 1A. The semiconductor wafer 100 has a surface 101. The semiconductor wafer 100 includes the first impurity region 6, the second impurity region 7, and the buried region 8. The first impurity region 6 includes the high concentration region 6a and the low concentration region 6b. The high concentration region 6a is made of a p-type semiconductor substrate. The low concentration region 6b is made of a p-type epitaxial layer laminated on a semiconductor substrate by means of an epitaxial growth method.

Next, referring to FIG. 5B, a first mask 102 and a second mask 103 are laminated in that order on the surface 101 of the semiconductor wafer 100. The first mask 102 may be a silicon nitride film. The first mask 102 may be formed by a CVD method. The second mask 103 may be silicon oxide (SiO₂). The second mask 103 may be formed by the CVD method. The first mask 102 and the second mask 103 are selectively removed by an etching method, and, as a result, the first mask 102 and the second mask 103 become a first hard mask 104. The first hard mask 104 exposes a region in which a first trench 105 is to be formed, and covers regions other than this region in the surface 101.

Next, the semiconductor wafer 100 is selectively removed by the etching method through the first hard mask 104. Hence, the first trench 105 is formed in the surface 101 of the semiconductor wafer 100 (first step). The first trench 105 penetrates through the second impurity region 7, through the buried region 8, and through the low concentration region 6b, and exposes the high concentration region 6a. The first trench 105 is formed in a tapered shape whose width becomes larger from the bottom portion toward the surface 101 in a cross-sectional view. The etching method may be a dry etching method and/or wet etching method.

Next, referring to FIG. 5C, a polysilicon material 106 that serves as abase of the buried conductor 17 is deposited on the surface 101 through the first mask 102 and the second mask 103. In this embodiment, the polysilicon material 106 includes doped-polysilicon to which p-type (first conductivity type) impurities have been added. The deposition of the polysilicon material 106 is continuously performed until the first trench 105 is completely filled. The deposition of the polysilicon material 106 may be performed by the CVD method.

Next, referring to FIG. 5D, unnecessary portions of the polysilicon material 106 that has been deposited are removed. This step includes a step of removing the polysilicon material 106 by means of a grinding method until the second mask 103 is exposed. The grinding method may be a CMP (chemical mechanical polishing) method. Hence, the buried conductor 17 is formed by the polysilicon material 106 remaining in the first trench 105 (second step). Of course, in this step, the etching method (wet etching method and/or dry etching method) may be employed instead of the grinding method.

Next, referring to FIG. 5E, the second mask 103 is removed by the etching method (wet etching method). Hence, the first mask 102 is exposed.

Next, a third mask 107 is laminated on the first mask 102 and on the buried conductor 17. The third mask 107 may be silicon oxide (SiO₂). The third mask 107 may be formed by the CVD method.

Next, referring to FIG. 5F, the first mask 102 and the third mask 107 are selectively removed by the etching method, and, as a result, the first mask 102 and the third mask 107 become a third hard mask 108. The third hard mask 108 exposes regions in which a second trench 109 and a third trench 110 are to be formed, and covers regions other than these regions in the surface 101.

Next, referring to FIG. 5G, the semiconductor wafer 100 is selectively removed by the etching method through the third hard mask 108. Hence, the second trench 109 and the third trench 110 are formed on a lateral side of the buried conductor 17 in the surface 101 of the semiconductor wafer 100 (third step). The etching method may be a dry etching method.

The second trench 109 and the third trench 110 are formed in a tapered shape whose width becomes smaller from the bottom portion toward the surface 101 in a cross-sectional view. The second trench 109 and the third trench 110 are formed at a shallower depth than the first trench 105. At least either one of an etching temperature in the etching method and a flow rate of etching gas in the etching method is regulated, and, as a result, the second trench 109 and the third trench 110 are formed in a tapered shape whose width becomes smaller from the bottom portion toward the surface 101.

The second trench 109 includes a first side surface 109a, a second side surface 109b, and a bottom surface 109c. The first side surface 109a is formed by an upper part of the sidewall 36 of the buried conductor 17. The first side surface 109a is formed as an inclined surface (inclined surface with respect to the surface 101 of the semiconductor wafer 100) that approaches the second side surface 109b side in proportion to an approach to an open portion 109d from the bottom surface 109c. The sidewall 36 of the buried conductor 17 is exposed to the first side surface 109a.

The second side surface 109b is formed in the second impurity region 7, the buried region 8, the low concentration region 6b, and the high concentration region 6a. The second side surface 109b is formed as an inclined surface (inclined surface with respect to the surface 101 of the semiconductor wafer 100) that approaches the first side surface 109a side in proportion to an approach to the open portion 109d from the bottom surface 109c. The bottom surface 109c is formed in the high concentration region 6a. The bottom surface 109c has a round shape that swells toward the second principal surface 4 side in a cross-sectional view.

The third trench 110 includes a first side surface 110a, a second side surface 110b, and a bottom surface 110c. The first side surface 110a is formed by an upper part in the sidewall 37 of the buried conductor 17. The first side surface 110a is formed as an inclined surface (inclined surface with respect to the surface 101 of the semiconductor wafer 100) that approaches the second side surface 109b side in proportion to an approach to an open portion 110d from the bottom surface 110c. The sidewall 37 of the buried conductor 17 is exposed to the first side surface 110a.

The second side surface 110b is formed in the second impurity region 7, the buried region 8, the low concentration region 6b, and the high concentration region 6a. The second side surface 110b is formed as an inclined surface (inclined surface with respect to the surface 101 of the semiconductor wafer 100) that approaches the first side surface 110a side in proportion to an approach to the open portion 110d from the bottom surface 110c. The bottom surface 110c is formed in the high concentration region 6a. The bottom surface 110c has a round shape that swells toward the second principal surface 4 side in a cross-sectional view.

Next, referring to FIG. 5H, a first insulating material 111 that serves as a base of the first insulating film 41, 51, a base of the second insulating film 42, 52, a base of the third insulating film 43, 53, and a base of the upper insulating film 44, 54 is deposited on the surface 101 through the third hard mask 108. The first insulating material 111 may be silicon oxide (SiO₂), or may be tetraethyl orthosilicate (TEOS). The deposition of the first insulating material 111 is continuously performed until the open portion 109d of the second trench 109 and the open portion 110d of the third trench 110 are completely filled. In this embodiment, the deposition of the first insulating material 111 may be performed by the CVD method.

In the second trench 109, the width of the halfway portion in the depth direction of the second trench 109 is larger than the width of the open portion 109d of the second trench 109. Therefore, it is impossible to completely fill the whole area of the internal space of the second trench 109 with the first insulating material 111. Therefore, the air gap AG1 is formed at the central portion of the internal space of the second trench 109 in a cross-sectional view. The first side surface 109a, the second side surface 109b, and the bottom surface 109c of the second trench 109 are covered by the first insulating material 111. Additionally, the open portion 109d of the second trench 109 is filled with the first insulating material 111.

Likewise, in the third trench 110, the width of the halfway portion in the depth direction of the third trench 110 is larger than the width of the open portion 110d of the third trench 110. Therefore, it is impossible to completely fill the whole area of the internal space of the third trench 110 with the first insulating material 111. Therefore, the air gap AG2 is formed at the central portion of the internal space of the third trench 110 in a cross-sectional view. The first side surface 110a, the second side surface 110b, and the bottom surface 110c of the third trench 110 are covered by the first insulating material 111. The open portion 110d of the third trench 110 is filled with the first insulating material 111.

Next, referring to FIG. 5I, unnecessary portions of the first insulating material 111 that have been deposited are removed. This step includes a step of removing the first insulating material 111 and the third hard mask 108 by means of a grinding method until the first mask 102 is exposed. The grinding method may be a CMP (chemical mechanical polishing) method. Of course, in this step, the etching method (wet etching method and/or dry etching method) may be employed instead of the grinding method.

The first insulating material 111 covering the first side surface 109a, the second side surface 109b, and the bottom surface 109c and the first insulating material 111 with which the open portion 109d is filled become the first insulating film 41, the second insulating film 42, the third insulating film 43, and the upper insulating film 44, respectively. Hence, the first insulating film 41 and the second insulating film 42 facing each other across the air gap AG1 are formed (fourth step).

Additionally, the first insulating material 111 covering the first side surface 110a, the second side surface 110b, and the bottom surface 110c and the first insulating material 111 with which the open portion 110d is filled become the first insulating film 51, the second insulating film 52, the third insulating film 53, and the upper insulating film 54, respectively. Hence, the first insulating film 51 and the second insulating film 52 facing each other across the air gap AG2 are formed (fourth step).

The trench 16 is formed by the first trench 105, the second trench 109, and the third trench (second trench) 110. The second side surface 109b and the bottom surface 109c of the second trench 109 become the first side surface 21 and the first lateral bottom surface 26 of the trench 16, respectively. The second side surface 110b and the bottom surface 110c of the third trench 110 become the second side surface 22 and the second lateral bottom surface 27 of the trench 16, respectively. In the first trench 105, a part that is deeper than the bottom surface 109c of the second trench 109 and than the bottom surface 110c of the third trench 110 becomes the central bottom surface 28 of the trench 16.

Next, referring to FIG. 5J, the first mask 102 is removed from the surface 101 of the semiconductor wafer 100 by means of the etching method.

Next, referring to FIG. 5K, a fourth mask 112 is laminated on the surface 101 of the semiconductor wafer 100, the upper insulating films 44 and 54, and the buried conductor 17. The fourth mask 112 exposes a region in which the shallow trench 62 is to be formed, and covers regions other than this region in the surface 101.

Next, referring to FIG. 5K, the semiconductor wafer 100, the upper insulating films 44 and 54, and the buried conductor 17 are each selectively removed by the etching method through the fourth mask 112. Hence, the shallow trenches 62 are formed. Thereafter, the fourth mask 112 may be removed. The etching method may be a dry etching method and/or a wet etching method.

Next, referring to FIG. 5L, a second insulating material 113 that serves as a base of the buried insulator 63 is formed on the surface 101. The second insulating material 113 may be the same as the first insulating material 111. The second insulating material 113 may be silicon oxide (SiO₂), or may be tetraethyl orthosilicate (TEOS). The deposition of the second insulating material 113 is continuously performed until the shallow trench 62 is completely filled. The deposition of the second insulating material 113 may be performed by the CVD method.

Next, referring to FIG. 5M, unnecessary portions of the second insulating material 113 are removed. In this step, the second insulating material 113 is removed by the grinding method until the surface 101 is exposed. The grinding method may be a CMP (chemical mechanical polishing) method. Hence, the buried insulator 63 is formed by the second insulating material 113 remaining in the shallow trench 62. Of course, in this step, the etching method (wet etching method and/or dry etching method) may be employed instead of the grinding method.

Additionally, a functional device, such as the MISFET cell 70, is formed on the surface 101 of the semiconductor wafer 100. Hence, the active region 11 is formed at the surface 101 of the semiconductor wafer 100. The semiconductor device 1A is formed through these steps including the above.

According to the semiconductor device 1A according to the first embodiment of the present disclosure, the first trench structure 13 included in the element isolation portion 12 includes the trench 16 and the buried conductor 17 buried in the trench 16. In the trench 16, the first insulating films 41 and 51 formed on the side surfaces 21 and 22 of the trench 16 and the second insulating films 42 and 52 covering the sidewalls 36 and 37 of the buried conductor 17 are formed across the air gaps AG1 and AG2. This makes it possible to electrically excellently insulate the buried conductor 17 from the active region 11 by means of the first insulating films 41 and 51 and the second insulating films 42 and 52.

Additionally, the air gaps AG1 and AG2 are formed so as to be sandwiched between the buried region 8 and the buried conductor 17 in the lateral direction along the first principal surface 3. There is a concern that the withstand voltage of the semiconductor device 1A might be reduced if electric field concentration occurs in a part between the buried region 8 and the buried conductor 17 in the side surfaces 21 and 22 of the trench 16. The air gaps AG1 and AG2 are formed so as to be sandwiched between the buried region 8 and the buried conductor 17. This makes it possible to lessen the electric field concentration. Therefore, it is possible to improve the withstand voltage in the lateral direction along the first principal surface 3 of the semiconductor chip 2.

Additionally, the buried conductor 17, the first insulating films 41 and 51, and the second insulating films 42 and 52 are formed in the same trench 16, and therefore it is possible to make the width of the first trench structure 13 smaller than in a case in which the first insulating films 41 and 51 and the second insulating films 42 and 52 are formed in mutually different trenches. This makes it possible to make the semiconductor device 1A small in size.

For example, as is disclosed by the above Patent Literature 1, it is known to bury an electroconductive buried body (polysilicon) in a trench with an insulating film covering a side surface of the trench between the buried body and the trench. In this case, it is conceivable to lessen the aforementioned electric field concentration by increasing the thickness of the insulating film formed between the electroconductive embedded body and the trench in sidewalls of the trench. However, in this case, the thickness of the insulating film is increased, and hence there is no escape-way of stress in the insulating film. Therefore, there is a concern that a crystal defect might occur in the insulating film.

In contrast, in this embodiment, the first insulating films 41 and 51 and the second insulating films 42 and 52 are formed across the air gaps AG1 and AG2, respectively, and therefore it is possible to escape the stress generated in the insulating films 41, 42, 51, and 52 to the air gaps AG1 and AG2. Hence, it is possible to prevent the occurrence of crystal defects in the insulating films 41, 42, 51, and 52. Therefore, it is possible to lessen the aforementioned electric field concentration while preventing the occurrence of crystal defects.

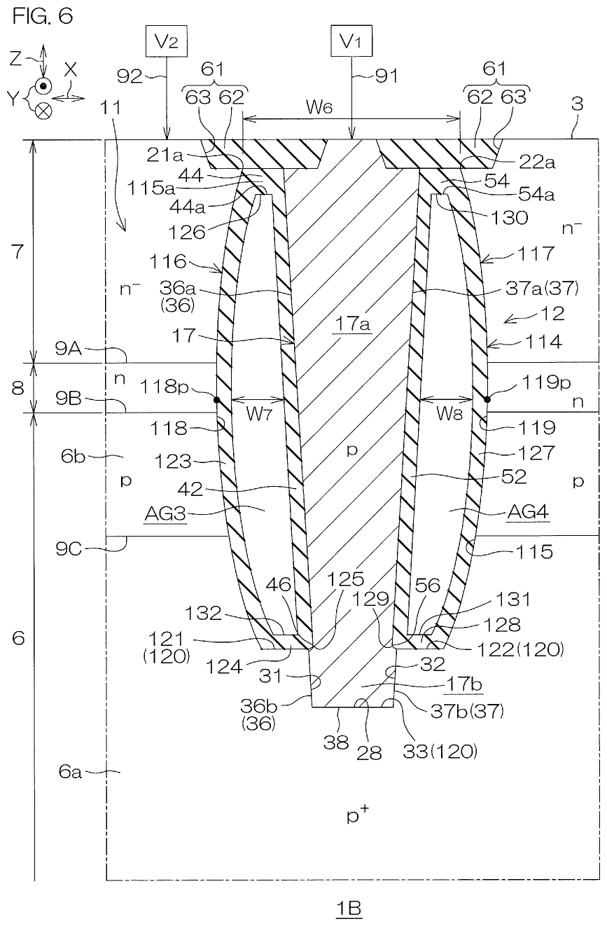

FIG. 6 corresponds to FIG. 4, and is a cross-sectional enlarged view of a main portion of a semiconductor device 1B according to a second embodiment of the present disclosure. In the second embodiment, only a part chiefly different from the first embodiment will be described, and the same reference sign is assigned to a constituent that is the same as the constituent described above, and a description of the same constituent is omitted.

The element isolation portion 12 according to the second embodiment includes a first trench structure 114 instead of the first trench structure 13. The first trench structure 114 includes a trench 115, a first insulating portion 116, and a second insulating portion 117. The buried conductor 17 is buried in the trench 115.

The trench 115 includes a first side surface (side surface, side surface on one side) 118 on the active region 11 side, a second side surface (side surface, side surface on the other side) 119 on the side opposite to the active region 11 side, and a bottom surface 120. The first side surface 118 and the second side surface 119 are each formed in an arched shape that is convex outwardly from the trench 115 in a cross-sectional view. The trench 115 differs from the trench 16 chiefly in this respect.

The trench 115 has a sixth width W₆ in open ends 118a and 119a. The sixth width W₆ is a width in a direction perpendicular to a direction in which the trench 115 extends in a plan view. The sixth width W₆ may be not less than 0.5 μm and not more than 10 μm. Preferably, the sixth width W₆ is not less than 2 μm and not more than 4 μm.

The first side surface 118 of the trench 115 is formed so as to straddle the second impurity region 7, the buried region 8, the low concentration region 6b, and the high concentration region 6a. The first side surface 118 is contiguous to the second impurity region 7, the buried region 8, the low concentration region 6b, and the high concentration region 6a. The first side surface 118 is formed in an arched shape that is convex outwardly from the trench 115 (toward the active region 11 side) in a cross-sectional view. In other words, the first side surface 118 has a shape in which a halfway portion in the depth direction of the trench 115 is convex more outwardly from the trench 115 (active region 11 side) than the open end 118a in a cross-sectional view. A top portion 118p of the first side surface 118 is formed at a central portion in the depth direction of the trench 115. The top portion 118p of the first side surface 118 is sandwiched between the buried region 8 and the buried conductor 17.

The second side surface 119 of the trench 115 is formed so as to straddle the second impurity region 7, the buried region 8, the low concentration region 6b, and the high concentration region 6a. The second side surface 119 is contiguous to the second impurity region 7, the buried region 8, the low concentration region 6b, and the high concentration region 6a. The second side surface 119 is formed in an arched shape that is convex outwardly from the trench 115 (toward the side opposite to the active region 11 side) in a cross-sectional view. In other words, the second side surface 119 has a shape in which the halfway portion in the depth direction of the trench 115 is convex more outwardly from the trench 115 (toward the side opposite to the active region 11 side) than the open end 119a in a cross-sectional view. A top portion 119p of the second side surface 119 is formed at the central portion in the depth direction of the trench 115. The top portion 119p of the second side surface 119 is sandwiched between the buried region 8 and the buried conductor 17.

The bottom surface 120 includes a first bottom surface 121, a second bottom surface 122, and the central bottom surface 28. The central bottom surface 28 connects the first bottom surface 121 and the second bottom surface 122. The first bottom surface 121 is formed on the active region 11 side with respect to the central bottom surface 28. The second bottom surface 122 is formed on the side opposite to the first bottom surface 121 with respect to the central bottom surface 28. The first bottom surface 121 and the second bottom surface 122 are placed such that the central bottom surface 28 is sandwiched between the first bottom surface 121 and the second bottom surface 122 in the direction perpendicular to the direction in which the trench 115 extends in a plan view.

The first bottom surface 121 extends along the direction in which the trench 115 extends. The first bottom surface 121 is formed in the high concentration region 6a. The first bottom surface 121 is contiguous to the high concentration region 6a. The first bottom surface 121 may have a flat surface parallel to the first principal surface 3. The first bottom surface 121 may have a round shape that swells toward the second principal surface 4 side in a cross-sectional view. The width of the first bottom surface 121 is narrower than the groove width of the central bottom surface 28.

The second bottom surface 122 extends along the direction in which the trench 115 extends. The second bottom surface 122 is formed in the high concentration region 6a. The second bottom surface 122 is contiguous to the high concentration region 6a. The second bottom surface 122 may have a flat surface parallel to the first principal surface 3. The second bottom surface 122 may have a round shape that swells toward the second principal surface 4 side in a cross-sectional view. The width of the second bottom surface 122 is narrower than the groove width of the central bottom surface 28. The second bottom surface 122 is placed at the same depth position as the first bottom surface 121.

The first trench structure 114 includes the first insulating portion 116. The first insulating portion 116 insulates the buried conductor 17 and the first side surface 118 of the trench 115 in the trench 115. The first insulating portion 116 includes a first insulating film 123, the second insulating film 42, a third insulating film 124, the upper insulating film 44, and an air gap AG3. The buried conductor 17 and a region on the active region 11 side with respect to the first trench structure 114 are electrically insulated by the first insulating portion 116.

The first insulating portion 116 differs from the first insulating portion 18 in the point that the first insulating portion 116 includes the first insulating film 123 and the third insulating film 124 instead of the first insulating film 41 and the third insulating film 43, respectively.

The first insulating film 123 is formed on the first side surface 118 of the trench 115. The first insulating film 123 covers the first side surface 118 of the trench 115. The first insulating film 123 has a shape that follows the first side surface 118. In other words, the first insulating film 123 is formed in an arched shape that is convex outwardly from the trench 115 (toward the active region 11 side) in a cross-sectional view. The first insulating film 123 may be an oxide film. The oxide film may be silicon oxide (SiO₂), or may be tetraethyl orthosilicate (TEOS).

The third insulating film 124 covers the first bottom surface 121 of the trench 115. The third insulating film 124 is flat and is parallel to the first principal surface 3. The third insulating film 124 may be an oxide film. The oxide film may be silicon oxide (SiO₂), or may be tetraethyl orthosilicate (TEOS). In the example of FIG. 6, an inner end 125 (end portion on the side opposite to the active region 11 side) of the third insulating film 124 is located on a more inward side (side opposite to the active region 11 side) than the first groove side surface 31 of the central bottom surface 28. The inner end 125 is fitted to the stepped portion 46 formed at the first sidewall 36 of the buried conductor 17.

The upper insulating film 44 connects the first insulating film 123 and the second insulating film 42 in an upper portion 115a of the trench 115.

The air gap AG3 is a sealed space demarcated by the first insulating film 123, by the second insulating film 42, by the third insulating film 124, and by the upper insulating film 44, and houses air in the inside. The air gap AG3 is sandwiched in the direction perpendicular to the direction in which the trench 115 extends in a plan view. In other words, the second insulating film 42 is formed inside the trench 115 inwardly from the first insulating film 123 (side opposite to the active region 11 side) with the air gap AG3 between the second insulating film 42 and the first insulating film 123.

The air gap AG3 is formed so as to be interposed among the buried conductor 17, the second impurity region 7, the buried region 8, the low concentration region 6b, and the high concentration region 6a. In detail, the air gap AG3 is sandwiched between the buried conductor 17 and the buried region 8. The air gap AG3 is sandwiched between the buried conductor 17 and the low concentration region 6b.

The air gap AG3 is formed in a substantially semicylindrical shape that is convex outwardly (toward the active region 11 side) in a cross-sectional view. The air gap AG3 is sandwiched in the direction perpendicular to the direction in which the trench 115 extends in a plan view. In other words, the second insulating film 42 is formed inside the trench 115 inwardly from the first insulating film 123 (side opposite to the active region 11 side) with the air gap AG3 between the second insulating film 42 and the first insulating film 123. The air gap AG3 has a seventh width W₇. The seventh width W₇ is a width in the direction perpendicular to the direction in which the trench 115 extends in a depth position corresponding to the top portion 118p in a plan view. The seventh width W₇ may be 1/300 to ½ times as large as the depth of the trench 115.

In this embodiment, the air gap AG3 is sandwiched between the buried conductor 17 and the buried region 8. In this embodiment, the air gap AG3 is sandwiched between the buried conductor 17 and the low concentration region 6b.

In the example of FIG. 6, the distance between an upper end 126 of the air gap AG3 and the first principal surface 3 is shorter than the distance between the upper end 126 of the air gap AG3 and the boundary part 9A between the buried region 8 and the second impurity region 7. The distance between the upper end 126 and the first principal surface 3 may be longer than the distance between the upper end 126 and the boundary part 9A.

The first trench structure 114 includes the second insulating portion 117 as described above. The second insulating portion 117 insulates the buried conductor 17 and the second side surface 119 of the trench 115 in the trench 115. The second insulating portion 117 includes a first insulating film 127, the second insulating film 52, a third insulating film 128, the upper insulating film 54, and an air gap AG4. The buried conductor 17 and a region on the side opposite to the active region 11 side with respect to the first trench structure 114 are electrically insulated by the second insulating portion 117.

The second insulating portion 117 differs from the second insulating portion 19 in the point that it includes the first insulating film 127 and the third insulating film 128 instead of the first insulating film 51 and the third insulating film 53, respectively.

The first insulating film 127 is formed on the second side surface 119 of the trench 115. The first insulating film 127 covers the second side surface 119 of the trench 115. The first insulating film 127 has a shape that follows the second side surface 119. In other words, the first insulating film 127 is formed in an arched shape that is convex outwardly from the trench 115 (toward the side opposite to the active region 11 side) in a cross-sectional view. The first insulating film 127 may be an oxide film. The oxide film may be silicon oxide (SiO₂), or may be tetraethyl orthosilicate (TEOS).

The third insulating film 128 covers the second bottom surface 122 of the trench 115. The third insulating film 128 is flat and is parallel to the first principal surface 3. The third insulating film 128 may be an oxide film. The oxide film may be silicon oxide (SiO₂), or may be tetraethyl orthosilicate (TEOS). In the example of FIG. 6, an inner end 129 (end portion on the active region 11 side) of the third insulating film 128 is located on a more inward side (active region 11 side) than the second groove side surface 32 of the central bottom surface 28. The stepped portion 56 that demarcates the upper part 37a and the lower part 37b is formed at the second sidewall 37 of the buried conductor 17. The inner end 129 is fitted to the stepped portion 56.

The upper insulating film 54 connects the first insulating film 127 and the second insulating film 52 in the upper portion 115a of the trench 115.

The air gap AG4 is a sealed space demarcated by the first insulating film 127, by the second insulating film 52, by the third insulating film 128, and by the upper insulating film 54, and houses air in the inside. The air gap AG4 is sandwiched in the direction perpendicular to the direction in which the trench 115 extends in a plan view. In other words, the second insulating film 52 is formed inside the trench 115 inwardly from the first insulating film 127 (the active region 11 side) with the air gap AG4 between the second insulating film 52 and the first insulating film 127. The air gap AG4 has an eighth width W₈. The eighth width W₈ is a width in the direction perpendicular to the direction in which the trench 115 extends in a depth position corresponding to the top portion 118p in a plan view. The eighth width W₈ may be 1/300 to ½ times as large as the depth of the trench 115.

The air gap AG4 is formed so as to be interposed among the buried conductor 17, the second impurity region 7, the buried region 8, the low concentration region 6b, and the high concentration region 6a. In detail, the air gap AG4 is sandwiched between the buried conductor 17 and the buried region 8. The air gap AG4 is sandwiched between the buried conductor 17 and the low concentration region 6b.

In the example of FIG. 6, the distance between an upper end 130 of the air gap AG4 and the first principal surface 3 is shorter than the distance between the upper end 130 of the air gap AG4 and the boundary part 9A between the buried region 8 and the second impurity region 7. The distance between the upper end 130 and the first principal surface 3 may be longer than the distance between the upper end 130 and the boundary part 9A.

In the example of FIG. 6, a lower end 131 of the air gap AG4 is located closer to the second principal surface 4 side than the boundary part 9B between the buried region 8 and the first impurity region 6. In this embodiment, the lower end 131 of the air gap AG4 is located closer to the second principal surface 4 side than the boundary part 9C between the low concentration region 6b and the high concentration region 6a. The amount of protrusion of the lower end 131 from the boundary part 9C is the same as the amount of protrusion of a lower end 132 from the boundary part 9C. The lower end 131 of the air gap AG4 is located closer to the first principal surface 3 side than the bottom wall 38 of the buried conductor 17.

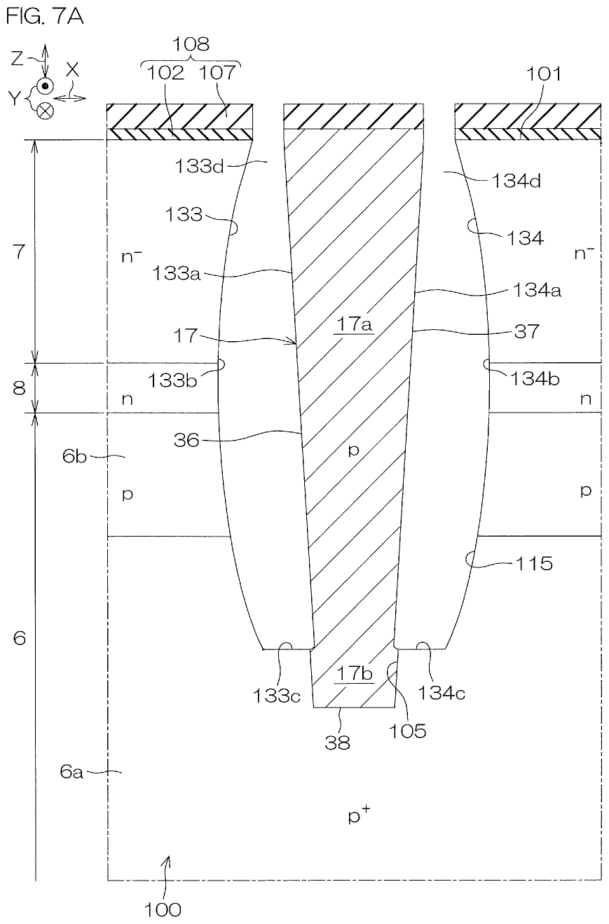

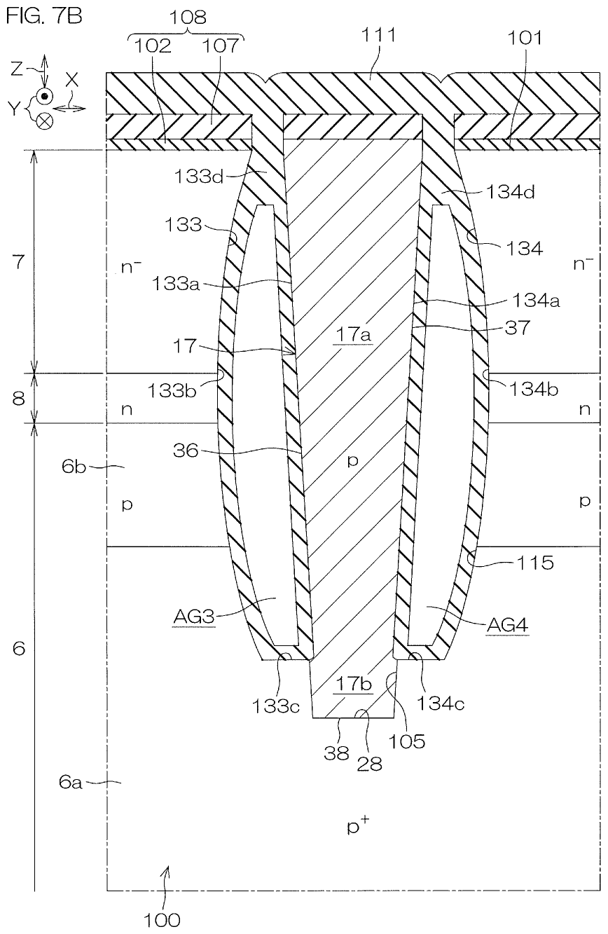

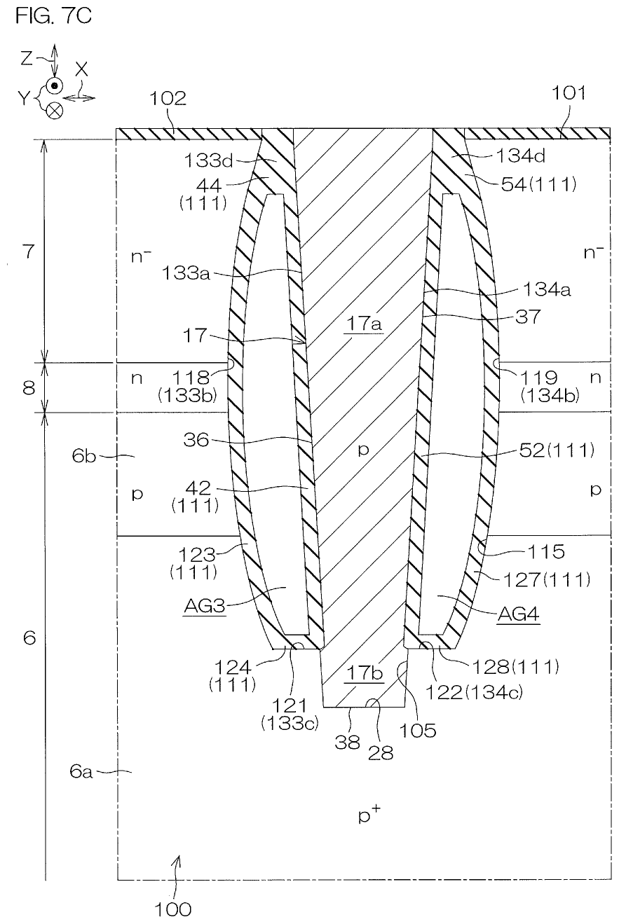

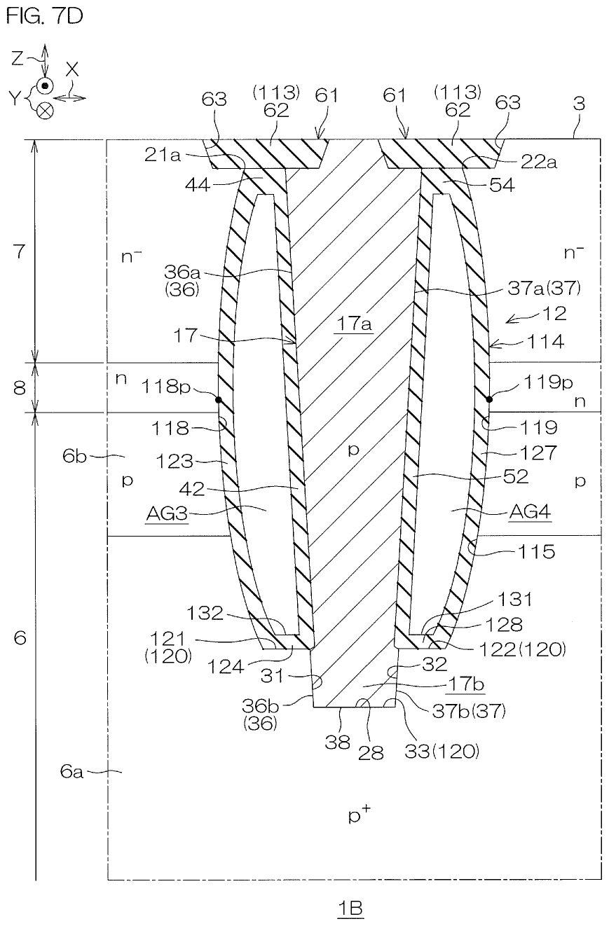

FIG. 7A to FIG. 7D are views shown to describe a process of manufacturing the semiconductor device 1B according to the second embodiment of the present disclosure, and are longitudinal sectional views of a part corresponding to FIG. 6.

The manufacturing process of the semiconductor device 1B is partially in common with the manufacturing process of the semiconductor device 1A. In the manufacturing process of the semiconductor device 1B, the steps shown in FIG. 5A to FIG. 5F of the manufacturing process of the semiconductor device 1A are first performed. A description of the steps shown in FIG. 5A to FIG. 5F has already been ended, and therefore the description of these steps is omitted.

Subsequently to the steps shown in FIG. 5A to FIG. 5F, referring to FIG. 7A, the third hard mask 108 exposes regions in which a second trench 133 and a third trench 134 are to be formed, and covers regions other than these regions in the surface 101. The semiconductor wafer 100 is selectively removed by the etching method through the third hard mask 108. Hence, the second trench 133 and the third trench 134 are formed on a lateral side of the buried conductor 17 in the surface 101 of the semiconductor wafer 100 (third step). The etching method may be a dry etching method.

The second trench 133 and the third trench (second trench) 134 are formed at a shallower depth than the first trench 105.

The second trench 133 includes a first side surface 133a, a second side surface 133b, and a bottom surface 133c. The first side surface 133a is formed by an upper part of the sidewall 36 of the buried conductor 17. The first side surface 133a is formed as an inclined surface (inclined surface with respect to the surface 101 of the semiconductor wafer 100) that approaches the second side surface 133b side in proportion to an approach to an open portion 133d from the bottom surface 133c. The sidewall 36 of the buried conductor 17 is exposed to the first side surface 133a.

The second side surface 133b is formed in the second impurity region 7, the buried region 8, the low concentration region 6b, and the high concentration region 6a. The second side surface 133b is formed in an arched shape that is convex toward the side opposite to the buried conductor 17 side in a cross-sectional view. The bottom surface 133c is formed in the high concentration region 6a. The bottom surface 133c may have a flat surface parallel to the first principal surface 3.

The third trench 134 includes a first side surface 134a, a second side surface 134b, and a bottom surface 134c. The first side surface 134a is formed by an upper part of the sidewall 37 of the buried conductor 17. The first side surface 134a is formed as an inclined surface (inclined surface with respect to the surface 101 of the semiconductor wafer 100) that approaches the second side surface 134b side in proportion to an approach to an open portion 134d from the bottom surface 134c. The sidewall 36 of the buried conductor 17 is exposed to the first side surface 134a.

The second side surface 134b is formed in the second impurity region 7, the buried region 8, the low concentration region 6b, and the high concentration region 6a. The second side surface 134b is formed in an arched shape that is convex toward the side opposite to the buried conductor 17 side in a cross-sectional view. The bottom surface 134c is formed in the high concentration region 6a. The bottom surface 133c may have a flat surface parallel to the first principal surface 3.

Next, referring to FIG. 7B, the first insulating material 111 that serves as a base of the first insulating film 123, 127, a base of the second insulating film 42, 52, a base of the third insulating film 124, 128, and a base of the upper insulating film 44, 54 is deposited on the surface 101 through the third hard mask 108 including the first mask 102 and the third mask 107. The first insulating material 111 may be silicon oxide (SiO₂), or may be tetraethyl orthosilicate (TEOS). The deposition of the first insulating material 111 is continuously performed until the open portion 133d of the third trench 134 and the open portion 134d of the third trench 134 are completely filled. In this embodiment, the deposition of the first insulating material 111 may be performed by the CVD method.

In the second trench 133, the width of the halfway portion in the depth direction of the second trench 133 is larger than the width of the open portion 133d of the second trench 133. Therefore, it is impossible to completely fill the whole area of the internal space of the second trench 133 with the first insulating material 111. Therefore, the air gap AG3 is formed at the central portion of the internal space of the second trench 133 in a cross-sectional view. The first side surface 133a, the second side surface 133b, and the bottom surface 133c of the second trench 133 are covered by the first insulating material 111. Additionally, the open portion 133d of the second trench 133 is filled with the first insulating material 111.

Likewise, in the third trench 134, the width of the halfway portion in the depth direction of the third trench 134 is larger than the width of the open portion 134 of the third trench 134. Therefore, it is impossible to completely fill the whole area of the internal space of the third trench 134 with the first insulating material 111. Therefore, the air gap AG4 is formed at the central portion of the internal space of the third trench 134 in a cross-sectional view. The first side surface 134a, the second side surface 134b, and the bottom surface 134c of the third trench 134 are covered by the first insulating material 111. Additionally, the open portion 134d of the third trench 134 is filled with the first insulating material 111.

Next, referring to FIG. 7C, unnecessary portions of the first insulating material 111 that have been deposited are removed. This step includes a step of removing the first insulating material 111 and the third hard mask 108 by means of a grinding method until the first mask 102 is exposed. The grinding method may be a CMP (chemical mechanical polishing) method. Of course, in this step, the etching method (wet etching method and/or dry etching method) may be employed instead of the grinding method.

The first insulating material 111 covering the first side surface 133a, the second side surface 133b, and the bottom surface 133c and the first insulating material 111 with which the open portion 133d is filled become the first insulating film 123, the second insulating film 42, the third insulating film 124, and the upper insulating film 44, respectively. Hence, the first insulating film 123 and the second insulating film 42 facing each other across the air gap AG3 are formed (fourth step).

Additionally, the first insulating material 111 covering the first side surface 134a, the second side surface 134b, and the bottom surface 134c and the first insulating material 111 with which the open portion 134d is filled become the first insulating film 127, the second insulating film 52, the third insulating film 128, and the upper insulating film 54, respectively. Hence, the first insulating film 127 and the second insulating film 52 facing each other across the air gap AG4 are formed (fourth step).

The trench 115 is formed by the first trench 105, the second trench 133, and the third trench (second trench) 134. The second side surface 133b and the bottom surface 133c of the second trench 133 become the first side surface 118 and the first lateral bottom surface 121 of the trench 115, respectively. The second side surface 134b and the bottom surface 134c of the third trench 134 become the second side surface 119 and the second bottom surface 122 of the trench 115, respectively. In the first trench 105, a part that is deeper than the bottom surface 133c of the second trench 133 and than the bottom surface 134c of the third trench 134 becomes the central bottom surface 28 of the trench 115.

Subsequent steps are the same as the steps shown in FIG. 5J to FIG. 5L. A description of the steps shown in FIG. 5J to FIG. 5L has already been ended, and therefore the description of these steps is omitted.

Subsequently to the steps shown in FIG. 5J to FIG. 5L, referring to FIG. 7D, unnecessary portions of the second insulating material 113 are removed. In this step, the second insulating material 113 is removed by means of a grinding method until the surface 101 of the semiconductor wafer 100 is exposed. The grinding method may be a CMP (chemical mechanical polishing) method. Hence, the buried insulator 63 is formed by the second insulating material 113 remaining in the shallow trench 62. Of course, in this step, the etching method (wet etching method and/or dry etching method) may be employed instead of the grinding method. Additionally, a functional device, such as the MISFET cell 70, is formed on the surface 101 of the semiconductor wafer 100. Hence, the active region 11 is formed at the surface 101 of the semiconductor wafer 100. The semiconductor device 1B is formed through these steps including the above.

According to the semiconductor device 1B according to the second embodiment of the present disclosure, operations and effects equivalent to the operations and effects described in relation to the first embodiment are fulfilled.

The present disclosure can be carried out in still other modes although the first and second embodiments of the present disclosure have been described as above.

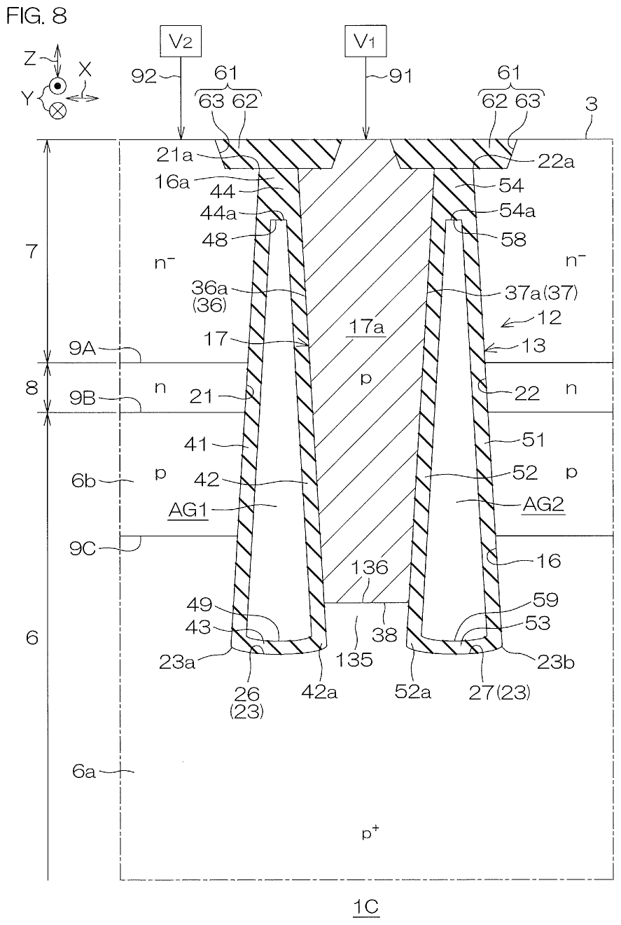

For example, the bottom wall 38 of the buried conductor 17 may be located closer to the first principal surface 3 side than the lower ends 49 and 59 of the air gaps AG1 and AG2 with regard to the depth direction of the trench 16 the bottom wall 38 of the buried conductor 17 in the same way as a semiconductor device 1C shown in FIG. 8.

In detail, a convex portion 135 is formed at the bottom surface 23 on the first principal surface 3 side instead of the central bottom surface 28. The convex portion 135 is formed by the high concentration region 6a. The convex portion 135 has an upper surface 136 that is a flat surface along the first principal surface 3. The bottom wall 38 of the buried conductor 17 is located closer to the first principal surface 3 side than the lower ends 42a and 52a of the second insulating films 42 and 52. Additionally, the bottom wall 38 of the buried conductor 17 is located closer to the first principal surface 3 side than the lower ends 49 and 59 of the air gaps AG1 and AG2. The convex portion 135 is sandwiched between the second insulating film 42 and the second insulating film 52 in the direction perpendicular to the direction in which the trench 16 extends in a plan view. The upper surface 136 of the convex portion 135 is contiguous to the bottom wall 38 of the buried conductor 17. Hence, an electrical connection of the buried conductor 17 with the high concentration region 6a is achieved. The modification of FIG. 8 may be applied to the semiconductor device 1B according to the second embodiment.

Additionally, the element isolation portion 12 demarcates other regions by annularly surrounding the single active region 11 in the description above, and yet the element isolation portion 12 may demarcate a boundary between two active regions 11 adjoining each other.

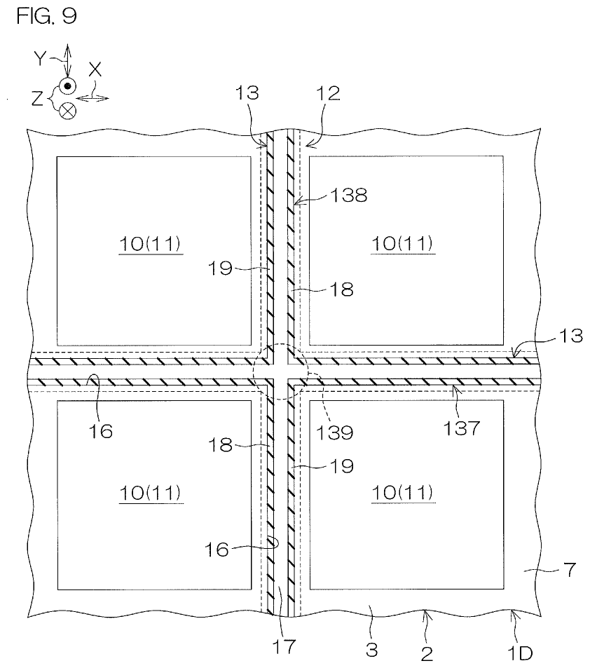

In detail, the element isolation portion 12 (the first trench structure 13) may include a linear first part 137 that extends in an X direction and a linear second part 138 extending in a Y direction in the same way as a semiconductor device 1D shown in FIG. 9. The term “linear” is not limited to a straight line shown in FIG. 9, and may semantically include a curved line. The element isolation portion 12 may have an intersection portion 139 at which the first part 137 and the second part 138 intersect each other. The intersection portion 139 may be a part at which the two intersect each other in a cross shape or in a T shape. In this case, the depth of the trench 16, 115 of the first trench structure 13 included in the intersection portion 139 is greater than the depth of the trench 16, 115 of the first trench structure 13 included in other parts (parts excluding the intersection portion 139 in the first part 137 and the second part 138). This is caused by the fact that the etching rate in the intersection portion 139 is faster than the etching rate in other parts. Likewise, with respect to the position of the lower end 49, 59, 132, 131 of the air gap AG1, AG2, AG3, AG4, the first trench structure 13 included in the intersection portion 139 is located at a deeper position than the other parts.

Additionally, with respect to a combination of two insulating portions included in the first trench structure 13, a combination of the first insulating portion 18 and the second insulating portion 117 or a combination of the first insulating portion 116 and the second insulating portion 19 may be employed.

Additionally, in a case in which the element isolation portion 12 annularly surrounds the single active region 11, and demarcates other regions, the second insulating portion 19, 117 may be abolished in the first trench structure 13, 114 included in the element isolation portion 12.

Additionally, for example, a configuration may be employed in which the conductivity type of each semiconductor part of the semiconductor device 1A, 1B, 1C, 1D is inverted. For example, a p-type (first conductivity type) part may be n-type, and an n-type (second conductivity type) part may be p-type in the semiconductor device 1A, 1B, 1C, 1D.

### Third to Fifth Preferred Embodiments

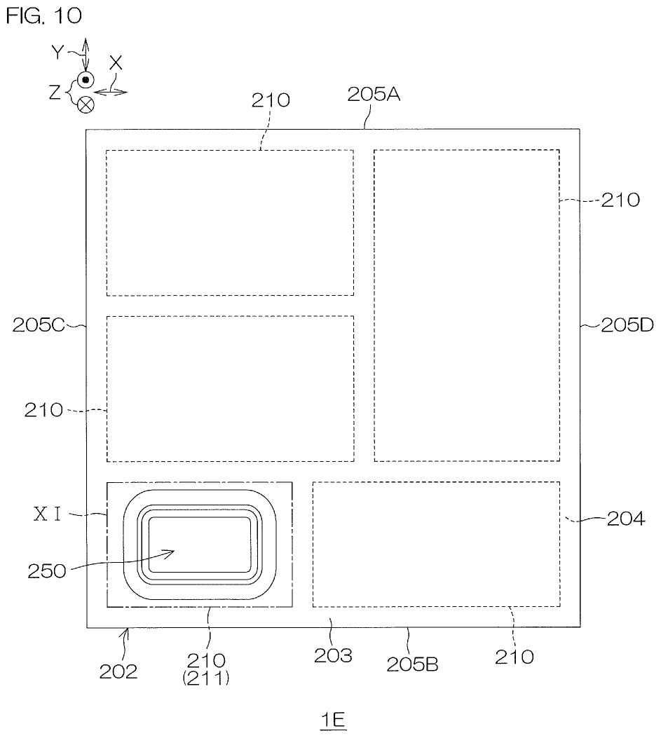

FIG. 10 is a schematic plan view of a semiconductor device 1E according to a third embodiment of the present disclosure.

Referring to FIG. 10, the semiconductor device 1E includes a rectangular parallelepiped shaped semiconductor chip 202. In this embodiment, the semiconductor chip 202 is made of a Si (silicon) chip. The semiconductor chip 202 has a first principal surface 203 on one side, a second principal surface 204 on the other side, and first to fourth side surfaces 205A to 205D that connect the first principal surface 203 and the second principal surface 204.

The first principal surface 203 and the second principal surface 204 are each formed in a quadrangular shape in a plan view seen from their normal directions Z (hereinafter, referred to simply as a “plan view”). The normal direction Z is also a thickness direction of the semiconductor chip 202. The first side surface 205A and the second side surface 205B extend in the first direction X along the first principal surface 203, and face each other in the second direction Y that intersects the first direction X (in detail, perpendicularly intersects the first direction X). The third side surface 205C and the fourth side surface 205D extend in the second direction Y, and face each other in the first direction X.

The semiconductor device 1E includes a plurality of device regions 210 formed at the first principal surface 203. The device regions 210 are regions in which various functional devices are formed by use of regions inside the semiconductor chip 202, respectively. The device regions 210 are each demarcated in an inward portion of the first principal surface 203 at a distance from the first to fourth side surfaces 205A to 205D in a plan view. The device region 210 is optional in number, in disposition, and in shape, and is not limited to a specific number, to a specific disposition, and to a specific shape.

The functional devices may include at least one among a semiconductor switching device, a semiconductor rectifying device, and a passive device. The semiconductor switching device may include at least one among JFET (Junction Field Effect Transistor), MISFET (Metal Insulator Semiconductor Field Effect Transistor), BJT (Bipolar Junction Transistor), and IGBT (Insulated Gate Bipolar Junction Transistor).

The semiconductor rectifying device may include at least one among a pn junction diode, a pin junction diode, a Zener diode, a Schottky barrier diode, and a fast recovery diode. The passive device may include at least one among a resistor, a capacitor, an inductor, and a fuse. In this embodiment, the device regions 210 include at least one active region 211.

The active region 211 is a region in which a plurality of transistor devices are formed. An electric current flows in a lateral direction of the semiconductor chip 202 in the active region 211 when a source-drain interval of the semiconductor device 1E is in an electrically conductive state (when turned on). The active region 211 is, for example, a quadrilateral shape in a plan view.

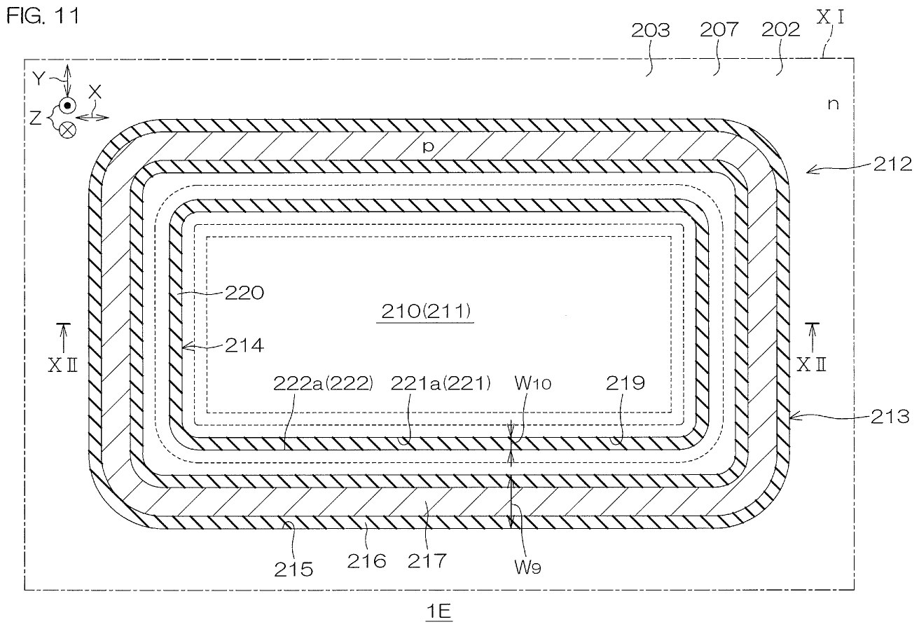

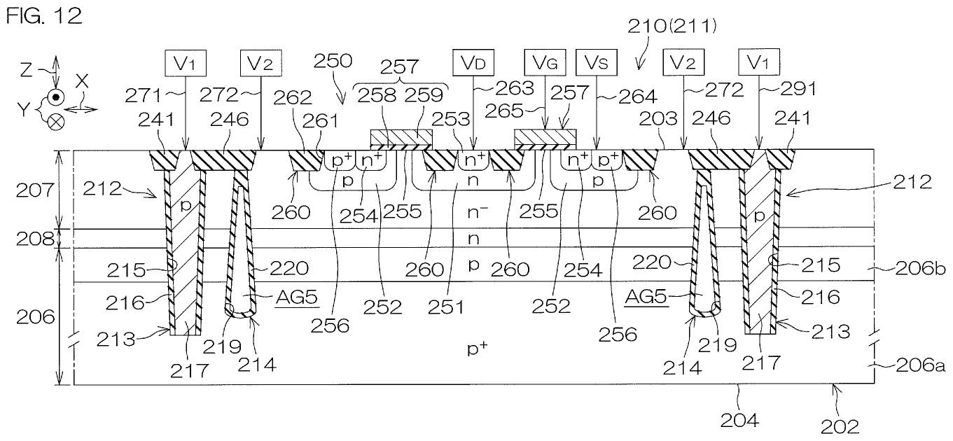

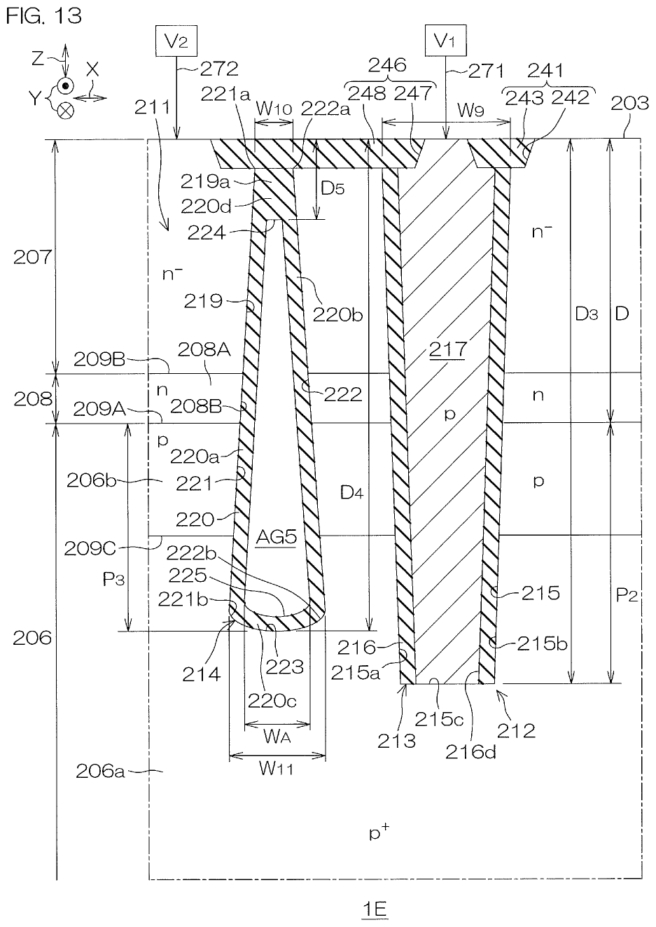

FIG. 11 is an enlarged view of region XI shown in FIG. 10. FIG. 12 is a view showing cross section XII-XII shown in FIG. 11. FIG. 13 is a cross-sectional enlarged view of a main portion of a structure shown in FIG. 12.

Referring to FIG. 12, the semiconductor chip 202 includes a p-type (first conductivity type) first impurity region 206 in a region located on the second principal surface 204 side. The first impurity region 206 may be referred to as a “base region.” The first impurity region 206 extends in a layer shape that follows the second principal surface 204, and is exposed from a part of the second principal surface 204 and from a part of the first to fourth side surfaces 205A to 205D. The first impurity region 206 has a concentration gradient in which a p-type impurity concentration on the first principal surface 203 side is lower than a p-type impurity concentration on the second principal surface 204 side. In detail, the first impurity region 206 has a laminated structure including a p-type high concentration region 206a and a p-type low concentration region 206b that are laminated in that order from the second principal surface 204 side.

The high concentration region 206a has a comparatively high p-type impurity concentration. The p-type impurity concentration of the high concentration region 206a may be not less than 1×10¹⁷ cm⁻³ and not more than 1×10²¹ cm⁻³. The high concentration region 206a may include boron (B) as a p-type impurity. The high concentration region 206a may have a thickness of not less than 50 μm and not more than 500 μm. In this embodiment, the high concentration region 206a is made of a p-type semiconductor substrate (Si substrate).

The low concentration region 206b has a p-type impurity concentration lower than the high concentration region 206a, and is laminated on the high concentration region 206a. The p-type impurity concentration of the low concentration region 206b may be not less than 1×10¹⁴ cm⁻³ and not more than 1×10¹⁷ cm⁻³. The low concentration region 206b may include boron (B) as a p-type impurity. The thickness of the low concentration region 206b may be less than the thickness of the high concentration region 206a. The thickness of the low concentration region 206b may be not less than 1 μm and not more than 20 μm. In this embodiment, the low concentration region 206b is made of a p-type epitaxial layer (Si epitaxial layer).

The semiconductor chip 202 additionally includes an n-type (second conductivity type) second impurity region 207 formed in a region located on the first principal surface 203 side. The second impurity region 207 extends in a layer shape that follows the first principal surface 203, and is exposed from a part of the first principal surface 203 and from a part of the first to fourth side surfaces 205A to 205D. The n-type impurity concentration of the second impurity region 207 may be not less than 1×10¹⁴ cm⁻³ and not more than 1×10¹⁷ cm⁻³. The thickness of the second impurity region 207 may be not less than 5 μm and not more than 30 m. The second impurity region 207 may have an n-type impurity concentration that is uniform in the thickness direction, or may have a concentration gradient in which the n-type impurity concentration becomes higher toward the first principal surface 203. The second impurity region 207 may be made of an n-type epitaxial layer (Si epitaxial layer).

The semiconductor chip 202 additionally includes an n-type (second conductivity type) buried region 208 that is buried between the first impurity region 206 and the second impurity region 207. In other words, the first impurity region 206, the buried region 208, and the second impurity region 207 are laminated in that order from the second principal surface 204 side. The buried region 208 is electrically connected to the first impurity region 206 and to the second impurity region 207. The buried region 208 extends in a layer shape that follows the second impurity region 207. The buried region 208 is exposed from a part of the first to fourth side surfaces 205A to 205D. The n-type impurity concentration of the buried region 208 may be not less than 1×10¹⁶ cm⁻³ and not more than 1×10²¹ cm⁻³. The thickness of the buried region 208 may be not less than 0.1 μm and not more than 5 μm. The buried region 208 may be made of an n-type epitaxial layer (Si epitaxial layer).

Referring to FIG. 11 and FIG. 12, the semiconductor chip 202 includes an element isolation portion 212 that is formed on the first principal surface 203 side and demarcates the active region 211. In this embodiment, the element isolation portion 212 annularly surrounds the single active region 211. The element isolation portion 212 is rectangularly annular in a plan view. In detail, the element isolation portion 212 has a rectangularly annular shape having corner portions (four corners) each of which is curved in a circular arc shape in a plan view.

The element isolation portion 212 has a multi-trench structure including at least one first trench structure 213 and at least one second trench structure 214. In this embodiment, the element isolation portion 212 includes the single first trench structure 213 and the single second trench structure 214.

The first trench structure 213 is formed so as to demarcate the active region 211 on the first principal surface 203 side of the semiconductor chip 202. The first trench structure 213 is annular in a plan view, and in detail, is rectangularly annular. In more detail, the first trench structure 213 has a rectangularly annular shape having corner portions (four corners) each of which is curved in a circular arc shape in a plan view. The first trench structure 213 includes a first trench 215, a first insulating film 216, and a buried conductor 217.

The first trench 215 is formed so as to demarcate the active region 211 on the first principal surface 203 side of the semiconductor chip 202. The first trench 215 is annular, and, in detail, is rectangularly annular in a plan view. In more detail, the first trench 215 has corner portions (four corners) each of which is curved in a circular arc shape in a plan view. The planar shape of the first trench 215 is appropriately changed in accordance with the planar shape of the active region 211. If the planar shape of the first trench 215 is polygonal, circular, and elliptical, the planar shape of the first trench 215 may be polygonally annular, circularly annular, and elliptically annular, respectively.

Referring to FIG. 13, the first trench 215 is formed so as to penetrate through a boundary part 209A between the first impurity region 206 and the buried region 208, and demarcates a wall surface of the first trench structure 213. The first trench 215 has a third depth D₃. The first trench 215 penetrates through the buried region 208 so as to reach the first impurity region 206. In detail, the first trench 215 extends from the first principal surface 203 toward the second principal surface 204 so as to reach the high concentration region 206a of the first impurity region 206, and penetrates through the buried region 208 and the low concentration region 206b of the first impurity region 206. The first trench 215 is formed in a tapered shape whose width becomes smaller toward the second principal surface 204 in a cross-sectional view. The first trench 215 protrudes from the boundary part 209A between the first impurity region 206 and the buried region 208 toward the second principal surface 204 by a second amount of protrusion P₂. The second amount of protrusion P₂ may exceed a distance D between the first principal surface 203 and the boundary part 209A (P₂>D). The second amount of protrusion P₂ may be equal to or less than the distance D between the first principal surface 203 and the boundary part 209A (P₂<D).

The first trench 215 includes a pair of side surfaces (inner surfaces) 215a and 215b facing each other and a bottom surface (bottom portion) 215c connecting the pair of side surfaces 215a and 215b. The pair of side surfaces 215a and 215b include the side surface 215a on the active region 211 side and the side surface 215b on the side opposite to the active region 211 side. In this embodiment, the side surface 215a is an inner peripheral surface of the first trench 215, and the side surface 215b is an outer peripheral surface of the first trench 215. The side surfaces 215a and 215b are formed so as to straddle the second impurity region 207, the buried region 208, the low concentration region 206b, and the high concentration region 206a. The side surfaces 215a and 215b are contiguous to the second impurity region 207, the buried region 208, the low concentration region 206b, and the high concentration region 206a.

In this embodiment, the bottom surface 215c is a flat surface parallel to the first principal surface 203. The bottom surface 215c is formed in the high concentration region 206a. The bottom surface 215c is contiguous to the high concentration region 206a. The bottom surface 215c may have a round shape that swells toward the second principal surface 204 side in a cross-sectional view.

The first trench 215 has a ninth width W₉ (see also FIG. 11). The ninth width W₉ is a width (maximum value) in the direction perpendicular to the direction in which the first trench 215 extends in a plan view. The ninth width W₉ may be not less than 0.5 μm and not more than 10 μm. Preferably, the ninth width W₉ is not less than 2 μm and not more than 4 μm.

The first insulating film 216 covers the side surfaces 215a and 215b of the first trench 215. The first insulating film 216 has an opening 216d in the bottom surface 215c of the first trench 215. In detail, the first insulating film 216 is contiguous to the second impurity region 207, the buried region 208, the low concentration region 206b, and the high concentration region 206a in the side surface 215a and the side surface 215b of the first trench 215. The opening 216d exposes the high concentration region 206a of the first impurity region 206 from the bottom surface 215c of the first trench 215. In this embodiment, the opening 216d is formed in an annular shape extending along the first trench 215 in a plan view. The opening 216d may be formed in a with-end belt shape extending along the first trench 215 in a plan view. The first insulating film 216 may be an oxide film. The oxide film may be silicon oxide (SiO₂), or may be tetraethyl orthosilicate (TEOS).

The buried conductor 217 is buried in the first trench 215 with the first insulating film 216 between the buried conductor 217 and the first trench 215. The buried conductor 217 is polysilicon. In this embodiment, this polysilicon is doped-polysilicon to which a p-type (first conductivity type) impurity (for example, boron (B)) is added. The buried conductor 217 is electrically insulated from the second impurity region 207 and from the buried region 208 by means of the first insulating film 216. The buried conductor 217 has an exposed portion exposed from the bottom surface 215c of the first trench 215 (the opening 216d of the first insulating film 216). In this exposed portion, the buried conductor 217 is mechanically connected to the first impurity region 206 (the high concentration region 206a).

Referring to FIG. 11 and FIG. 12, the second trench structure 214 is formed at a distance from the first trench structure 213 to the active region 211 side in a plan view, and extends in a belt shape that follows the first trench structure 213. In other words, the second trench structure 214 is formed in a region closer to the active region 211 side than the first trench structure 213 on the first principal surface 203 side of the semiconductor chip 202. The second trench structure 214 is annular, and, in detail, is rectangularly annular in a plan view. In more detail, the second trench structure 214 has a rectangularly annular shape having corner portions (four corners) each of which is curved in a circular arc shape in a plan view. The second trench structure 214 includes a second trench 219 and a second insulating film 220 formed on the inner surface of the second trench 219. The second trench structure 214 insulates the active region 211 and the buried conductor 217 of the first trench structure 213.

The second trench 219 demarcates the active region 211 on the first principal surface 203 side of the semiconductor chip 202. In this embodiment, the second trench 219 is formed in an annular shape extending substantially in parallel with the first trench 215 in a plan view (in this embodiment, in a rectangularly annular shape). In more detail, the second trench 219 has a rectangularly annular shape having corner portions (four corners) each of which is curved in a circular arc shape in a plan view. The planar shape of the second trench 219 is appropriately changed in accordance with the planar shape of the active region 211. If the planar shape of the active region 211 is polygonal, circular, and elliptical, the planar shape of the second trench 219 may be polygonally annular, circularly annular, and elliptically annular, respectively.

Referring to FIG. 13, the second trench 219 is formed in the first principal surface 203 so as to penetrate through the boundary part 209A between the first impurity region 206 and the buried region 208, and demarcates a wall surface of the second trench structure 214. The second trench 219 has a fourth depth D₄. In the example of FIG. 13, the fourth depth D₄ of the second trench 219 is less than the third depth D₃ of the first trench 215 (D₄<D₃). In other words, the fourth depth D₄ of the second trench 219 differs from the third depth D₃ of the first trench 215. The second trench 219 penetrates through the buried region 208 so as to reach the first impurity region 206. In detail, the second trench 219 extends from the first principal surface 203 toward the second principal surface 204 so as to reach the high concentration region 206a of the first impurity region 206, and penetrates through the buried region 208 and the low concentration region 206b of the first impurity region 206. The second trench 219 is formed in a tapered shape whose width becomes smaller from a bottom surface 223 described below toward the first principal surface 203 in a cross-sectional view. The fourth depth D₄ of the second trench 219 may be deeper than the third depth D₃ of the first trench 215 (D₄>D₃). The fourth depth D₄ of the second trench 219 may be substantially equal to the third depth D₃ of the first trench 215 (D₄≈D₃).

The second trench 219 protrudes from the boundary part 209A between the first impurity region 206 and the buried region 208 toward the second principal surface 204 by a third amount of protrusion P₃. The third amount of protrusion P₃ may exceed the distance D between the first principal surface 203 and the boundary part 209A (P₃>D). The third amount of protrusion P₃ may be equal to or less than the distance D between the first principal surface 203 and the boundary part 209A (P₃<D).

The second trench 219 includes a first side surface (inner surface) 221 and a second side surface (inner surface) 222 facing each other and a bottom surface (inner surface, bottom portion) 223 connecting the first side surface 221 and the second side surface 222. The first side surface 221 is a side surface of the active region 211 side. The second side surface 222 is a side surface on the side opposite to the active region 211 side. In this embodiment, the first side surface 221 is an inner peripheral surface of the second trench 219, and the side surface 222 is an outer peripheral surface of the second trench 219.

The side surface 221 is formed so as to straddle the second impurity region 207, the buried region 208, the low concentration region 206b, and the high concentration region 206a. The side surface 221 is contiguous to the second impurity region 207, the buried region 208, the low concentration region 206b, and the high concentration region 206a. The first side surface 221 is an inclined surface that advances to a more outward side of the second trench 219 (toward the active region 211 side) in proportion to an approach to the second principal surface 204. With regard to the direction perpendicular to the direction in which the second trench 219 extends in a plan view, a bottom portion 221b of the first side surface 221 is closer to the outward side of the second trench 219 (the active region 211 side) than an open end 221a.

The side surface 222 is formed so as to straddle the second impurity region 207, the buried region 208, the low concentration region 206b, and the high concentration region 206a. The side surface 222 is contiguous to the second impurity region 207, the buried region 208, the low concentration region 206b, and the high concentration region 206a. The second side surface 222 is an inclined surface that advances to a more outward side of the second trench 219 (the side opposite to the active region 211 side) in proportion to an approach to the second principal surface 204. With regard to the direction perpendicular to the direction in which the second trench 219 extends in a plan view, a bottom portion 222b of the second side surface 222 is closer to the outward side (the side opposite to the active region 211 side) than an open end 222a.

The bottom surface 223 is formed in the high concentration region 206a. The bottom surface 223 is contiguous to the high concentration region 206a. In the example of FIG. 12 and FIG. 13, the bottom surface 223 has a round shape that swells toward the second principal surface 204 side in a cross-sectional view. The bottom surface 223 may be a flat surface parallel to the first principal surface 203.

The second trench 219 has a tenth width W₁₀ in the open ends 221a and 222a (see also FIG. 11). The tenth width W₁₀ is a width in the direction perpendicular to the direction in which the second trench 219 extends in a plan view. The tenth width W₁₀ is narrower than the ninth width W₉ (W₁₀<W₉). The tenth width W₁₀ may be not less than 0.05 μm and not more than 5 μm. Preferably, the tenth width W₁₀ is not less than 0.5 μm and not more than 2 m. The tenth width W₁₀ may be substantially equal to the ninth width W₉ (W₁₀≈W₉), or may be wider than the ninth width W₉ (W₁₀>W₉).

The bottom surface 223 of the second trench 219 has an eleventh width W₁₁. The eleventh width W₁ is a width in the direction perpendicular to the direction in which the second trench 219 extends in a plan view. The eleventh width W₁ᵢ is wider than the tenth width W₁₀ (W₁1>W₁₀). The eleventh width W₁ᵤ is narrower than the ninth width W₉ (W₁<W₉). The eleventh width W₁ᵢ may be substantially equal to the ninth width W₉ (W₁₁≈W₉), or may be wider than the ninth width W₉ (W₁₁>W₉).

The second trench 219 is not necessarily required to reach the high concentration region 206a of the first impurity region 206. In this case, the second trench 219 may extend from the first principal surface 203 toward the second principal surface 204 so as to reach the low concentration region 206b of the first impurity region 206, and may penetrate through the buried region 208. Additionally, in this case, the bottom surface 223 may be formed in the low concentration region 206b.

The second insulating film 220 is formed on the inner surface of the second trench 219. Inside the second trench 219, a hollow air gap AG5 is demarcated by the second insulating film 220. In other words, the second insulating film 220 is formed on the inner surface of the second trench 219 so that the hollow air gap AG5 is formed inside the second trench 219. The hollow air gap AG5 is an enclosed space closed by the second insulating film 220, and the inner surface of the second insulating film 220 is exposed over the entirety of the hollow air gap AG5. The second insulating film 220 includes a first part 220a covering the first side surface 221, a second part 220b covering the second side surface 222, a third part 220c covering the bottom surface 223, and a fourth part 220d formed at an open portion 219a. The first part 220a is contiguous to the second impurity region 207, the buried region 208, the low concentration region 206b, and the high concentration region 206a in the first side surface 221. The second part 220b is contiguous to the second impurity region 207, the buried region 208, the low concentration region 206b, and the high concentration region 206a in the second side surface 222. The third part 220c is contiguous to the high concentration region 206a in the bottom surface 223. The fourth part 220d connects the first part 220a and the second part 220b in the open portion 219a. The fourth part 220d closes the open portion 219a at the upper part of the air gap AG5. The first part 220a and the second part 220b are connected only in the open portion 219a of the second trench 219.

The air gap AG5 is a space demarcated by the first part 220a, by the second part 220b, by the third part 220c, and by the fourth part 220d, and houses air in the inside. The air gap AG5 is formed in a tapered shape whose width becomes smaller from the bottom surface 223 toward the first principal surface 203 in a cross-sectional view. The first part 220a and the second part 220b of the second insulating film 220 sandwich the air gap AG5 in the direction perpendicular to the direction in which the second trench 219 extends in a plan view.

The air gap AG5 has the width W_{A}. The width W_{A} is a maximal width in the direction perpendicular to the direction in which the second trench 219 extends in a plan view. The width W_{A} may be 0.001 to 1.0 times as large as the depth of the second trench 219.

In the example of FIG. 13, an upper end 224 of the air gap AG5 is closer to the first principal surface 203 side with respect to a boundary part 209B between the second impurity region 207 and the buried region 208. A lower end 225 of the air gap AG5 is closer to the second principal surface 204 side with respect to a boundary part 209C between the low concentration region 206b and the high concentration region 206a.

In detail, the upper end 224 of the air gap AG5 has a fifth depth D₅. The fifth depth D₅ is 0.1 μm to 30 μm. In the example of FIG. 13, the fifth depth D₅ is shorter than the distance between the upper end 224 of the air gap AG5 and the boundary part 209B between the second impurity region 207 and the buried region 208. The fifth depth D₅ may be equal to or more than the distance between the upper end 224 and the boundary part 209B. Additionally, the lower end 225 of the air gap AG5 may be located at the same position as the boundary part 209C between the low concentration region 206b and the high concentration region 206a, or may be located at a position between the boundary part 209C and the boundary part 209A between the first impurity region 206 and the buried region 208 with regard to the depth direction of the second trench 219.

The air gap AG5 is sandwiched between a region 208A on the active region 211 side with respect to the second trench 219 in the buried region 208 and the buried conductor 217 in the lateral direction along the first principal surface 203. In other words, the air gap AG5 is formed so as to be sandwiched between the buried region 208 and the buried conductor 217 in the lateral direction along the first principal surface 203. Additionally, the air gap AG5 is sandwiched between a region on the active region 211 side with respect to the second trench 219 in the low concentration region 206b and the buried conductor 217 in the lateral direction along the first principal surface 203.

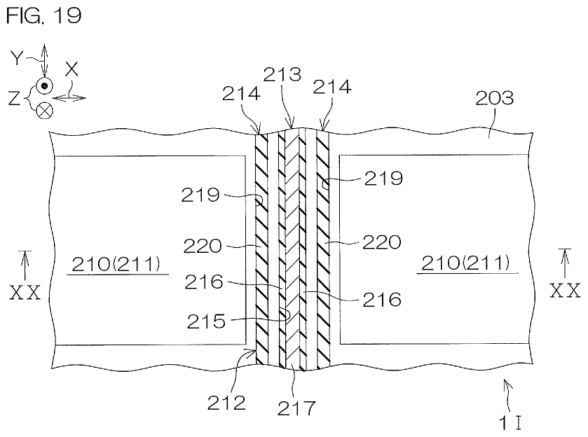

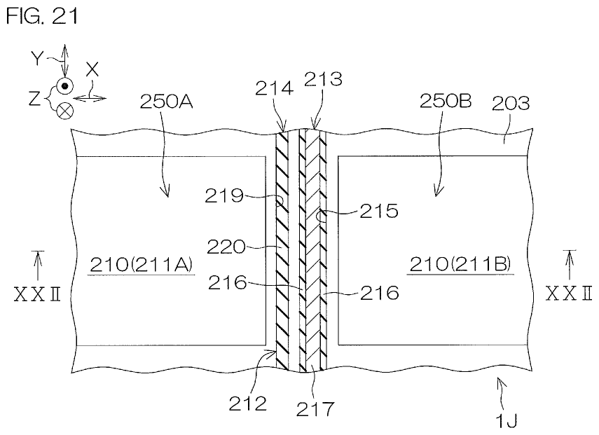

Referring to FIG. 12 and FIG. 13, the element isolation portion 212 additionally includes a third trench structure 241 formed at the first principal surface 203. In FIG. 11, the third trench structure 241 is omitted, and is not shown (the same applies in FIG. 19 and FIG. 21 described later). The third trench structure 241 may be referred to as an STI structure (shallow trench isolation structure).

The third trench structure 241 is formed at a distance from the buried region 208 toward the first principal surface 203 side. That is, the third trench structure 241 is formed in the thickness range of the second impurity region 207. The third trench structure 241 extends along the first trench structure 213 in a plan view. In this embodiment, the third trench structure 241 is formed in an annular shape (in this embodiment, rectangularly annular shape) extending along the first trench structure 213 in a plan view.

Referring to FIG. 13, the third trench structure 241 includes a first shallow trench 242 and a first buried insulator 243. The first shallow trench 242 is formed at a position at which the first shallow trench 242 overlaps with the second side surface 215b of the first trench 215 in a plan view, and exposes the second impurity region 207, the first insulating film 216, and the buried conductor 217. The first buried insulator 243 is buried in the first shallow trench 242. The first buried insulator 243 is contiguous to the second impurity region 207, the first insulating film 216, and the buried conductor 217 inside the first shallow trench 242. The first buried insulator 243 may be an oxide film. The oxide film may be silicon oxide (SiO₂), or may be tetraethyl orthosilicate (TEOS).

Referring to FIG. 12 and FIG. 13, the element isolation portion 212 additionally includes a fourth trench structure 246 formed at the first principal surface 203. In FIG. 11, the fourth trench structure 246 is omitted, and is not shown (the same applies in FIG. 19 and FIG. 21 described later). The fourth trench structure 246 may be referred to as an STI structure (shallow trench isolation structure).

The fourth trench structure 246 is formed at a distance from the buried region 208 toward the first principal surface 203 side. That is, the fourth trench structure 246 is formed in the thickness range of the second impurity region 207. The fourth trench structure 246 extends along the second trench structure 214 in a plan view. In this embodiment, the fourth trench structure 246 is formed in an annular shape (in this embodiment, rectangularly annular shape) extending along the second trench structure 214 in a plan view.

Referring to FIG. 13, the fourth trench structure 246 includes a second shallow trench 247 and a second buried insulator 248. The second shallow trench 247 is formed at a position at which the second shallow trench 247 overlaps with the first side surface 215a of the first trench 215, with the side surfaces 221 and 222 of the second trench 219, and with the open portion 219a of the second trench 219 in a plan view, and exposes the second impurity region 207, the first insulating film 216, and the buried conductor 217.

The second buried insulator 248 is buried in the second shallow trench 247. The second buried insulator 248 is contiguous to the second impurity region 207, the first insulating film 216, and the second insulating film 220 inside the second shallow trench 247. The second buried insulator 248 may be an oxide film. The oxide film may be silicon oxide (SiO₂), or may be tetraethyl orthosilicate (TEOS).

Referring to FIG. 12, the semiconductor device 1E includes a planar-gate type MISFET cell 250 that is an example of the functional device formed in the active region 211.

In FIG. 11, the MISFET cell 250 is omitted, and is not shown. The MISFET cell 250 can employ any one form of HV (high voltage)-MISFET cell (for example, not less than 300 V and not more than 3000 V), MV (middle voltage)-MISFET cell (for example, not less than 30 V and not more than 300 V), and LV (low voltage)-MISFET cell (for example, not less than 1 V and not more than 30 V) in accordance with the largeness of a drain-source voltage. In this embodiment, an example in which the MISFET cell 250 is an HV-MISFET cell will be described, and yet this does not denote that the form of the MISFET cell 250 is limited to the HV-MISFET cell.

The MISFET cell 250 includes at least one n-type first well region 251 (in this embodiment, one n-type first well region 251), at least one p-type second well region 252 (in this embodiment, a plurality of p-type second well regions 252), at least one n-type drain region 253 (in this embodiment, one n-type drain region 253), at least one n-type source region 254 (in this embodiment, a plurality of n-type source regions 254), at least one p-type channel region 255 (in this embodiment, a plurality of p-type channel regions 255), at least one p-type contact region 256 (in this embodiment, a plurality of p-type contact regions 256), and at least one planar gate structure 257 (in this embodiment, a plurality of planar gate structures 257) in a cross-sectional view.

The first well region 251 is formed at a surficial portion of the second impurity region 207 in the active region 211. The first well region 251 has an n-type impurity concentration higher than the second impurity region 207. The second well regions 252 are formed at the surficial portion of the second impurity region 207 at a distance from the first well region 251 in the active region 211. The second well region 252 that is one of the second well regions 252 is formed at a distance from the first well region 251 to one side in the first direction X, and the other second well region 252 is formed at a distance from the first well region 251 to the other side in the first direction X.

The drain region 253 is formed at a surficial portion of the first well region 251 at a distance inwardly from the peripheral edge of the first well region 251. The source region 254, the channel region 255, the contact region 256, and the planar gate structure 257 correspond to each of the second well regions 252 on a one-to-one basis. The source regions 254 are each formed at a surficial portion of a corresponding one of the second well regions 252 at a distance inwardly from the peripheral edge of the corresponding second well region 252. The channel regions 255 are each formed between the second impurity region 207 and the source region 254 in the surficial portion of the corresponding second well region 252. The contact regions 256 are each formed at the surficial portion of the corresponding second well region 252 at a distance inwardly from the peripheral edge of the corresponding second well region 252. The contact regions 256 adjoin a corresponding one of the source regions 254.

The planar gate structures 257 are each formed on the first principal surface 203 so as to cover a corresponding one of the channel regions 255, and controls the on/off of the corresponding channel region 255. In this embodiment, the planar gate structures 257 are each formed so as to straddle the first well region 251 and the corresponding source region 254.

The planar gate structures 257 include a gate insulating film 258 and a gate electrode 259 laminated in that order from the first principal surface 203 side. The gate insulating film 258 may be an oxide film. The oxide film may be silicon oxide (SiO₂), or may be tetraethyl orthosilicate (TEOS). Preferably, the gate insulating film 258 includes a silicon oxide film made of an oxide of the semiconductor chip 202. Preferably, the gate electrode 259 includes polysilicon. The gate electrode 259 may include either one or both of an n-type region and a p-type region formed in the polysilicon.

Referring to FIG. 12, the semiconductor device 1E includes a plurality of fifth trench structures 260 formed at the first principal surface 203. In FIG. 11, the fifth trench structure 260 is omitted, and is not shown (the same applies in FIG. 19 and FIG. 21 described later). The fifth trench structures 260 may be referred to as STI structures (shallow trench isolation structures). In this embodiment, the fifth trench structures 260 are formed at a distance from each other so as to demarcate the drain region 253 from other regions and so as to demarcate outer edge portions of the second well regions 252 from other regions.

In this embodiment, the fifth trench structures 260 are formed at a distance from the buried region 208 toward the first principal surface 203 side. That is, the fifth trench structures 260 are formed in the thickness range of the second impurity region 207.

Each of the fifth trench structures 260 includes a shallow trench 261 and a buried insulator 262. The shallow trench 261 is dug down from the first principal surface 203 toward the second principal surface 204. The buried insulator 262 is buried in the shallow trench 261. The buried insulator 262 may be an oxide film. The oxide film may be silicon oxide (SiO₂), or may be tetraethyl orthosilicate (TEOS).

In the active region 211, the drain potential V_{D} is given to the drain region 253 through a drain contact electrode 263. In FIG. 12, the drain contact electrode 263 is shown by being simplified by an arrow. The drain potential V_{D} is a positive device potential in the active region 211. The source potential Vs less than the drain potential V_{D} is given to the source region 254 through a source contact electrode 264. In FIG. 12, the source contact electrode 264 is shown by being simplified by an arrow. The gate potential VG is given to the gate electrode 259 through a gate contact electrode 265. In FIG. 12, the gate contact electrode 265 is shown by being simplified by an arrow.

The first potential V₁ is given to the buried conductor 217 through a contact electrode 271. In FIG. 12 and FIG. 13, the contact electrode 271 is shown by being simplified by an arrow. The first potential V₁ given to the buried conductor 217 is given to the high concentration region 206a through the buried conductor 217. Hence, the high concentration region 206a is fixed at the same electric potential as the buried conductor 217. Preferably, the first potential V₁ is a potential equal to or less than the drain potential V_{D} (preferably, less than the drain potential V_{D}). That is, preferably, the first potential V₁ is less than a maximal device potential. The first potential V₁ may be a reference potential that serves as a criterion for a circuit operation or a ground potential. Preferably, the first potential V₁ is a ground potential.

The second potential V₂ is given to a region demarcated between the first trench structure 213 and the active region 211 in the semiconductor chip 202 through a second contact electrode 272. In FIG. 12 and FIG. 13, the second contact electrode 272 is shown by being simplified by an arrow. Preferably, the second potential V₂ is a potential equal to or less than the drain potential V_{D} (preferably, less than the drain potential V_{D}). Preferably, the second potential V₂ is less than a maximal device potential. The second potential V₂ may be equal to or more than the first potential V₁ (V₂≥V₁). The second potential V₂ may exceed the first potential V₁ (V₂>V₁). The second potential V₂ may be a reference potential or a ground potential.

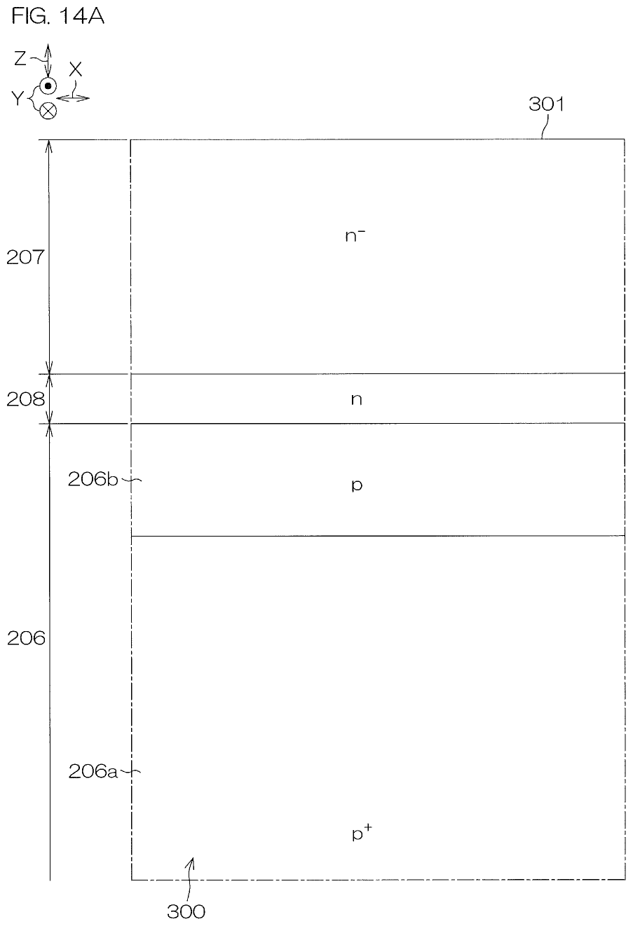

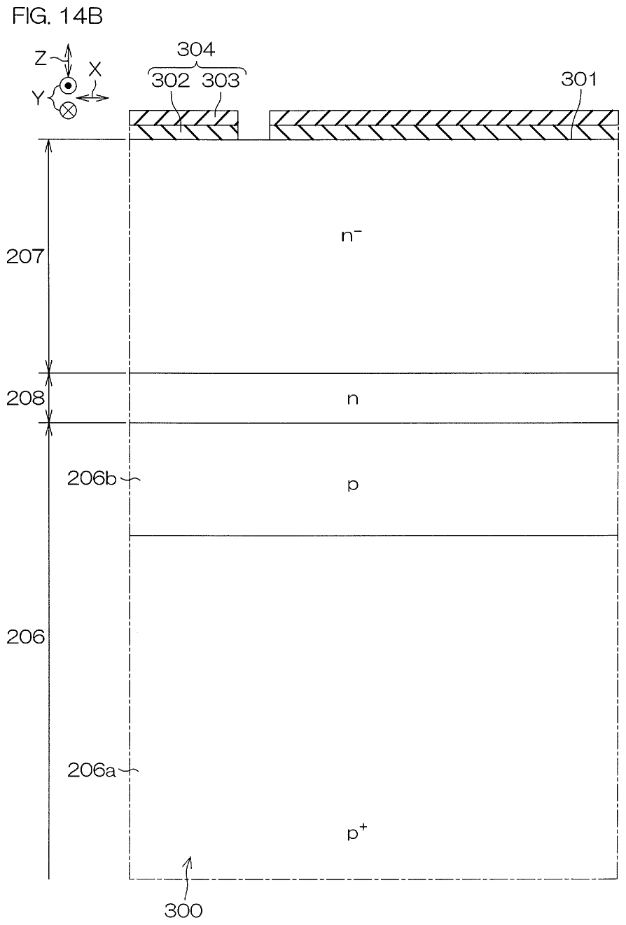

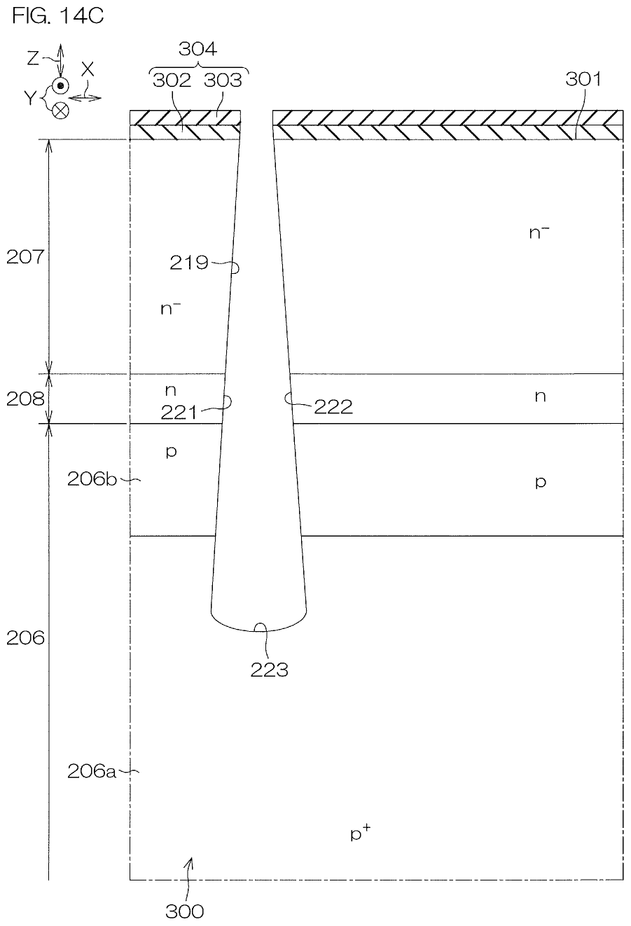

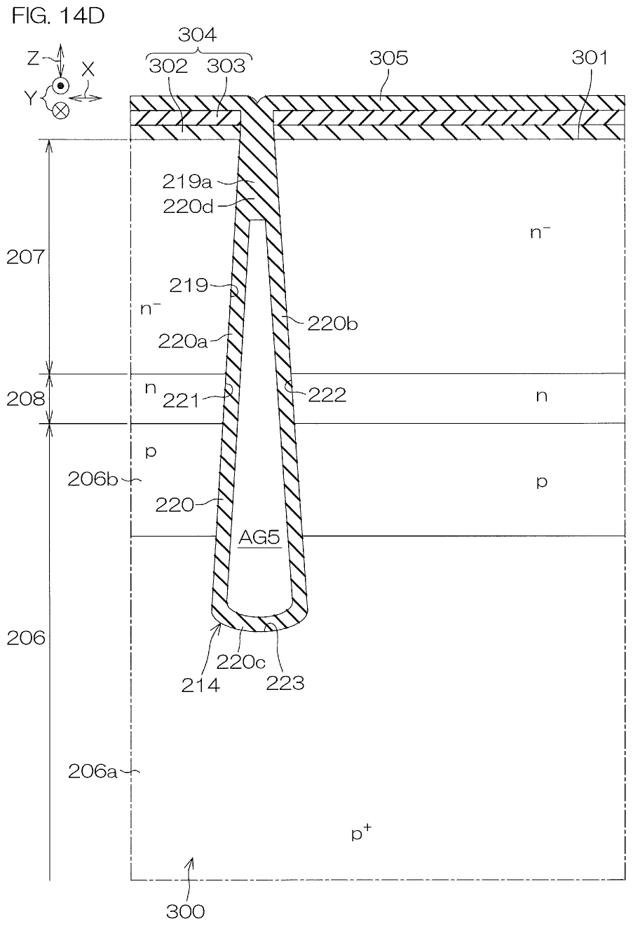

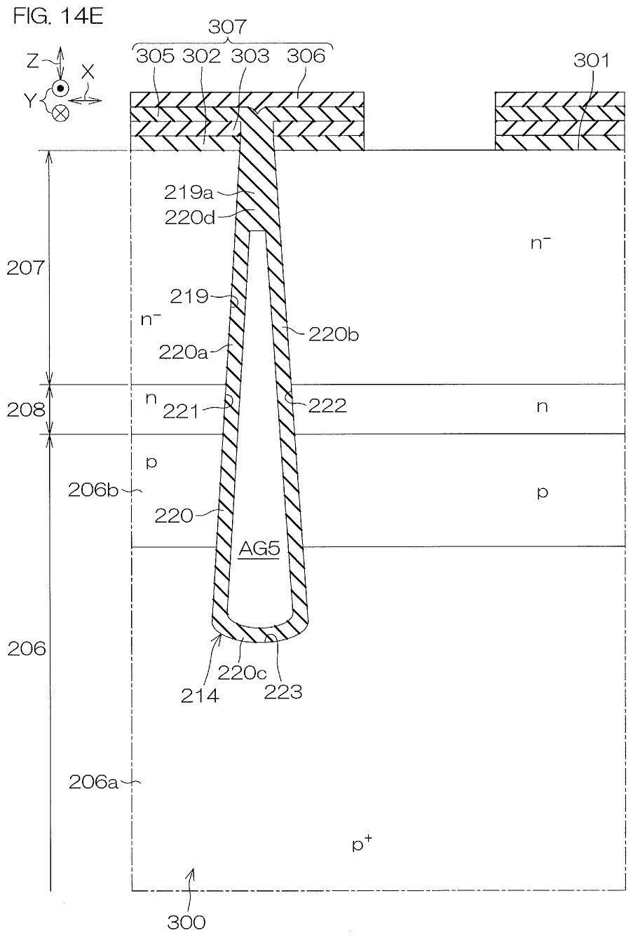

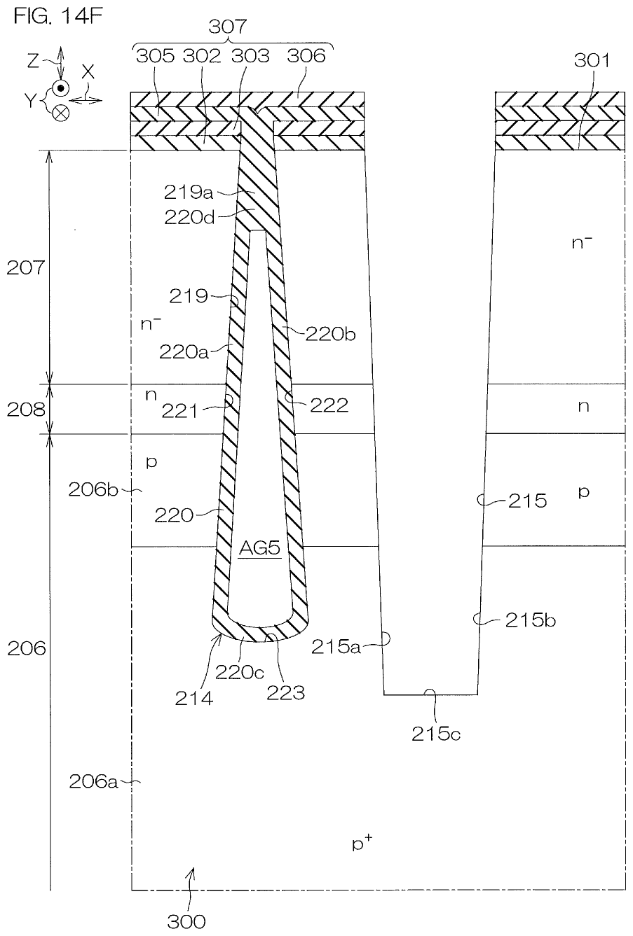

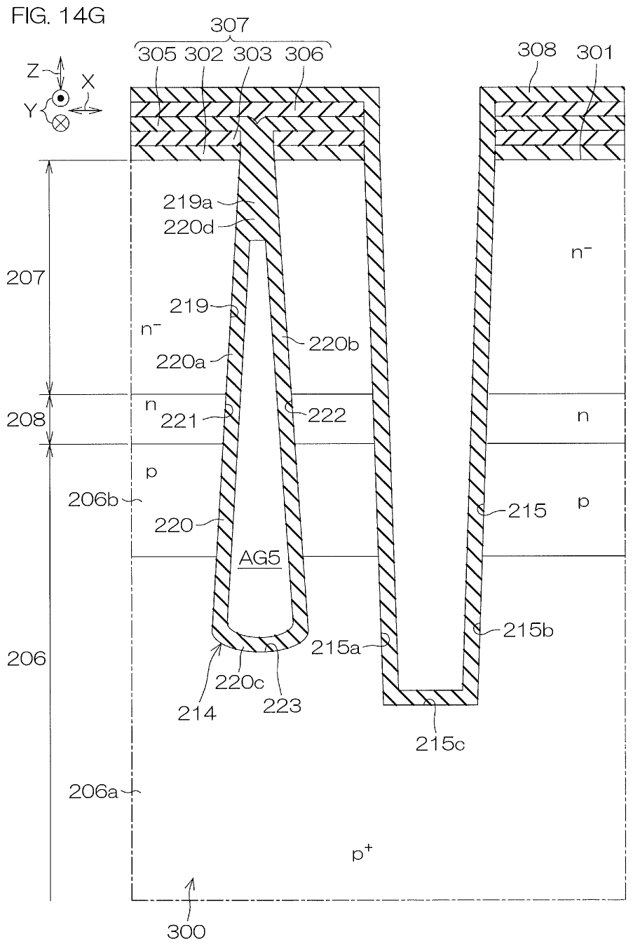

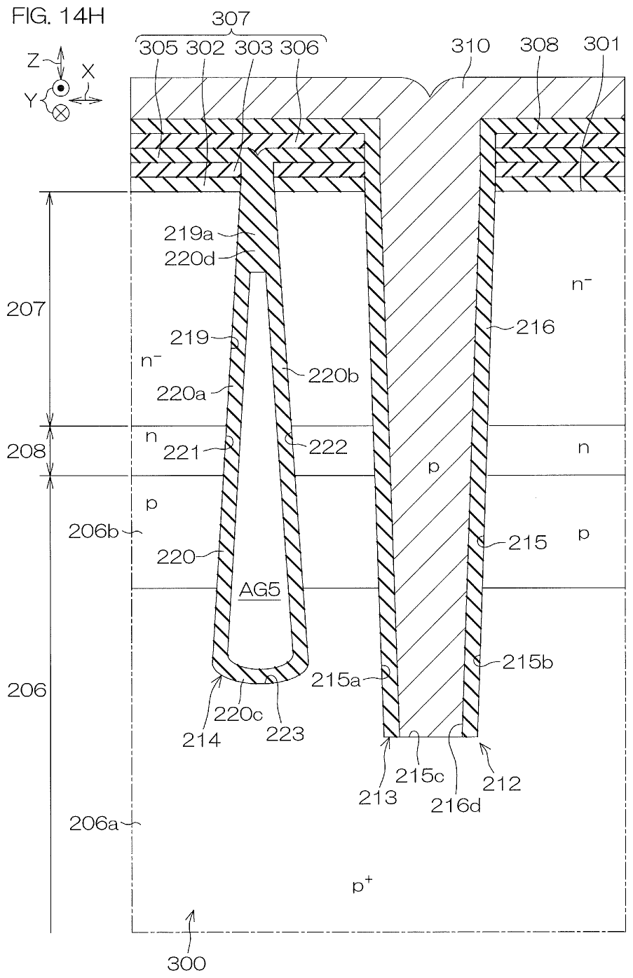

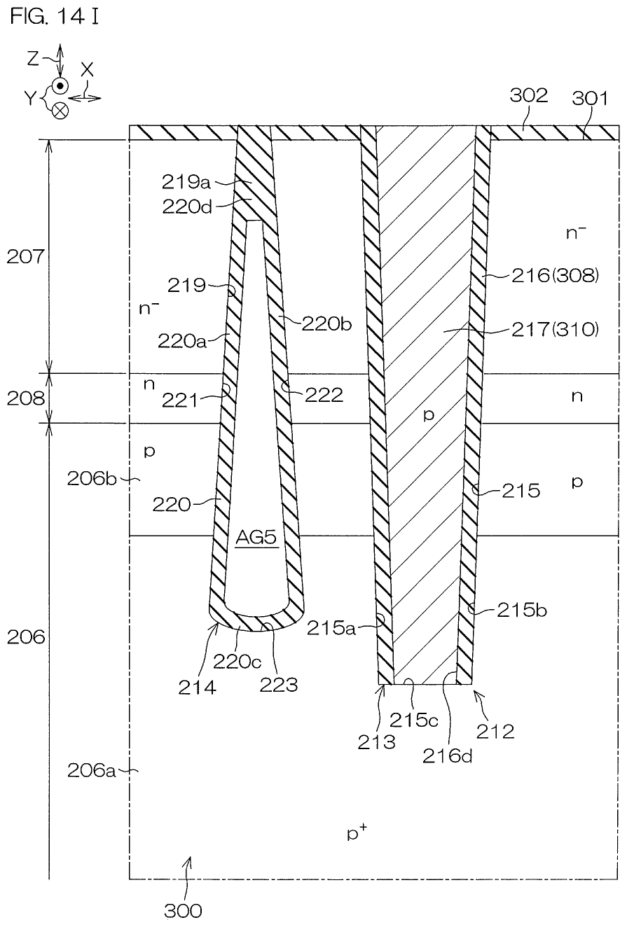

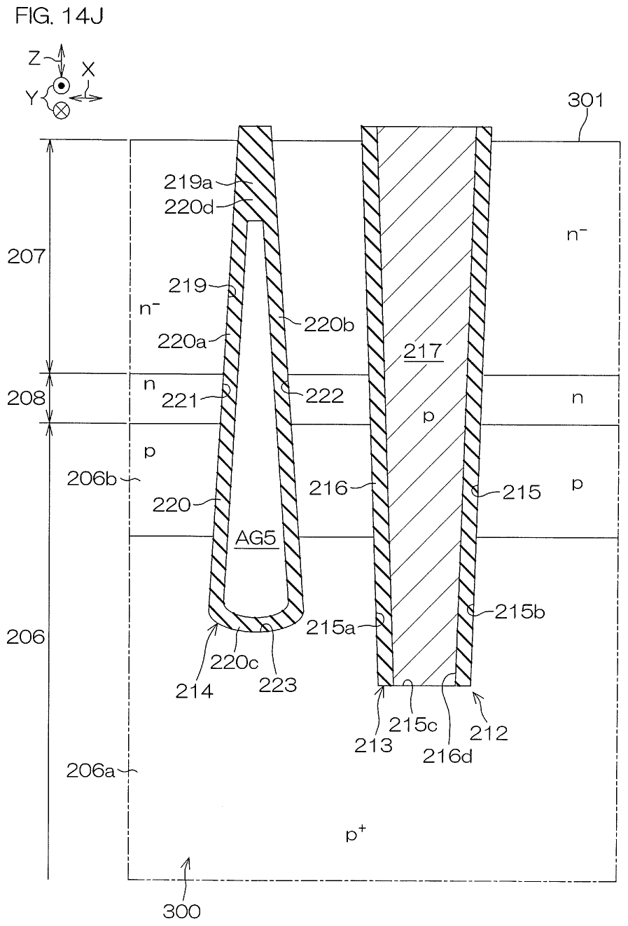

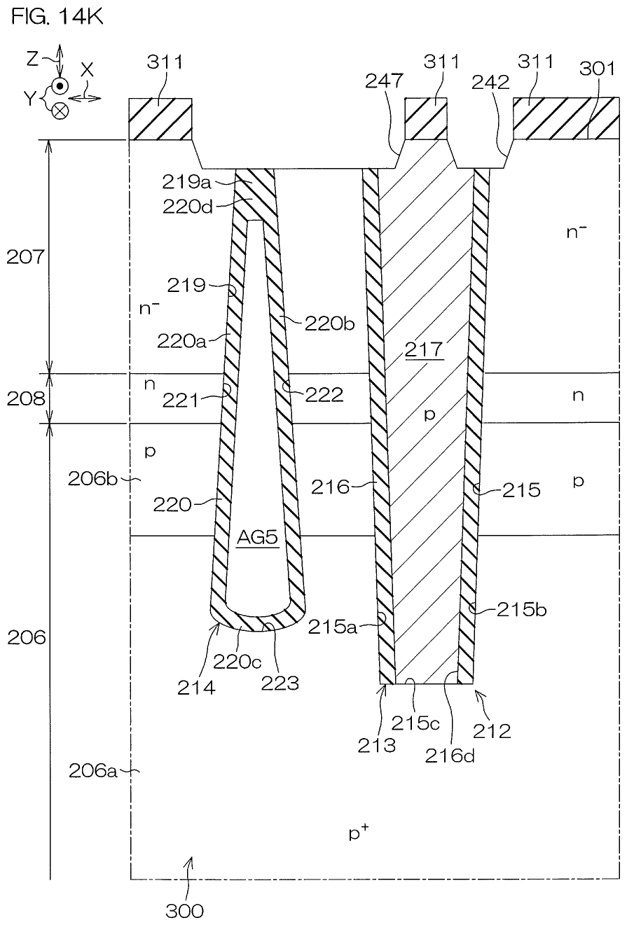

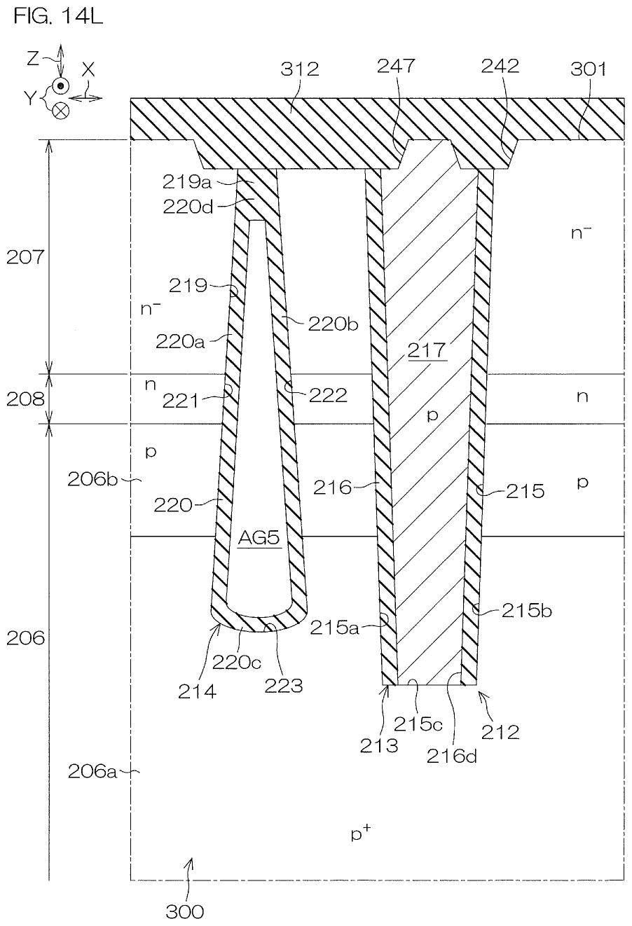

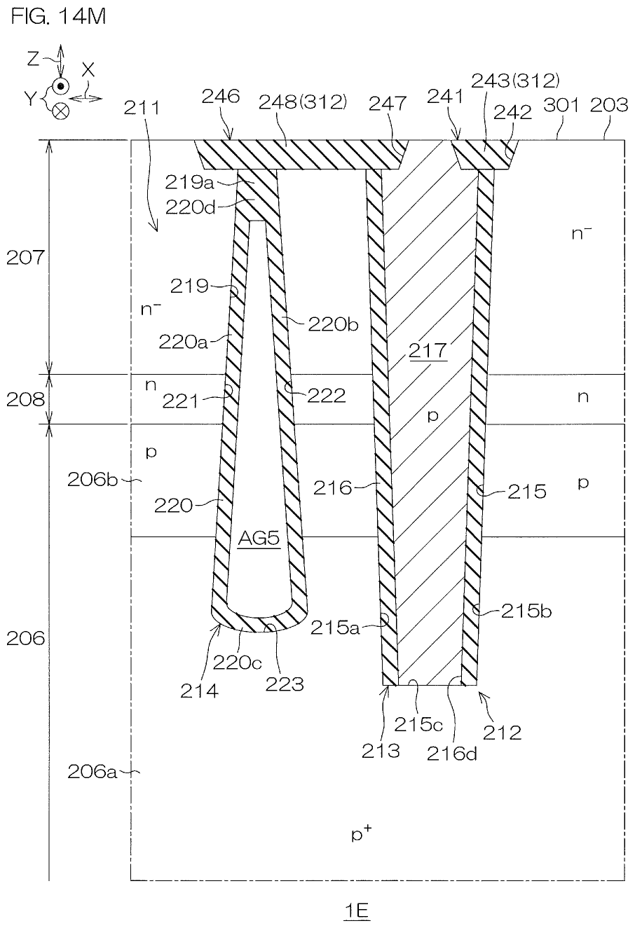

FIG. 14A to FIG. 14M are views shown to describe a process of manufacturing the semiconductor device 1E according to the third embodiment of the present disclosure, and are longitudinal sectional views of a part corresponding to FIG. 13.

Referring to FIG. 14A, a semiconductor wafer 300 that serves as a base of the semiconductor chip 202 is prepared to manufacture the semiconductor device 1E. The semiconductor wafer 300 has a surface 301. The semiconductor wafer 300 includes the first impurity region 206, the second impurity region 207, and the buried region 208. The first impurity region 206 includes the high concentration region 206a and the low concentration region 206b. The high concentration region 206a is made of a p-type semiconductor substrate. The low concentration region 206b is made of a p-type epitaxial layer laminated on a semiconductor substrate by means of an epitaxial growth method.

Next, referring to FIG. 14B, a first mask 302 and a second mask 303 are laminated in that order on the surface 301 of the semiconductor wafer 300. The first mask 302 may be a silicon nitride film. The first mask 302 may be formed by a CVD method. The second mask 303 may be silicon oxide (SiO₂). The second mask 303 may be formed by the CVD method. The first mask 302 and the second mask 303 are selectively removed by an etching method, and, as a result, the first mask 302 and the second mask 303 become a first hard mask 304. The first hard mask 304 exposes a region in which the second trench 219 is to be formed, and covers regions other than this region in the surface 301.

Next, referring to FIG. 14C, the semiconductor wafer 300 is selectively removed by the etching method through the first hard mask 304. Hence, the second trench 219 is formed in the surface 301 of the semiconductor wafer 300 (first step). The etching method may be a dry etching method. The second trench 219 includes the first side surface 221, the second side surface 222, and the bottom surface 223. The second trench 219 is formed in a tapered shape whose width becomes smaller from the bottom surface 223 toward the surface 301 in a cross-sectional view. At least either one of an etching temperature in the dry etching method and a flow rate of etching gas in the dry etching method is regulated, and, as a result, the second trench 219 is formed in a tapered shape whose width becomes smaller from the bottom portion toward the surface 301.

Next, referring to FIG. 14D, a first base insulating film 305 that serves as a base of the second insulating film 220 is formed on the surface 301 through the first hard mask 304. The first base insulating film 305 includes an oxide film. The oxide film may be silicon oxide (SiO₂), or may be tetraethyl orthosilicate (TEOS). In this embodiment, the formation of the first base insulating film 305 may be performed by the CVD method.

The first side surface 221, the second side surface 222, and the bottom surface 223 of the second trench 219 are covered by the first base insulating film 305. The formation of the first base insulating film 305 is continuously performed until the open portion 219a of the second trench 219 is closed. In the second trench 219, the width of a halfway portion in the depth direction of the second trench 219 is wider than the width of the open portion 219a of the second trench 219. Therefore, the open portion 219a of the second trench 219 is closed by the first base insulating film 305 before the whole area of an internal space of the second trench 219 is completely filled with the first base insulating film 305. Hence, the air gap AG5 is formed in the internal space of the second trench 219 (second step). The second insulating film 220 is formed by the first base insulating film 305 covering the first side surface 221, the second side surface 222, and the bottom surface 223 and by the first base insulating film 305 with which the open portion 219a is filled.

Next, referring to FIG. 14E, a third mask 306 is laminated on the first base insulating film 305. The third mask 306 may be silicon oxide (SiO₂). The third mask 306 may be formed by the CVD method.

Next, the first mask 302, the second mask 303, the first base insulating film 305, and the third mask 306 are selectively removed by the etching method, and, as a result, the first mask 302, the second mask 303, the first base insulating film 305, and the third mask 306 become a second hard mask 307. The second hard mask 307 exposes a region in which the first trench 215 is to be formed, and covers regions other than this region in the surface 301.

Next, referring to FIG. 14F, the semiconductor wafer 300 is selectively removed by the etching method through the second hard mask 307. Hence, the first trench 215 is formed in the surface 301 of the semiconductor wafer 300 (third step). The etching method may be a dry etching method and/or wet etching method.

Next, referring to FIG. 14G, a second base insulating film 308 that serves as a base of the first insulating film 216 is formed. The second base insulating film 308 includes an oxide film. The oxide film may be silicon oxide (SiO₂), or may be tetraethyl orthosilicate (TEOS).

The second base insulating film 308 may be formed by an oxidation treatment method (for example, thermal oxidation treatment method). The second base insulating film 308 may be formed by the CVD method.

Next, referring to FIG. 14H, a part, which covers the bottom surface 215c of the first trench 215, of the second base insulating film 308 is removed by the etching method through the second hard mask 307. Preferably, the etching method is an anisotropic etching method.

For example, the etching method may be an RIE method as an example of the dry etching method. Hence, the opening 216d that exposes the bottom surface 215c of the first trench 215 is formed in the second base insulating film 308. The first insulating film 216 is formed by the second base insulating film 308 covering the side surfaces 215a and 215b of the first trench 215 (fourth step).

Next, a second base conductive film 310 that serves as a base of the buried conductor 217 is formed on the surface 301 through the second hard mask 307 and the second base insulating film 308. In this embodiment, the second base conductive film 310 includes doped-polysilicon to which a p-type (first conductivity type) impurity has been added. The formation of the second base conductive film 310 may be performed by the CVD method. The formation of the second base conductive film 310 is continuously performed until the first trench 215 is completely filled.

Next, referring to FIG. 14I, unnecessary portions of the second base conductive film 310 are removed. This step includes a step of removing the second base conductive film 310, the second base insulating film 308, the third mask 306, the first base insulating film 305, and the second mask 303 until the first mask 302 is exposed by the grinding method. The grinding method may be a CMP (chemical mechanical polishing) method. In this step, the etching method (wet etching method and/or dry etching method) may be employed instead of the grinding method. The buried conductor 217 is formed by the second base conductive film 310 remaining in the first trench 215 (fifth step).

Next, referring to FIG. 14J, the first mask 302 is removed from the surface 301 of the semiconductor wafer 300 by means of the etching method.

Next, referring to FIG. 14K, the fourth mask 311 is laminated on the surface 301 of the semiconductor wafer 300, the second insulating film 220, and the buried conductor 217. The fourth mask 311 exposes regions in which the first shallow trench 242 and the second shallow trench 247 are to be formed, and covers other regions except these regions in the surface 301.

Next, the semiconductor wafer 300, the second insulating film 220, and the buried conductor 217 are each selectively removed by the etching method through the fourth mask 311. Hence, the first shallow trench 242 and the second shallow trench 247 are formed. Thereafter, the fourth mask 311 is removed. The etching method may be the dry etching method and/or the wet etching method.

Next, referring to FIG. 14L, a fourth base insulating film 312 that serves as a base of both the first second buried insulator 243 and the second buried insulator 248 is formed on the surface 301. The fourth base insulating film 312 includes an oxide film. The oxide film may be silicon oxide (SiO₂), or may be tetraethyl orthosilicate (TEOS). The fourth base insulating film 312 may be formed by the CVD method.

Next, referring to FIG. 14M, unnecessary portions of the fourth base insulating film 312 are removed. In this step, the fourth base insulating film 312 is removed by the grinding method until the surface 301 is exposed. The grinding method may be the CMP method. Hence, the first buried insulator 243 is formed by the fourth base insulating film 312 remaining in the first shallow trench 242, and the second buried insulator 248 is formed by the fourth base insulating film 312 remaining in the second shallow trench 247. In other words, the third trench structure 241 and the fourth trench structure 246 are formed. In this step, the etching method (wet etching method and/or dry etching method) may be employed instead of the grinding method.

Additionally, the fifth trench structure 260 (see FIG. 12) is formed in the surface 301 of the semiconductor wafer 300 in parallel with the formation of the third trench structure 241 and the fourth trench structure 246.

Next, a functional device, such as a MISFET cell 250 (see FIG. 12), is formed on the surface 301 side of the semiconductor wafer 300. Hence, the active region 211 is formed on the surface 301 side of the semiconductor wafer 300. The semiconductor device 1E is formed through these steps including the above.

According to the semiconductor device 1E according to the third embodiment of the present disclosure, in the element isolation portion 212, the second trench 219 is formed on the active region 211 side of the first trench 215 adjacently to the first trench 215 in which the buried conductor 217 is buried. The hollow air gap AG5 is formed inside the second trench 219 by the second insulating film 220 formed on the side surfaces 221 and 222 and the bottom surface 223 of the second trench 219. The buried conductor 217 is electrically insulated from the active region 211 by means of the air gap AG5 and the second insulating film 220 formed on the active region 211 side with respect to the buried conductor 217. This makes it possible to electrically excellently insulate the buried conductor 217 from the active region 211. Therefore, it is possible to improve the withstand voltage in the lateral direction along the first principal surface 203 of the semiconductor chip 202.

Additionally, the air gap AG5 is sandwiched between the region 208A on the active region 211 side with respect to the second trench 219 in the buried region 208 and the buried conductor 217. In other words, the air gap AG5 is formed so as to be sandwiched between the buried region 208 and the buried conductor 217 in the lateral direction along the first principal surface 203. There is a concern that the withstand voltage of the semiconductor device 1E might be reduced if electric field concentration occurs in a boundary part 208B (see FIG. 13) between the buried region 208 and the buried conductor 217 in the side surfaces 221 and 222 of the second trench 219. The air gap AG5 is sandwiched between the region 208A and the buried conductor 217, and therefore it is possible to lessen the electric field concentration occurring in the boundary part 208B between the buried region 208 and the buried conductor 217. This makes it possible to improve the withstand voltage in the lateral direction along the first principal surface 203 of the semiconductor chip 202.

Additionally, in this embodiment, the hollow air gap AG5 is formed by the second insulating film 220 inside the second trench 219. Therefore, it is possible to escape the stress generated in the second insulating film 220 to the air gap AG5. This makes it possible to prevent the occurrence of crystal defects in the second insulating film 220. Therefore, it is possible to lessen the electric field concentration mentioned above while preventing the occurrence of crystal defects.

For example, it is expected to improve the withstand voltage by the second insulating film 220 that is a thick film having the width of the second trench 219 by employing a manner in which the second trench 219 is completely backfilled with the second insulating film 220. However, in this embodiment, the entirety of the outer surface of the second insulating film 220 that is a thick film is contiguous to the inner surface of the second trench 219, and therefore it is difficult to escape the stress generated in the second insulating film 220. In contrast, if the air gap AG5 is formed, it is possible to use the air gap AG5 as a space for reducing the stress generated in the second insulating film 220.

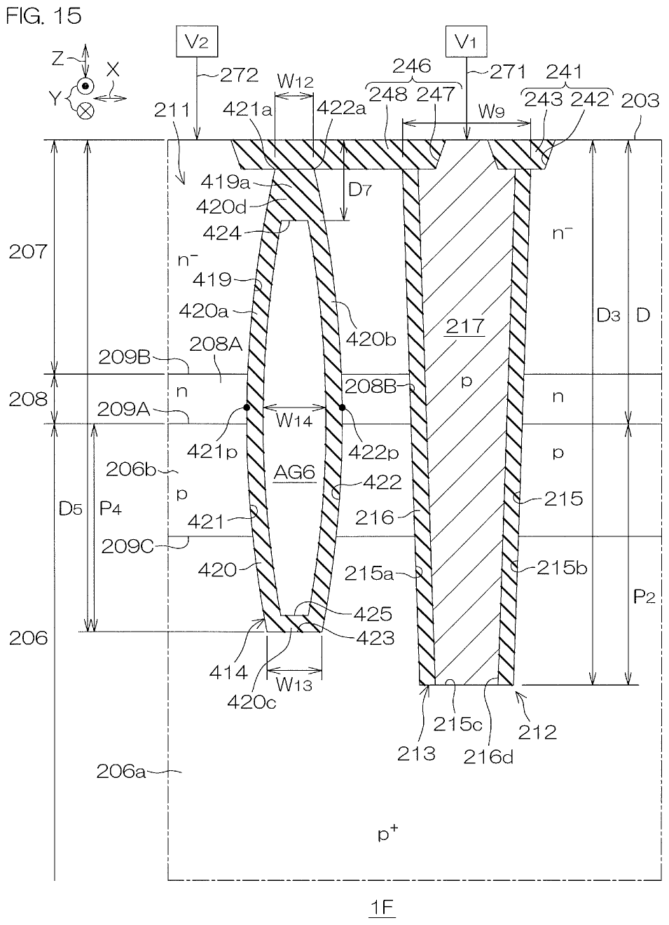

FIG. 15 corresponds to FIG. 13, and is a cross-sectional enlarged view of a main portion of a semiconductor device 1F according to a fourth embodiment of the present disclosure. In the fourth embodiment, only a part chiefly different from the third embodiment will be described, and the same reference sign is assigned to a constituent that is the same as the constituent described above, and a description of the same constituent is omitted.

The fourth embodiment differs from the third embodiment in the point that the element isolation portion 212 includes a second trench structure 414 instead of the second trench structure 214.

The second trench structure 414 includes a second trench 419 and a second insulating film 420 formed on an inner surface of the second trench 419. The second trench 419 differs from the second trench 219 according to the third embodiment in its shape.

The second trench 419 is formed in the first principal surface 203 so as to penetrate through the boundary part 209A between the first impurity region 206 and the buried region 208, and demarcates a wall surface of the second trench structure 414. The second trench 419 has a sixth depth D₆. In the example of FIG. 15, the sixth depth D₆ of the second trench 419 is shallower than the third depth D₃ of the first trench 215 (D₆<D₃). In other words, the sixth depth D₆ of the second trench 419 differs from the third depth D₃ of the first trench 215. The second trench 419 penetrates through the buried region 208 so as to reach the first impurity region 206. In detail, the second trench 419 extends from the first principal surface 203 toward the second principal surface 204 so as to reach the high concentration region 206a of the first impurity region 206, and penetrates through the buried region 208 and the low concentration region 206b of the first impurity region 206. The sixth depth D₆ of the second trench 419 may be deeper than the third depth D₃ of the first trench 215 (D₆>D₃). The sixth depth D₆ of the second trench 419 may be substantially equal to the third depth D₃ of the first trench 215 (D₆≈D₃).

The second trench 419 protrudes from the boundary part 209A between the first impurity region 206 and the buried region 208 toward the second principal surface 204 by a fourth amount of protrusion P₄. The fourth amount of protrusion P₄ may exceed the distance D between the first principal surface 203 and the boundary part 209A (P₄>D). The fourth amount of protrusion P₄ may be equal to or less than the distance D between the first principal surface 203 and the boundary part 209A (P₄<D).

The second trench 419 includes a first side surface (inner surface) 421 and a second side surface (inner surface) 422 facing each other and a bottom surface (inner surface, bottom portion) 423 connecting the first side surface 421 and the second side surface 422. The first side surface 421 is a side surface of the active region 211 side. The second side surface 422 is a side surface on the side opposite to the active region 211 side. In this embodiment, the first side surface 421 is an inner peripheral surface of the second trench 419, and the side surface 422 is an outer peripheral surface of the second trench 419. The first side surface 421 and the second side surface 422 are each formed in an arched shape that is convex outwardly from the second trench 419 (toward the active region 211 side) in a cross-sectional view. The second trench 419 differs from the second trench 219 according to the third embodiment chiefly in this respect.

The first side surface 421 is formed so as to straddle the second impurity region 207, the buried region 208, the low concentration region 206b, and the high concentration region 206a. The first side surface 421 is contiguous to the second impurity region 207, the buried region 208, the low concentration region 206b, and the high concentration region 206a. The first side surface 421 is formed in an arched shape that is convex outwardly from the second trench 419 (toward the active region 211 side) in a cross-sectional view. In other words, the first side surface 421 has a shape in which a halfway portion in the depth direction of the second trench 419 is convex more outwardly from the second trench 419 (active region 211 side) than an open end 421a in a cross-sectional view. A top portion 421p of the first side surface 421 is formed at a halfway portion in the depth direction of the second trench 419. The top portion 421p of the first side surface 421 is contiguous to the buried region 208.

The second side surface 422 is formed so as to straddle the second impurity region 207, the buried region 208, the low concentration region 206b, and the high concentration region 206a. The second side surface 422 is contiguous to the second impurity region 207, the buried region 208, the low concentration region 206b, and the high concentration region 206a. The second side surface 422 is formed in an arched shape that is convex outwardly from the second trench 419 (the side opposite to the active region 211 side) in a cross-sectional view. In other words, the second side surface 422 has a shape in which a halfway portion in the depth direction of the second trench 419 is convex more outwardly from the second trench 419 (the side opposite to the active region 211 side) than an open end 422a in a cross-sectional view. A top portion 422p of the second side surface 422 is formed at a halfway portion in the depth direction of the second trench 419. The top portion 422p of the second side surface 422 is contiguous to the buried region 208.

The bottom surface 423 is formed in the high concentration region 206a. The bottom surface 423 is contiguous to the high concentration region 206a. In the example of FIG. 15, the bottom surface 423 is a flat surface parallel to the first principal surface 203. The bottom surface 423 may have a round shape that swells toward the second principal surface 204 side in a cross-sectional view.

The second trench 419 has a twelfth width W₁₂ in the open ends 221a and 222a. The twelfth width W₁₂ is a width in the direction perpendicular to the direction in which the second trench 419 extends in a plan view. The twelfth width W₁₂ is narrower than the ninth width W₉ (W₁₂<W₉). The twelfth width W₁₂ may be not less than 0.05 μm and not more than 5 km. Preferably, the twelfth width W₁₂ is not less than 1 μm and not more than 3 μm. The twelfth width W₁₂ may be substantially equal to the ninth width W₉ (W₁₂≈W₉), or may be wider than the ninth width W₉ (W₁₂>W₉).

The bottom surface 423 of the second trench 419 has a thirteenth width W₁₃. The thirteenth width W₁₃ is a width in the direction perpendicular to the direction in which the second trench 419 extends in a plan view. The thirteenth width W₁₃ is substantially equal to the twelfth width W₁₂ (W₁₃≈W₁₂), and is narrower than the ninth width W₉ (W₁₃<W₉). The thirteenth width W₁₃ may be wider than the twelfth width W₁₂ (W₁₃>W₁₂), or may be narrower than the twelfth width W₁₂ (W₁₃<W₁₂). The thirteenth width W₁₃ may be substantially equal to the ninth width W₉ (W₁₃≈W₉), or may be wider than the ninth width W₉ (W₁₃>W₉).

The second trench 419 is not necessarily required to reach the high concentration region 206a of the first impurity region 206. In this case, the second trench 419 may extend from the first principal surface 203 toward the second principal surface 204 so as to reach the low concentration region 206b of the first impurity region 206, and may penetrate through the buried region 208. Additionally, in this case, the bottom surface 423 may be formed in the low concentration region 206b.

The second insulating film 420 is formed on the inner surface of the second trench 419. Inside the second trench 419, a hollow air gap AG6 is demarcated by the second insulating film 420. In other words, the second insulating film 420 is formed on the inner surface of the second trench 419 so that the hollow air gap AG6 is formed inside the second trench 419. The hollow air gap AG6 is an enclosed space closed by the second insulating film 420, and the inner surface of the second insulating film 420 is exposed over the entirety of the hollow air gap AG6. The second insulating film 420 includes a first part 420a covering the first side surface 421, a second part 420b covering the second side surface 422, a third part 420c covering the bottom surface 423, and a fourth part 420d formed at the open portion 419a. The first part 420a covers the second impurity region 207, the buried region 208, the low concentration region 206b, and the high concentration region 206a in the first side surface 421. The second part 420b covers the second impurity region 207, the buried region 208, the low concentration region 206b, and the high concentration region 206a in the second side surface 422. The third part 420c covers the high concentration region 206a in the bottom surface 423. The fourth part 420d connects the first part 420a and the second part 420b in the open portion 419a. The fourth part 420d closes the open portion 419a at the upper part of the air gap AG6. The first part 420a and the second part 420b are connected only in the open portion 419a of the second trench 419.

The air gap AG6 is a space demarcated by the first part 420a, by the second part 420b, by the third part 420c, and by the fourth part 420d, and houses air in the inside. The air gap AG6 is formed in a shape in which the central portion in the depth direction of the second trench 419 becomes convex outwardly from the second trench 419. The first part 420a and the second part 420b sandwich the air gap AG6 in the direction perpendicular to the direction in which the second trench 419 extends in a plan view.

The air gap AG6 has a fourteenth width W₁₄. The fourteenth width W₁₄ is a maximal width in the direction perpendicular to the direction in which the second trench 419 extends in a plan view. The fourteenth width W₁₄ may be 0.001 to 1.0 times as large as the depth of the second trench 419.

In the example of FIG. 15, an upper end 424 of the air gap AG6 is closer to the first principal surface 203 side with respect to the boundary part 209B between the second impurity region 207 and the buried region 208. A lower end 425 of the air gap AG6 is closer to the second principal surface 204 side with respect to the boundary part 209C between the low concentration region 206b and the high concentration region 206a.

In detail, the upper end 424 of the air gap AG6 has a seventh depth D₇. The seventh depth D₇ is 0.1 μm to 30 μm. In the example of FIG. 15, the seventh depth D₇ is shorter than the distance between the upper end 424 of the air gap AG6 and the boundary part 209B between the second impurity region 207 and the buried region 208. The seventh depth D₇ may be equal to or more than the distance between the upper end 424 and the boundary part 209B. Additionally, the lower end 425 of the air gap AG6 may be located at the same position as the boundary part 209C between the low concentration region 206b and the high concentration region 206a, or may be located at a position between the boundary part 209C and the boundary part 209A between the first impurity region 206 and the buried region 208 with regard to the depth direction of the second trench 419.

The air gap AG6 is sandwiched between the region 208A on the active region 211 side with respect to the second trench 419 in the buried region 208 and the buried conductor 217 in the lateral direction along the first principal surface 203. In other words, the air gap AG6 is formed so as to be sandwiched between the buried region 208 and the buried conductor 217 in the lateral direction along the first principal surface 203. Additionally, the air gap AG6 is sandwiched between a region on the active region 211 side with respect to the second trench 419 in the low concentration region 206b and the buried conductor 217 in the lateral direction along the first principal surface 203.

The manufacturing process of the semiconductor device 1F is in common with the manufacturing process of the semiconductor device 1E according to the third embodiment. Therefore, a detailed description of the manufacturing process of the semiconductor device 1F is omitted. The step of forming the second trench 419 in the surface 301 of the semiconductor wafer 300 (see FIG. 14A, etc.) is performed in the same way as the step described with reference to FIG. 14C. In other words, at least either one of an etching temperature in the dry etching method and a flow rate of etching gas in the dry etching method is regulated, and, as a result, the second trench 419 having the first side surface 421 and the second side surface 422 each of which is formed in an arched shape that is outwardly convex in a cross-sectional view.

According to the semiconductor device 1F according to the fourth embodiment of the present disclosure, operations and effects equivalent to the operations and effects described in relation to the third embodiment are fulfilled.

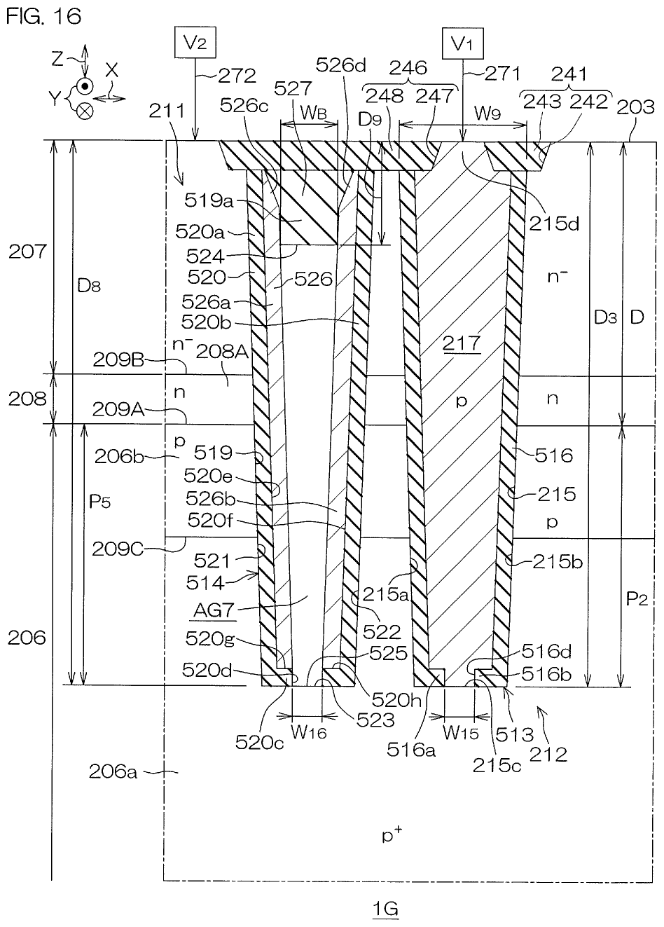

FIG. 16 corresponds to FIG. 13, and is a cross-sectional enlarged view of a main portion of a semiconductor device 1G according to a fifth embodiment of the present disclosure. In the fifth embodiment, only a part chiefly different from the third embodiment will be described, and the same reference sign is assigned to a constituent that is the same as the constituent described above, and a description of the same constituent is omitted.

The fifth embodiment differs from the third embodiment in the point that the element isolation portion 212 includes a first trench structure 513 instead of the first trench structure 213 and in the point that the element isolation portion 212 includes a second trench structure 514 instead of the second trench structure 214.

The first trench structure 513 differs from the first trench structure 213 according to the third embodiment in the point that the first trench structure 513 includes a first insulating film 516 instead of the first insulating film 216. The first insulating film 516 differs from the first insulating film 216 according to the third embodiment in the point that the first insulating film 516 includes an opening 516d instead of the opening 216d. The first insulating film 516 covers not only the side surface 215a and the side surface 215b but also a part of the bottom surface (inner surface) 215c. In detail, the first insulating film 516 has protruding portions 516a and 516b that inwardly protrude in the bottom surface 215c. The opening 516d is formed at a position that is at a distance from the side surfaces 215a and 215b to the inside of the first trench 215 in the bottom surface 215c of the first trench 215. The opening 516d has a fifteenth width W₁ₛ as an opening width. The opening 516d exposes the high concentration region 206a of the first impurity region 206 from the bottom surface 215c of the first trench 215. That is, the buried conductor 217 is mechanically connected to the first impurity region 206 (high concentration region 206a) in an exposed portion exposed from the opening 516d of the first insulating film 516. In this embodiment, the opening 516d is formed in an annular shape extending along the first trench 215 in a plan view. The opening 516d may be formed in a with-end belt shape extending along the first trench 215 in a plan view. A configuration excluding the opening 516d in the first insulating film 516 is the same as the first insulating film 216 according to the third embodiment.

The second trench structure 514 includes a second trench 519, a second insulating film 520 formed on the inner surface of the second trench 519, a conductive film 526 formed on the inner surface of the second insulating film 520, and a third insulating film 527 covering the conductive film 526 from above. The second trench structure 514 insulates the active region 211 and the buried conductor 217 of the first trench structure 213.

The second trench 519 is formed in the first principal surface 203 so as to penetrate through the boundary part 209A between the first impurity region 206 and the buried region 208, and demarcates a wall surface of the second trench structure 514. The second trench 519 has an eighth depth D₈. The eighth depth D₈ of the second trench 519 may be substantially equal to the third depth D₃ of the first trench 215 (D₈≈D₃). The second trench 519 penetrates through the buried region 208 so as to reach the first impurity region 206. In detail, the second trench 519 extends from the first principal surface 203 toward the second principal surface 204 so as to reach the high concentration region 206a of the first impurity region 206, and penetrates through the buried region 208 and the low concentration region 206b of the first impurity region 206. The second trench 519 is formed in a tapered shape whose width becomes larger from a bottom surface 523 described below toward the first principal surface 203 in a cross-sectional view. The second trench 519 protrudes from the boundary part 209A between the first impurity region 206 and the buried region 208 toward the second principal surface 204 by a fifth amount of protrusion P₅. The fifth amount of protrusion P₅ may exceed the distance D between the first principal surface 203 and the boundary part 209A (P₅>D). The fifth amount of protrusion P₅ may be equal to or less than the distance D between the first principal surface 203 and the boundary part 209A (P₅≤D).

The second trench 519 includes a first side surface (inner surface) 521 and a second side surface (inner surface) 522 facing each other and a bottom surface (inner surface, bottom portion) 523 connecting the first side surface 521 and the second side surface 522. The first side surface 521 is a side surface of the active region 211 side. The second side surface 522 is a side surface on the side opposite to the active region 211 side. In this embodiment, the first side surface 521 is an inner peripheral surface of the second trench 519, and the side surface 522 is an outer peripheral surface of the second trench 519.

The first side surface 521 is formed so as to straddle the second impurity region 207, the buried region 208, the low concentration region 206b, and the high concentration region 206a. The first side surface 521 is an inclined surface that advances to a more inward side of the second trench 519 (toward the side opposite to the active region 211 side) in proportion to an approach to the second principal surface 204. The inclination angle with respect to the first principal surface 203 of the first side surface 521 is the same as the inclination angle with respect to the first principal surface 203 of the side surface 215a of the first trench 215. The inclination angle with respect to the first principal surface 203 of the second side surface 522 is the same as the inclination angle with respect to the first principal surface 203 of the side surface 215b of the first trench 215. In this embodiment, the bottom surface 523 is a flat surface parallel to the first principal surface 203. The second trench 519 has the same shape as the first trench 215 in a cross-sectional view.

The second insulating film 520 is formed on the inner surface of the second trench 519. The second insulating film 520 includes a first part 520a covering the first side surface 521, a second part 520b covering the second side surface 522, and a third part 520c covering the bottom surface 523. The first part 520a covers the second impurity region 207, the buried region 208, the low concentration region 206b, and the high concentration region 206a in the first side surface 521. The second part 520b covers the second impurity region 207, the buried region 208, the low concentration region 206b, and the high concentration region 206a in the second side surface 522. The third part (bottom portion) 520c covers the high concentration region 206a in the bottom surface 523.

The third part 520c of the second insulating film 520 has an opening 520d that exposes the high concentration region 206a of the first impurity region 206 from the bottom surface 523. In this embodiment, the opening 520d is formed in an annular shape extending along the second trench 519 in a plan view. The opening 520d may be formed in a with-end belt shape extending along the second trench 519 in a plan view. The opening 520d is formed at a position that is at a distance from the side surfaces 521 and 522 to the inside of the second trench 519 in the bottom surface 523 of the second trench 519. The opening 520d has a sixteenth width W₁₆ as an opening width. The sixteenth width W₁₆ is the same as the fifteenth width W₁₅.

The second insulating film 520 may be an oxide film. The oxide film may be silicon oxide (SiO₂), or may be tetraethyl orthosilicate (TEOS).

The conductive film 526 is formed on the inner surface of the second insulating film 520. The conductive film 526 is electrically insulated from the second impurity region 207 and from the buried region 208 by means of the second insulating film 520, and is in an electrically floating state. The conductive film 526 includes a first part 526a laminated on the first part 520a and a second part 526b laminated on the second part 520b. The first part 526a and the second part 526b are physically and electrically separated from each other with both the third insulating film 527 and an air gap AG7 described later between the first part 526a and the second part 526b. The first part 526a covers a side surface (inner surface) 520e of the first part 520a and an upper surface (inner surface) 520g on the first side surface 521 side in the third part 520c. The side surface 520e of the first part 520a and the upper surface 520g of the third part 520c face the air gap AG7 described later. The second part 526b covers a side surface (inner surface) 520f of the second part 520b and an upper surface (inner surface) 520h on the second side surface 522 side in the third part 520c. The side surface 520f of the first part 520a and the upper surface 520h of the third part 520c face the air gap AG7 described later. An upper end portion 526c of the first part 526a and an upper end portion 526d of the second part 526b each become smaller in thickness in proportion to an approach to the first principal surface 203.

The conductive film 526 is polysilicon. In this embodiment, this polysilicon is doped-polysilicon to which a p-type (first conductivity type) impurity (for example, boron (B)) has been added.

The third insulating film 527 is formed at an open portion 519a of the second trench 519. The third insulating film 527 is sandwiched between an upper portion of the first part 526a of the conductive film 526 and an upper portion of the second part 526b of the conductive film 526. The third insulating film 527 is contiguous to the upper portion of the first part 526a and to the upper portion of the second part 526b.

In more detail, the third insulating film 527 is sandwiched between the upper end portion 526c of the conductive film 526 and the upper end portion 526d of the conductive film 526. The third insulating film 527 is contiguous to the upper end portion 526c and to the upper end portion 526d. The third insulating film 527 faces the air gap AG7 described as follows from above. The third insulating film 527 closes the open portion 519a at the upper part of the air gap AG7.

The air gap AG7 is a space demarcated by the first part 526a and the second part 526b of the conductive film 526, by the third part 520c of the second insulating film 520, by the third insulating film 527, and by the bottom surface 523, and houses air in the inside. The air gap AG7 is formed in a tapered shape whose width becomes smaller toward the second principal surface 204. The first part 520a and the second part 520b of the second insulating film 520 sandwich the air gap AG7 through the first part 526a and the second part 526b, respectively, in the direction perpendicular to the direction in which the second trench 519 extends in a plan view.

The air gap AG7 has the width W_{B}. The width W_{B} is a maximal width in the direction perpendicular to the direction in which the second trench 519 extends in a plan view. The width W_{B} may be 0.001 to 1.0 times as large as the depth of the second trench 519.

In the example of FIG. 16, an upper end 524 of the air gap AG7 is closer to the first principal surface 203 side with respect to the boundary part 209B between the second impurity region 207 and the buried region 208. A lower end 525 of the air gap AG7 is closer to the second principal surface 204 side with respect to the boundary part 209C between the low concentration region 206b and the high concentration region 206a.

In detail, the upper end 524 of the air gap AG7 has a ninth depth D₉. The ninth depth D₉ is 0.1 μm to 30 μm. In the example of FIG. 16, the ninth depth D₉ is shorter than the distance between the upper end 524 of the air gap AG7 and the boundary part 209B between the second impurity region 207 and the buried region 208. The ninth depth D₉ may be equal to or more than the distance between the upper end 524 and the boundary part 209B.

Additionally, in detail, the lower end 525 of the air gap AG7 reaches the bottom surface 523 of the second trench 519. The lower end 525 of the air gap AG7 may be located at the same position as the boundary part 209C between the low concentration region 206b and the high concentration region 206a, or may be located at a position between the boundary part 209C and the boundary part 209A between the first impurity region 206 and the buried region 208 with regard to the depth direction of the second trench 519.

The air gap AG7 is sandwiched between the region 208A on the active region 211 side with respect to the second trench 519 in the buried region 208 and the buried conductor 217 in the lateral direction along the first principal surface 203. In other words, the air gap AG7 is formed so as to be sandwiched between the buried region 208 and the buried conductor 217 in the lateral direction along the first principal surface 203. Additionally, the air gap AG7 is sandwiched between a region on the active region 211 side with respect to the second trench 519 in the low concentration region 206b and the buried conductor 217 in the lateral direction along the first principal surface 203.

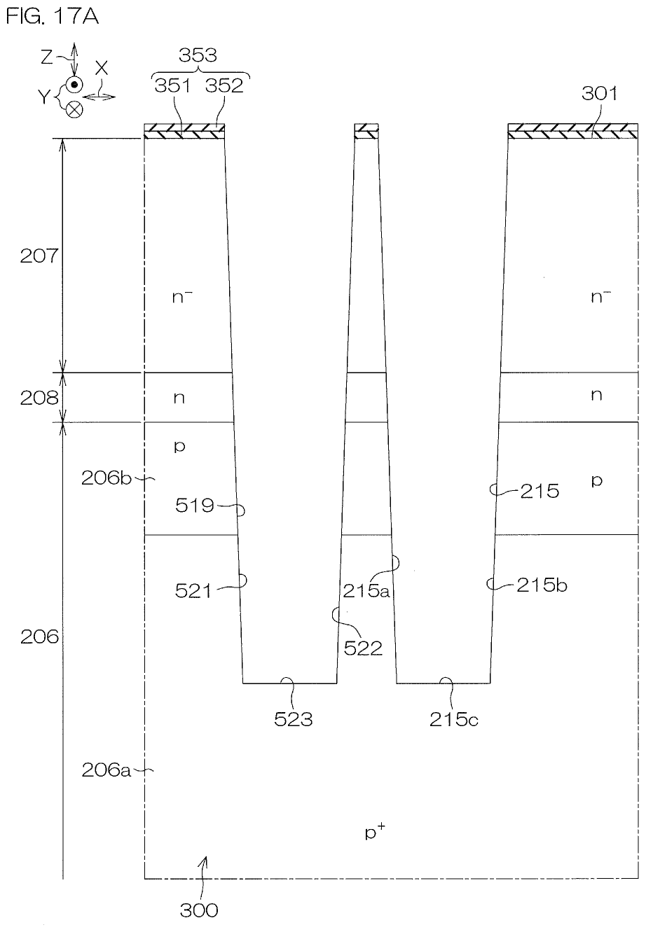

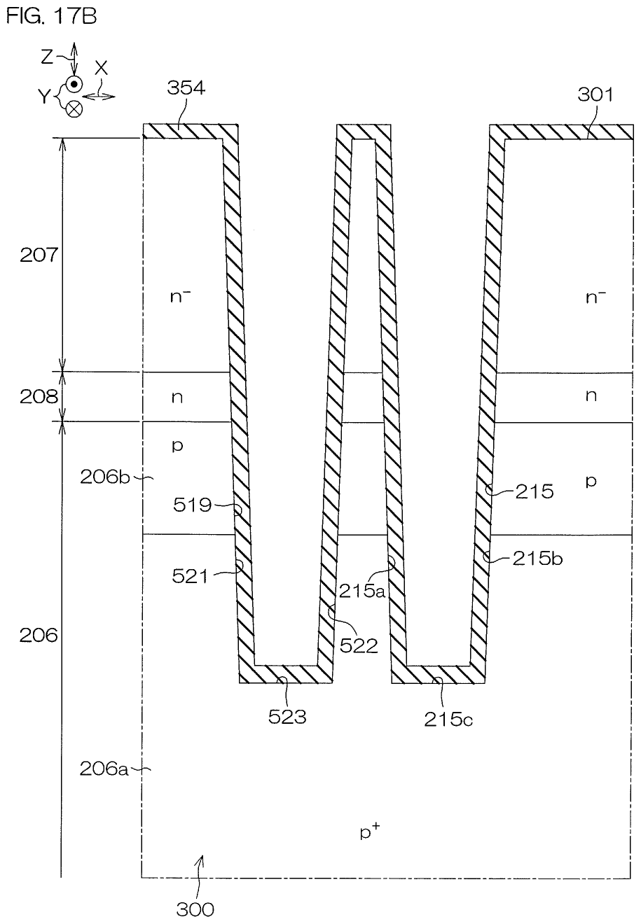

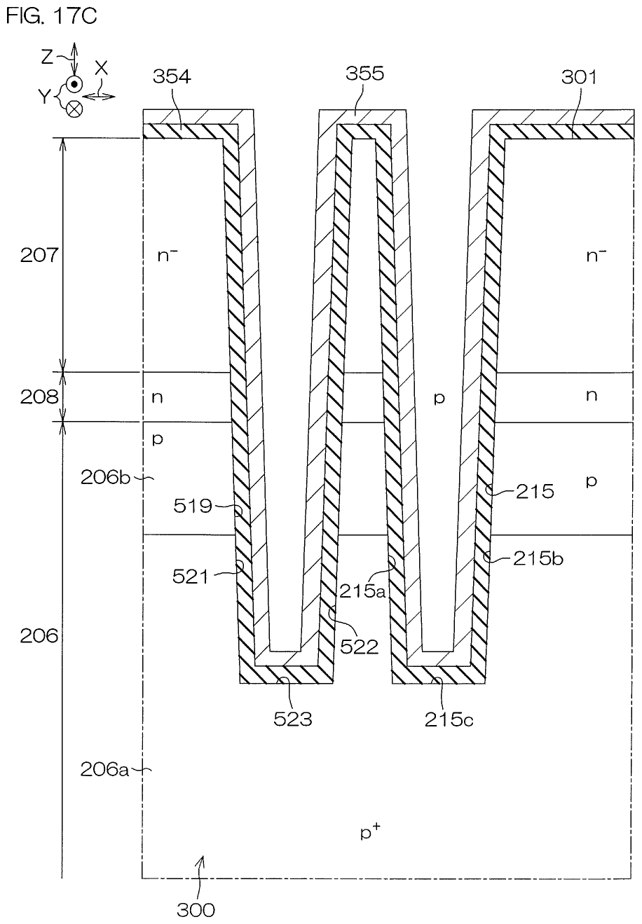

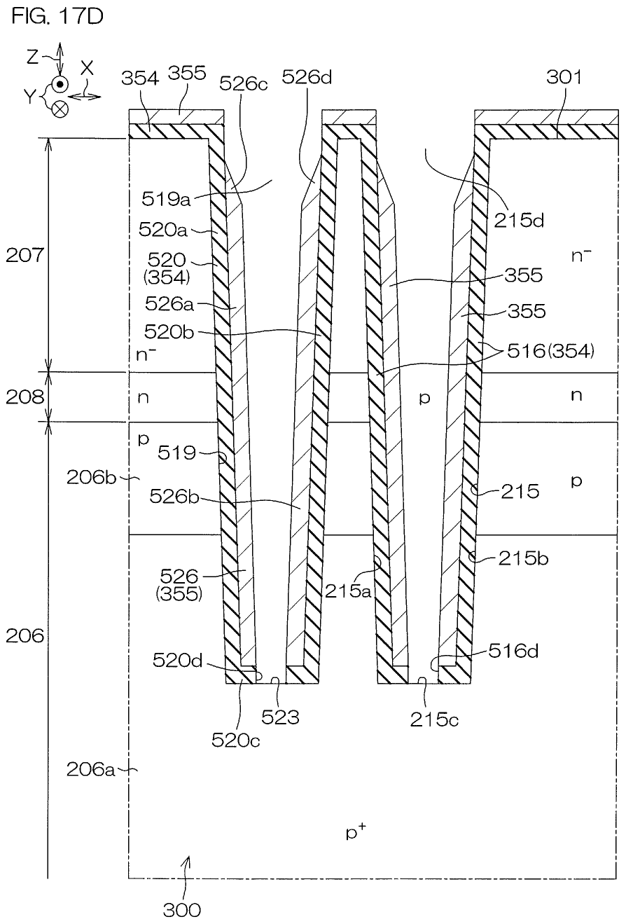

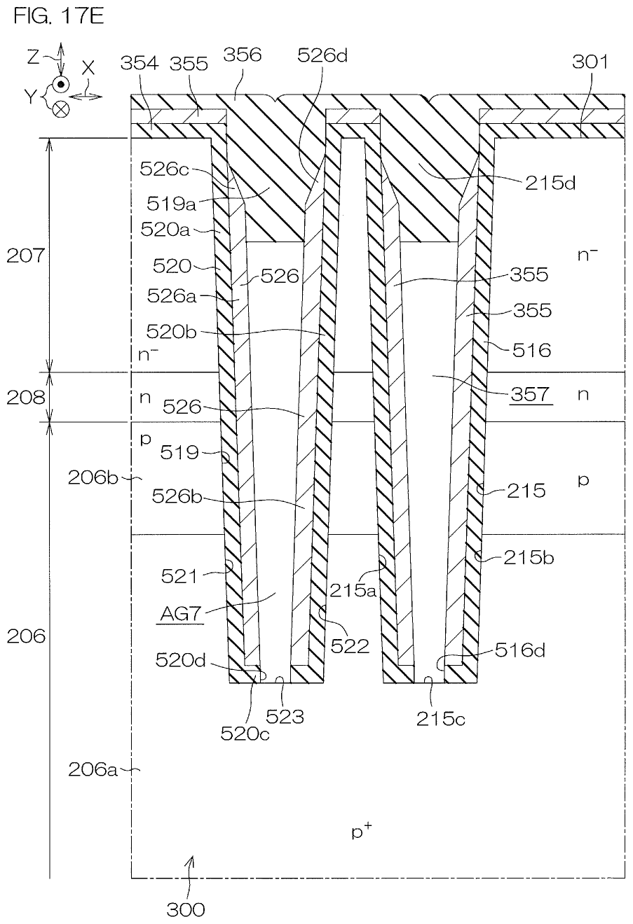

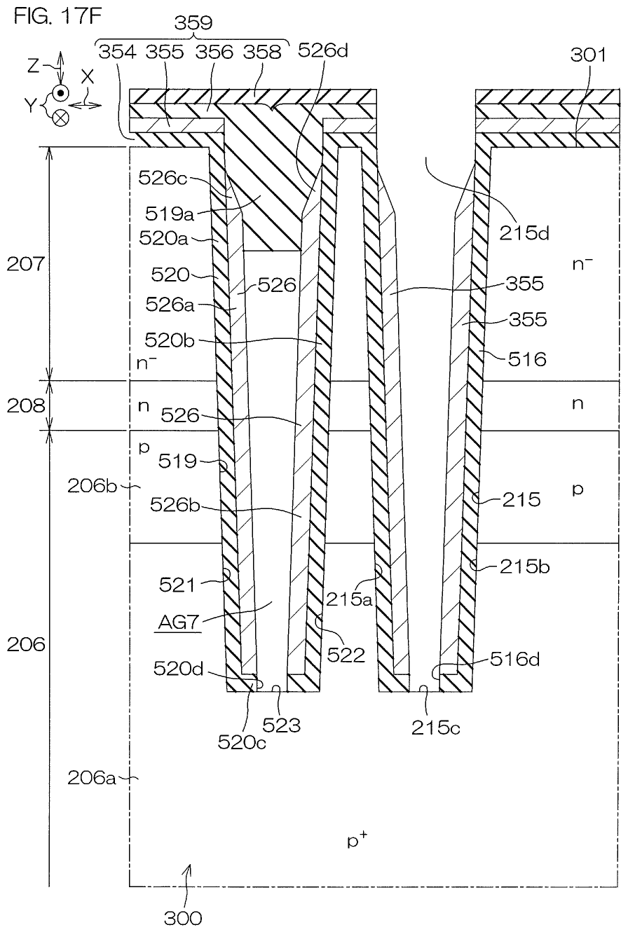

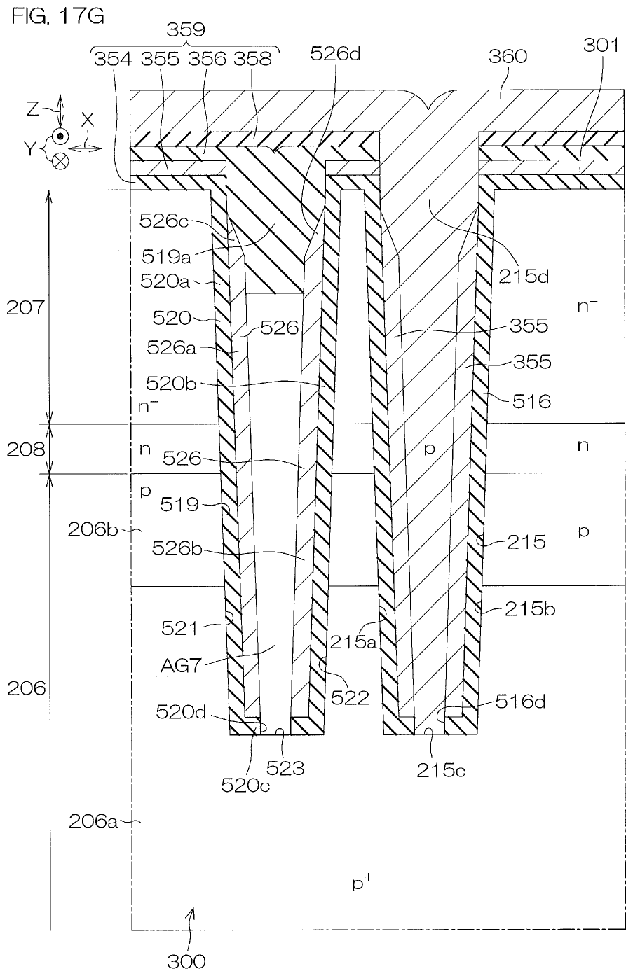

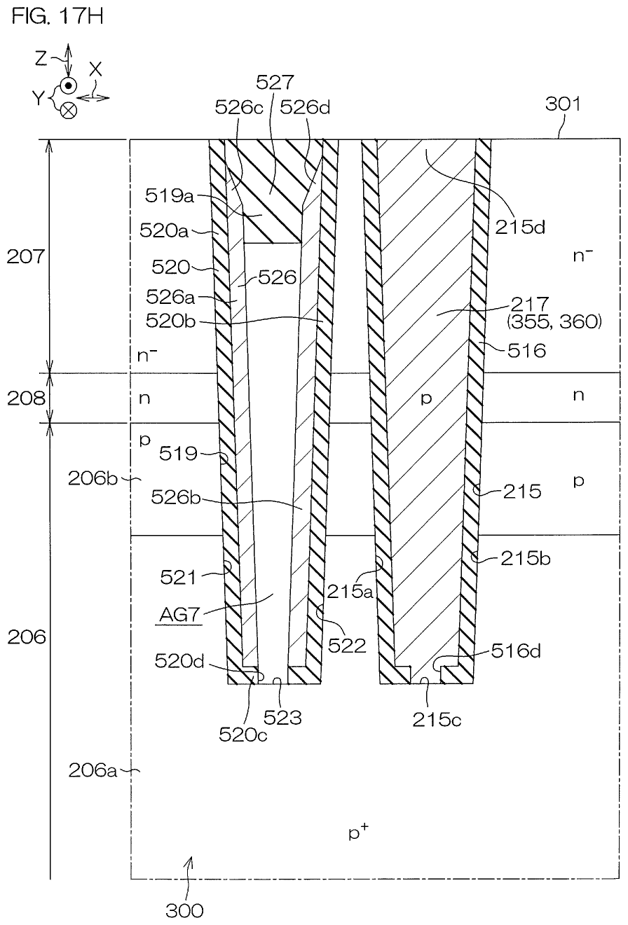

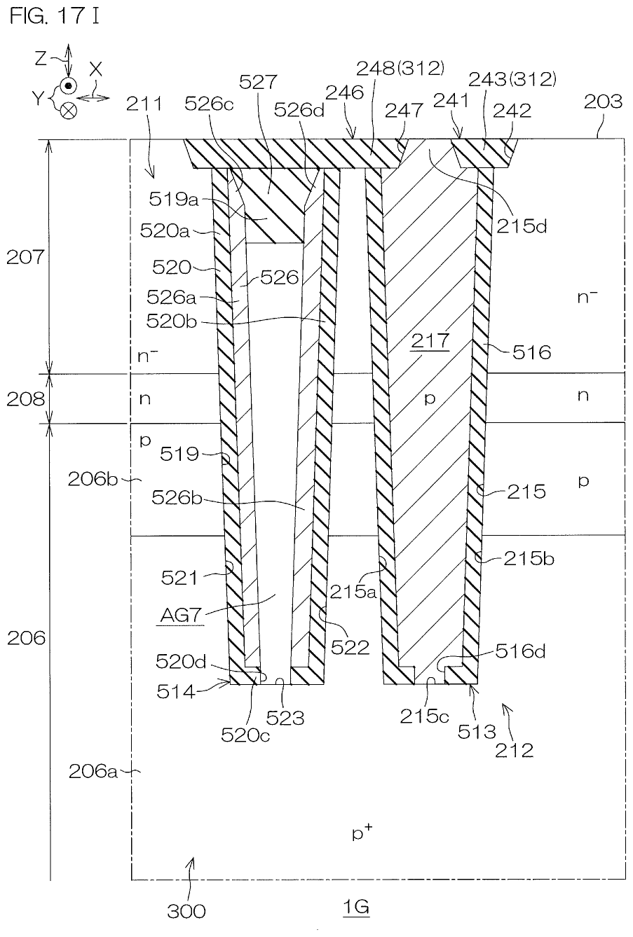

FIG. 17A to FIG. 17I are views shown to describe a process of manufacturing the semiconductor device 1G according to the fifth embodiment of the present disclosure, and are longitudinal sectional views of a part corresponding to FIG. 16.

Referring to FIG. 17A, the semiconductor wafer 300 that serves as a base of the semiconductor chip 202 is prepared to manufacture the semiconductor device 1G. The semiconductor wafer 300 is a semiconductor wafer equivalent to the semiconductor wafer 300 (see FIG. 14A) used in the manufacturing process of the semiconductor device 1E according to the third embodiment, and therefore the same reference sign is assigned, and a description of the semiconductor wafer 300 is omitted.

Next, a first mask 351 and a second mask 352 are laminated in that order on the surface 301 of the semiconductor wafer 300. The first mask 351 may be a silicon nitride film. The first mask 351 may be formed by the CVD method. The second mask 352 may be silicon oxide (SiO₂). The second mask 352 may be formed by the CVD method. The first mask 351 and the second mask 352 are selectively removed by the etching method, and, as a result, the first mask 351 and the second mask 352 become a first hard mask 353. The first hard mask 353 exposes regions in which the first trench 215 and the second trench 519 are to be formed, and covers other regions except these regions in the surface 301.

The semiconductor wafer 300 is selectively removed by the etching method through the first hard mask 353. Hence, the first trench 215 and the second trench 519 are formed in the surface 301 of the semiconductor wafer 300 (first step). The first trench 215 includes the side surfaces 215a and 215b and the bottom surface 215c. The second trench 519 includes the first side surface 521, the second side surface 522, and the bottom surface 523. The etching method may be a dry etching method and/or a wet etching method. Thereafter, the first hard mask 353 is removed.

Next, referring to FIG. 17B, a first base insulating film 354 that serves as a base of both the first insulating film 516 and the second insulating film 520 is formed at the surface 301. Hence, the side surfaces 215a and 215b and the bottom surface 215c of the first trench 215 are covered by the first base insulating film 354 (second step). Additionally, the side surfaces 521 and 522 and the bottom surface 523 of the second trench 519 are covered by the first base insulating film 354 (second step). The first base insulating film 354 includes an oxide film. The oxide film may be silicon oxide (SiO₂), or may be tetraethyl orthosilicate (TEOS). The first base insulating film 354 may be formed by an oxidation treatment method (for example, thermal oxidation treatment method). The first base insulating film 354 may be formed by the CVD method.

Next, referring to FIG. 17C, a first base conductive film 355 that serves as a base of both the conductive film 526 and the buried conductor 217 is formed at the surface 301. Hence, the first base conductive film 355 is laminated inside the first base insulating film 354 in the side surfaces 215a and 215b and the bottom surface 215c of the first trench 215 (third step). Additionally, the first base conductive film 355 is laminated on the inside of the first base insulating film 354 in the side surfaces 521 and 522 and the bottom surface 523 of the second trench 519 (third step). In this embodiment, the first base conductive film 355 includes doped-polysilicon to which a p-type (first conductivity type) impurity has been added.

Next, referring to FIG. 17D, a part, which covers the bottom surface 215c of the first trench 215, of the first base conductive film 355, a part, which covers the bottom surface 523 of the second trench 519, of the first base conductive film 355, a part, which covers the central portion of the bottom surface 215c of the first trench 215 (a position at a distance from the side surfaces 215a and 215b to the inside of the 215 in the bottom surface 215c), of the first base insulating film 354, and a part, which covers the central portion of the bottom surface 523 of the second trench 519 (a position at a distance from the side surfaces 521 and 522 to the inside of the second trench 519 in the bottom surface 523), of the first base insulating film 354 are removed by the etching method. Preferably, the etching method is an anisotropic etching method. For example, the etching method may be an RIE method as an example of the dry etching method. Hence, the opening 516d that exposes the central portion of the bottom surface 215c of the first trench 215 is formed in the first base insulating film 354 inside the first trench 215. The first insulating film 516 is formed by the first base insulating film 354 covering the side surfaces 215a and 215b of the first trench 215. Additionally, the opening 520d that exposes the central portion of the bottom surface 523 of the second trench 519 is formed in the first base insulating film 354 inside the second trench 519. The second insulating film 520 is formed by the first base insulating film 354 covering the side surfaces 521 and 522 of the second trench 519. The second insulating film 520 includes the first part 520a, the second part 520b, and the third part 520c.

The first base conductive film 355 covering the side surfaces 215a and 215b of an open portion 215d of the first trench 215 is etched through the etching operation.

Additionally, the first base conductive film 355 covering the side surfaces 521 and 522 of the open portion 519a of the second trench 519 is removed through the etching operation. The conductive film 526 is formed by the first base conductive film 355 laminated on the inside of the second insulating film 520. The conductive film 526 includes the first part 526a and the second part 526b. The upper end portion 526c of the first part 526a and the upper end portion 526d of the second part 526b become smaller in thickness in proportion to an approach to the first principal surface 203 because of the etching of the first base conductive film 355.

Next, referring to FIG. 17E, a second base insulating film 356 that serves as a base of the third insulating film 527 is formed on the surface 301 through the first base insulating film 354 and the first base conductive film 355. The second base insulating film 356 may be silicon oxide (SiO2), or may be tetraethyl orthosilicate (TEOS). In this embodiment, the formation of the second base insulating film 356 may be performed by the CVD method.

The formation of the second base insulating film 356 is continuously performed until the open portion 215d of the first trench 215 and the open portion 519a of the second trench 519 are closed. The first base conductive film 355 is formed on the side surfaces 215a and 215b of the first trench 215, and therefore the width of the internal space of the first trench 215 is narrow. Therefore, the open portion 215d of the first trench 215 is completely filled with the second base insulating film 356 before the second base insulating film 356 reaches the halfway portion in the depth direction of the first trench 215 in the first trench 215. In other words, the second base insulating film 356 is formed in the open portion 215d. Hence, a cavity 357 is formed in the internal space of the first trench 215.

Likewise, the first base conductive film 355 is formed on the side surfaces 521 and 522 of the second trench 519, and therefore the width of the internal space of the second trench 519 is comparatively narrow. Therefore, the open portion 519a of the second trench 519 is completely filled with the second base insulating film 356 before the second base insulating film 356 reaches the halfway portion in the depth direction of the second trench 519 in the second trench 519. Hence, the air gap AG7 is formed in the internal space of the second trench 519 (fourth step). As described later, the third insulating film 527 (see FIG. 17H, etc.) is formed by the second base insulating film 356 with which the open portion 519a is filled (fourth step).

Next, referring to FIG. 17F, a third mask 358 is formed on the second base insulating film 356. The first base insulating film 354, the first base conductive film 355, the second base insulating film 356, and the third mask 358 are selectively removed by the etching method, and, as a result, the first base insulating film 354, the first base conductive film 355, the second base insulating film 356, and the third mask 358 become a second hard mask 359. The second hard mask 359 exposes a part which covers the first trench 215 and covers regions other than this part in the surface 301. Next, the second base insulating film 356 is removed from the open portion 215d of the first trench 215 by means of the etching method through the second hard mask 359 (fifth step). Hence, the open portion 215d of the first trench 215 communicates with the cavity 357.

Next, referring to FIG. 17G, a second base conductive film 360 that serves as a base of the buried conductor 217 is formed on the surface 301 through the second hard mask 359. In this embodiment, the second base conductive film 360 includes doped-polysilicon in which a p-type (first conductivity type) impurity has been added. The formation of the second base conductive film 360 may be performed by the CVD method. The formation of the second base conductive film 360 is continuously performed until the first trench 215 is completely filled (sixth step).

Next, referring to FIG. 17H, unnecessary portions of the second base conductive film 360 are removed. This step includes a step of removing the second base conductive film 360, the third mask 358, the second base insulating film 356, the first base conductive film 355, and the first base insulating film 354 by means of the grinding method until the surface 301 is exposed. The grinding method may be the CMP method. In this step, the etching method (wet etching method and/or dry etching method) may be employed instead of the grinding method. The buried conductor 217 is formed by both the first base conductive film 355 and the second base conductive film 360 that remain in the first trench 215. Additionally, the third insulating film 527 is formed by the second base insulating film 356 remaining in the second trench 519.

Subsequent steps are the same as the steps shown in FIG. 14K and FIG. 14L. A description of the steps shown in FIG. 14K and FIG. 14L has already been ended, and therefore a description of these steps is omitted.

Referring to FIG. 17I, unnecessary portions of the fourth base insulating film 312 are removed subsequently to the steps shown in FIG. 14K and FIG. 14L, with reference to FIG. 17I. In this step, the fourth base insulating film 312 is removed by the grinding method until the surface 301 is exposed. The grinding method may be the CMP method. Hence, the first buried insulator 243 is formed by the fourth base insulating film 312 remaining in the first shallow trench 242, and the second buried insulator 248 is formed by the fourth base insulating film 312 remaining in the second shallow trench 247. In other words, the third trench structure 241 and the fourth trench structure 246 are formed. In this step, the etching method (wet etching method and/or dry etching method) may be employed instead of the grinding method.

Additionally, the fifth trench structure 260 is formed at the surface 301 of the semiconductor wafer 300 in parallel with the formation of both the third trench structure 241 and the fourth trench structure 246.

Next, a functional device, such as the MISFET cell 250, is formed on the surface 301 side of the semiconductor wafer 300. Hence, the active region 211 is formed on the surface 301 side of the semiconductor wafer 300. The semiconductor device 1G is formed through these steps including the above.

Advantageously, in the manufacturing process of the semiconductor device 1G, it is possible to make the number of etching steps for forming trenches (the first trench 215 and the second trench 519) smaller than in the manufacturing process of the semiconductor device 1E.

According to the semiconductor device 1G according to the fifth embodiment of the present disclosure, operations and effects equivalent to the operations and effects described in relation to the third embodiment are fulfilled.

According to the semiconductor device 1G according to the fifth embodiment, the following operations and effects are additionally fulfilled. In other words, in this embodiment, the opening 520d is formed in the third part 520c of the second insulating film 520. Therefore, it is possible to escape stress generated in the second insulating film 520 into the opening 520d. Hence, it is possible to more effectively prevent the occurrence of crystal defects in the second insulating film 520.

The embodiments of the present disclosure have been described as above, and yet the present disclosure can be embodied in still other modes.

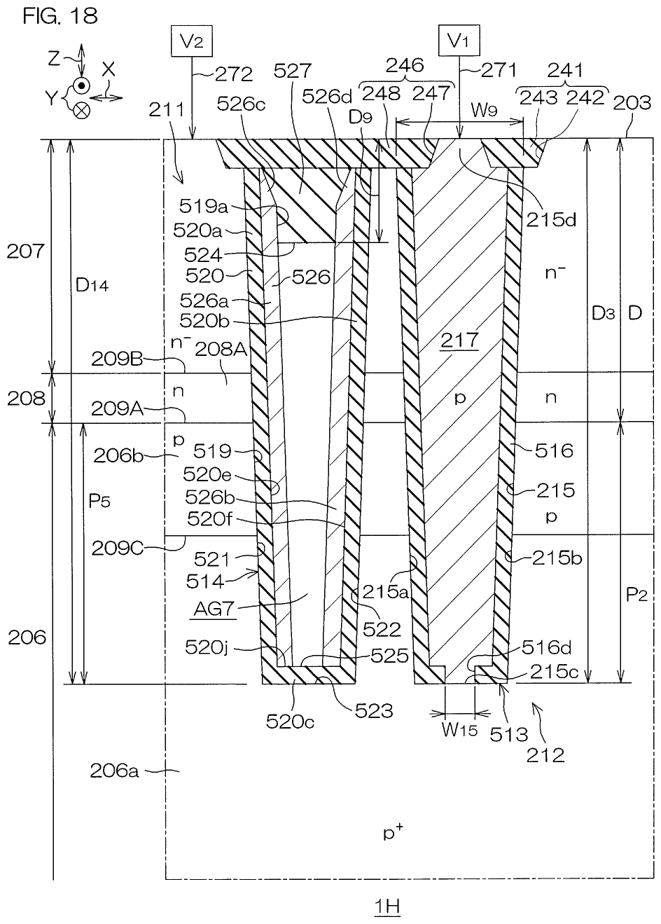

A modification of the fifth embodiment is shown in FIG. 18. FIG. 18 is a view corresponding to FIG. 16. A semiconductor device 1H shown in FIG. 18 differs from the semiconductor device 1G according to the fifth embodiment in the point that the opening 520d is not formed in the third part (bottom portion) 520c of the second insulating film 520. In this case, the whole area of the bottom surface 523 of the second trench 519 is covered by the second insulating film 520. Additionally, the lower end 525 of the air gap AG7 is located on an upper surface (inner surface) 520j of the third part 520c. The upper surface 520j of the third part 520c faces the air gap AG7.

Additionally, the conductive film 526 may be omitted from the second trench structure 514 in the semiconductor devices 1G and 1H.

Additionally, the element isolation portion 212 may demarcate a boundary between a plurality of (for example, two) active regions adjoining each other (the active region 211, and an active region 211/first active region 211A and an active region 211/second active region 211B described as follows), without demarcating the single active region 211 by annularly surrounding this active region 211.

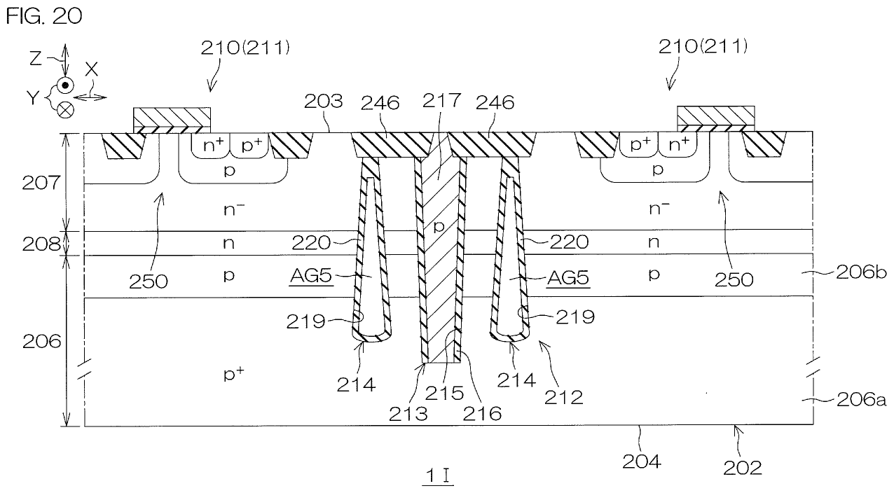

In detail, the element isolation portion 212 that demarcates a boundary between two active regions 211 adjoining each other includes a pair of the second trench structures 214 as in a semiconductor device 1I shown in FIG. 19 and FIG. 20, and this second trench structure 214 may be formed on both sides of the first trench structure 213 one by one. In other words, the second trench 219 may be formed on both sides of the first trench 215. The element isolation portion 212 may be formed in a with-end belt shape. In detail, the element isolation portion 212 may extend linearly. The term “linear” is not limited to a straight line shown in FIG. 19, and may semantically include a curved line.

In this case, the two second trench structures 214 sandwiches the first trench structure 213 in the direction perpendicular to the direction in which the element isolation portion 212 extends in a plan view. The element isolation portion 212 may be configured to include two fourth trench structures 246 without including the third trench structure 241 as shown in FIG. 20. In this case, the two fourth trench structures 246 are formed at positions at which the two fourth trench structures 246 overlap with the second trenches 219 of the two second trench structures 214, respectively, in a plan view. The two fourth trench structures 246 sandwich the buried conductor 217 of the first trench structure 213 in the direction perpendicular to the direction in which the element isolation portion 212 extends in a plan view.

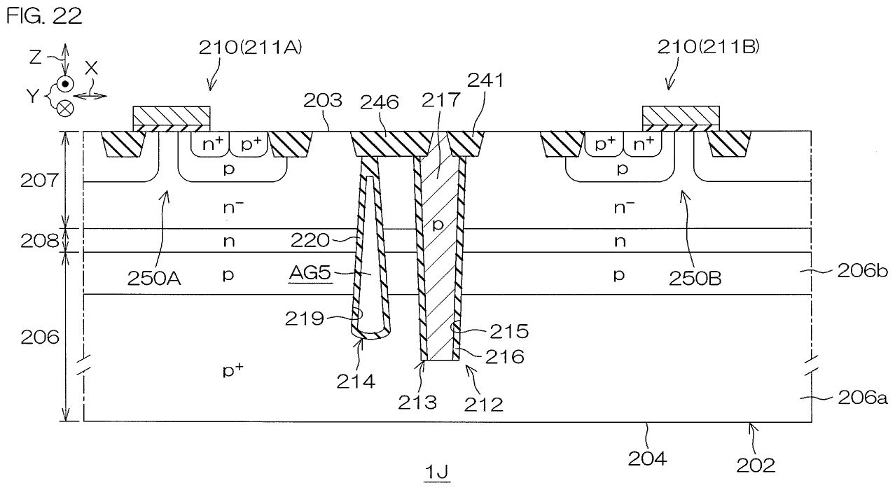

Additionally, the element isolation portion 212 that demarcates a boundary between two active regions adjoining each other (active region 211/first active region 211A and active region 211/second active region 211B) may be configured to include the single first trench structure 213 and the single second trench structure 214 as in a semiconductor device 1J of FIG. 21 and FIG. 22. The two active regions adjoining each other may include the active region 211/first active region 211A in which an element 250A that is high in withstand voltage is formed and the active region 211/second active region 211B in which an element 250B that is lower in withstand voltage than the element 250A is formed. The element 250A and the element 250B may be configured to be equivalent to the MISFET cell 250 (see FIG. 12, etc.). In the example of FIG. 21 and FIG. 22, the second trench structure 214 is formed on the active region 211/first active region 211A side with respect to the first trench structure 213. Additionally, the first trench structure 213 is formed on the active region 211/second active region 211B side with respect to the second trench structure 214. In other words, the second trench 219 is formed on the active region 211/first active region 211A side with respect to the first trench 215, and the first trench 215 is formed on the active region 211/second active region 211B side with respect to the second trench 219.

Additionally, the modifications shown in FIG. 19 to FIG. 22 may be combined with not only the semiconductor device 1E but also the semiconductor devices 1F, 1G, and 1H.

Additionally, for example, a configuration may be employed in which the conductivity type of each semiconductor part of the semiconductor device 1E, 1F, 1G, 1H, 1I, 1J is inverted. For example, a p-type (first conductivity type) part may be n-type, and an n-type (second conductivity type) part may be p-type in the semiconductor device 1E, 1F, 1G, 1H, 1I, 1J.

Characteristics appended below can be extracted from this description and from the drawings.

### Appendix 1-1

A semiconductor device (1, 1B, 1C, 1D) comprising:
a semiconductor chip (2) that has a first principal surface (3) and a second principal surface (4); and
an element isolation portion (12) that is formed on the side of the first principal surface (3) of the semiconductor chip (2) and that demarcates an active region (11),
the element isolation portion (12) comprising:
a trench (16, 115) formed on the side of the first principal surface (3) of the semiconductor chip (2);
a first insulating film (41, 51, 123, 127) formed on a side surface (21, 22, 118, 119) of the trench (16, 115);
a second insulating film (42, 52, 242, 252) formed inside the trench (16, 115) such that an air gap (AG1, AG2, AG3, AG4) is sandwiched between the first insulating film (41, 51, 123, 127) and the second insulating film (42, 52, 242, 252); and
a buried conductor (17) that is covered by the second insulating film (42, 52) and that is connected to the semiconductor chip (2) at a bottom portion (23, 120) of the trench (16, 115).

With this configuration, the element isolation portion (12) includes the trench (16, 115) and the buried conductor (17) buried in the trench (16, 115). In the trench (16, 115), the first insulating film (41, 51, 123, 127) formed on the side surface (21, 22, 118, 119) of the trench (16, 115) and the second insulating film (42, 52) covering the buried conductor (17) are formed with the air gap (AG1, AG2, AG3, AG4) between the first insulating film (41, 51, 123, 127) and the second insulating film (42, 52). This makes it possible to electrically excellently insulate the buried conductor (17) from the active region (11) by means of the first insulating film (41, 51, 123, 127) and the second insulating film (42, 52). Therefore, it is possible to improve the withstand voltage in the lateral direction along the first principal surface (3) of the semiconductor chip (2).

### Appendix 1-2

The semiconductor device (1, 1B, 1C, 1D) according to Appendix 1-1, wherein the side surface (21, 22, 118, 119) of the trench (16, 115) is formed in a shape in which a halfway portion in a depth direction (Z) of the trench (16, 115) is convex more outwardly from the trench (16, 115) than an open end (21a, 22a, 118a, 119a) of the trench (16, 115) in a cross-sectional view.

### Appendix 1-3

The semiconductor device (1, 1C, 1D) according to Appendix 1-2, wherein the side surface (21, 22) of the trench (16) is formed in a tapered shape whose width becomes smaller from the bottom portion (23) of the trench (16) toward the first principal surface (3) in a cross-sectional view.

### Appendix 1-4

The semiconductor device (1B, 1C, 1D) according to Appendix 1-2, wherein the side surface (118, 119) of the trench (115) is formed in an arched shape that is convex outwardly from the trench (115) in a cross-sectional view.

### Appendix 1-5

The semiconductor device (1, 1B, 1C, 1D) according to any one of Appendix 1-1 to Appendix 1-4, wherein the buried conductor (17) has a tapered sidewall (36, 37) whose width becomes larger from a bottom wall (38) of the buried conductor (17) toward the first principal surface (3) in a cross-sectional view, and
the second insulating film (42, 52) is contiguous to the sidewall (36, 37) of the buried conductor (17).

### Appendix 1-6

The semiconductor device (1, 1B, 1C, 1D) according to any one of Appendix 1-1 to Appendix 1-5, wherein the semiconductor chip (2) includes a first-conductivity-type first impurity region (6) that is formed on the side of the second principal surface (4) and to which the buried conductor (17) is connected at the bottom portion (23, 120) of the trench (16, 115), a second-conductivity-type second impurity region (7) formed on the side of the first principal surface (3), and a second-conductivity-type buried region (8) that is buried between the first impurity region (6) and the second impurity region (7), and
the air gap (AG1, AG2, AG3, AG4) is sandwiched between the buried region (8) and the buried conductor (17) in a lateral direction along the first principal surface (3).

### Appendix 1-7

The semiconductor device (1B, 1C, 1D) according to Appendix 1-6, wherein the side surface (118, 119) of the trench (115) is formed in an arched shape that is convex outwardly from the trench (115) in a cross-sectional view, and a top portion (118p, 119p) of the side surface (118, 119) having the arched shape is sandwiched between the buried region (8) and the buried conductor (17).

### Appendix 1-8

The semiconductor device (1, 1B, 1C, 1D) according to any one of Appendix 1-1 to Appendix 1-7, wherein the first insulating film (41, 51, 123, 127) is formed on both the side surface (21, 118) on one side of the trench (16, 115) and the side surface (22, 119) on one other side of the trench (16, 115), and
the air gap (AG1, AG2, AG3, AG4) is formed both between the buried conductor (17) and the side surface (21, 118) on the one side of the trench (16, 115) and between the buried conductor (17) and the side surface (22, 119) on the one other side of the trench (16, 115).

### Appendix 1-9

The semiconductor device (1, 1B, 1C, 1D) according to any one of Appendix 1-1 to Appendix 1-8, wherein the first insulating film (41, 51, 123, 127) and the second insulating film (42, 52) are connected in an upper portion (16a, 115a) of the trench (16, 115), and are not connected in a halfway portion in a depth direction (Z) of the trench (16, 115).

### Appendix 1-10

The semiconductor device (1, 1B, 1D) according to any one of Appendix 1-1 to Appendix 1-9, wherein the buried conductor (17) includes a protruding portion (17b) that protrudes toward the side of the second principal surface (4) than the second insulating film (42, 52), and
the air gap (AG1, AG2, AG3, AG4) is located closer to the side of the first principal surface (3) than a bottom wall (38) of the protruding portion (17b) with regard to a depth direction (Z) of the trench (16, 115).

### Appendix 1-11

The semiconductor device (1C) according to any one of Appendix 1-1 to Appendix 1-9, wherein the bottom wall (38) of the buried conductor (17) is located closer to the side of the first principal surface (3) than a lower end (42a, 52a) of the second insulating film (42, 52) and than a lower end (49, 59, 132, 131) of the air gap (AG1, AG2, AG3, AG4) with regard to a depth direction (Z) of the trench (16, 115).

### Appendix 1-12

A method of manufacturing a semiconductor device (1, 1B, 1C, 1D), the method comprising:
a first step of forming a first trench (105) in a surface (101) of a semiconductor wafer (100) so as to demarcate an active region (11);
a second step of burying a buried conductor (17) in the first trench (105);
a third step of forming a second trench (109, 110, 133, 134) having a first side surface (109a, 110a, 133a, 134a) formed by the buried conductor (17) and a second side surface (109b, 110b, 133b, 134b) formed by a part of the semiconductor wafer (100) on a lateral side of the buried conductor (17) so as to inwardly expose a sidewall (36, 37) of the buried conductor (17); and
a fourth step of forming a first insulating film (41, 51, 123, 127) and a second insulating film (42, 52) on the first side surface (109a, 110a, 133a, 134a) and the second side surface (109b, 110b, 133b, 134b), respectively, so as to face each other across an air gap (AG1, AG2, AG3, AG4) formed by an internal space of the second trench (109, 110, 133, 134).

### Appendix 1-13

The method of manufacturing a semiconductor device (1, 1C, 1D) according to Appendix 1-12, wherein the third step includes a step of forming the second side surface (109b, 110b) of the second trench (109, 110) as an inclined surface with respect to the surface (101) of the semiconductor wafer (100) so that the air gap (AG1, AG2) is formed in a tapered shape whose width becomes smaller from a bottom portion (109c, 110c) of the second trench (109, 110) toward the surface (101) of the semiconductor wafer (100) in a cross-sectional view.

### Appendix 1-14

The method of manufacturing a semiconductor device (1B, 1C, 1D) according to Appendix 1-12, wherein the third step includes a step of forming the second side surface (133b, 134b) of the second trench (133, 134) in an arched shape that is convex toward a side opposite to a side of the buried conductor (17) in a cross-sectional view.

### Appendix 1-15

The method of manufacturing a semiconductor device (1, 1B, 1C, 1D) according to any one of Appendix 1-12 to Appendix 1-14, wherein the third step includes a step of forming the second trench (109, 110, 133, 134) at a shallower depth than the first trench (105).

### Appendix 2-1

A semiconductor device (1E, 1F, 1G, 1H, 1I, 1J) comprising:
a semiconductor chip (202) that has a first principal surface (203) and a second principal surface (204); and
an element isolation portion (212) that is formed on the side of the first principal surface (203) of the semiconductor chip (202) and that demarcates an active region (211, 211A, 211B),
the element isolation portion (212) comprising:
a first trench (215) formed in the semiconductor chip (202);
a first insulating film (216, 516) formed on an inner surface (215a, 215b) of the first trench (215);
a buried conductor (217) that is buried in the first trench (215) and that is connected to the semiconductor chip (202) at a bottom portion (215c) of the first trench (215);
a second trench (219, 419, 519) formed such that the second trench (219, 419, 519) is adjacent to the first trench (215) on a side of the active region (211, 211A, 211B) with respect to the first trench (215); and
a second insulating film (220, 420, 520) formed on an inner surface (221, 222, 223, 421, 422, 423, 521, 522, 523) of the second trench (219, 419, 519) such that a hollow air gap (AG5, AG6, AG7) is formed inside the second trench (219, 419, 519).

With this configuration, in the element isolation portion (212), the second trench (219, 419, 519) is formed on the active region (211, 211A, 211B) side of the first trench (215) adjacently to the first trench (215) in which the buried conductor (217) is buried. The hollow air gap (AG5, AG6, AG7) is formed inside the second trench (219, 419, 519) by means of the second insulating film (220, 420, 520) formed on the inner surface (221, 222, 223, 421, 422, 423, 521, 522, 523) of the second trench (219, 419, 519). The buried conductor (217) is electrically insulated from the active region (211, 211A, 211B) by means of the air gap (AG5, AG6, AG7) formed on the active region (211, 211A, 211B) side with respect to the buried conductor (217) and the second insulating film (220, 420, 520). This makes it possible to electrically excellently insulate the buried conductor (217) from the active region (211, 211A, 211B). Therefore, it is possible to improve the withstand voltage in the lateral direction along the first principal surface (203) of the semiconductor chip (202).

### Appendix 2-2

The semiconductor device (1E, 1F, 1I, 1J) according to Appendix 2-1, wherein the second trench (219, 419) is formed so that a halfway portion in a depth direction (Z) of the second trench (219, 419) becomes convex more outwardly from the second trench (219, 419) than an open end (221a, 222a, 421a, 422a) of the second trench (219, 419) in a cross-sectional view.

### Appendix 2-3

The semiconductor device (1E, 1I, 1J) according to Appendix 2-2, wherein the second trench (219) is formed in a tapered shape whose width becomes smaller from a bottom portion (223) of the second trench (219) toward the first principal surface (203) in a cross-sectional view.

### Appendix 2-4

The semiconductor device (1F, 1I, 1J) according to Appendix 2-2, wherein a side surface (421, 422) of the second trench (419) is formed in an arched shape that is convex outwardly from the second trench (419) in a cross-sectional view.

### Appendix 2-5

The semiconductor device (1E, 1F, 11, 1J) according to any one of Appendix 2-2 to Appendix 2-4, wherein the second trench (219, 419) has a depth (D₄, D₆) differing from a depth of the first trench (215).

### Appendix 2-6

The semiconductor device (1G, 1H, 1I, 1J) according to Appendix 2-1, further comprising a conductive film (526) formed on an inner surface (520e, 520f, 520g, 520h, 520j) facing the air gap (AG7) in the second insulating film (520).

### Appendix 2-7

The semiconductor device (1G, 1H, 1I, 1J) according to Appendix 2-6, further comprising a third insulating film (527) covering the second insulating film (520) and the conductive film (526) in a position in which the third insulating film (527) faces an upper portion of the air gap (AG7) in the second trench (519).

### Appendix 2-8

The semiconductor device (1G, 1I, 1J) according to Appendix 2-6 or Appendix 2-7, wherein an opening (520d) is formed in a bottom portion (520c) of the second insulating film (520).

### Appendix 2-9

The semiconductor device (1G, 1H, 1I, 1J) according to any one of Appendix 2-6 to Appendix 2-8, wherein the second trench (519) has a same depth (D₈) as the first trench (215).

### Appendix 2-10

The semiconductor device (1G, 1H, 1I, 1J) according to any one of Appendix 2-6 to Appendix 2-9, wherein the second trench (519) has a same shape as the first trench (215) in a cross-sectional view.

### Appendix 2-11

The semiconductor device (1E, 1F, 1G, 1H, 1I, 1J) according to any one of Appendix 2-1 to Appendix 2-10, wherein the semiconductor chip (202) includes a first-conductivity-type first impurity region (206) that is formed on the side of the second principal surface (204) and that to which the buried conductor (217) is connected at the bottom portion (215c) of the first trench (215), a second-conductivity-type second impurity region (207) formed on the side of the first principal surface (203), and a second-conductivity-type buried region (208) buried between the first impurity region (206) and the second impurity region (207), and
wherein the air gap (AG5, AG6, AG7) is sandwiched between the buried region (208) and the buried conductor (217) in the lateral direction along the first principal surface (203).

### Appendix 2-12

The semiconductor device (1J) according to any one of Appendix 2-1 to Appendix 2-11, wherein the active region (211A, 211B) includes a first active region (211A) in which an element (250A) that is relatively high in withstand voltage and a second active region (211B) that is an active region adjoining the first active region (211A) and in which an element (250B) that is relatively low in withstand voltage is formed, and
wherein the second trench (219, 419, 519) is formed on a side of the first active region (211A) with respect to the first trench (215), and the first trench (215) is formed on a side of the second active region (211B) with respect to the second trench (219, 419, 519).

### Appendix 2-13

The semiconductor device (1I) according to any one of Appendix 2-1 to Appendix 2-12, wherein the second trench (219, 419, 519) includes a pair of second trenches (219, 419, 519) formed on both sides of the first trench (215).

### Appendix 2-14

A method of manufacturing a semiconductor device (1E, 1F, 1I, 1J), the method comprising a step of forming an element isolation portion (212) that includes a first trench (215) and a second trench (219, 419) that demarcate an active region (211) in a surface (301) of a semiconductor wafer (300),
the step of forming the element isolation portion (212) comprising:
a first step of forming the second trench (219, 419) in the semiconductor wafer (300);
a second step of forming a hollow air gap (AG5, AG6) inside the second trench (219, 419) by forming a second insulating film (220, 420) on an inner surface (221, 222, 223, 421, 422, 423) of the second trench (219, 419);
a third step of forming a first trench (215) adjacent to the second trench (219, 419, 519) on a side opposite to the active region (211) with respect to the second trench (219, 419, 519);
a fourth step of forming a first insulating film (216) on an inner surface (215a, 215b) of the first trench (215); and
a fifth step of burying a buried conductor (217) in an inside of the first insulating film (216) in the first trench (215).

### Appendix 2-15

A method of manufacturing a semiconductor device (1G, 1H, 1I, 1J), the method comprising:
a first step of forming a first trench (215) and a second trench (519) adjacent to the first trench (215) so as to demarcate an active region (211) in a surface (301) of a semiconductor wafer (300);
a second step of forming a first insulating film (516) and a second insulating film (520) on an inner surface (215a, 215b, 215c) of the first trench (215) and an inner surface (521, 522, 523) of the second trench (519), respectively;
a third step of laminating and a first base conductive film (355) and a conductive film (526) on an inside of the first insulating film (516) and an inside of the second insulating film (520), respectively;
a fourth step of forming a hollow air gap (AG7) in an internal space of the second trench (519) by sealing an open portion (519a) of the second trench (519) with a third insulating film (527) and of sealing an open portion (215d) of the first trench (215) with a base insulating film (356);
a fifth step of removing the base insulating film (356) from the first trench (215); and
a sixth step of burying the second base conductive film (360) in an inside of the first base conductive film (355) in the first trench (215).

What is claimed is:

1. A semiconductor device comprising:
a semiconductor chip that has a first principal surface and a second principal surface; and
an element isolation portion that is formed on the side of the first principal surface of the semiconductor chip and that demarcates an active region,
the element isolation portion comprising:
a trench formed on the side of the first principal surface of the semiconductor chip;
a first insulating film formed on a side surface of the trench;
a second insulating film formed inside the trench such that an air gap is sandwiched between the first insulating film and the second insulating film; and
a buried conductor that is covered by the second insulating film and that is connected to the semiconductor chip at a bottom portion of the trench.

2. The semiconductor device according to claim 1, wherein the side surface of the trench is formed in a shape in which a halfway portion in a depth direction of the trench is convex more outwardly from the trench than an open end of the trench in a cross-sectional view.

3. The semiconductor device according to claim 2, wherein the side surface of the trench is formed in a tapered shape whose width becomes smaller from the bottom portion of the trench toward the first principal surface in a cross-sectional view.

4. The semiconductor device according to claim 2, wherein the side surface of the trench is formed in an arched shape that is convex outwardly from the trench in a cross-sectional view.

5. The semiconductor device according to claim 1, wherein the buried conductor has a tapered sidewall whose width becomes larger from a bottom wall of the buried conductor toward the first principal surface in a cross-sectional view, and
the second insulating film is contiguous to the sidewall of the buried conductor.

6. The semiconductor device according to claim 1, wherein the semiconductor chip includes a first-conductivity-type first impurity region that is formed on the side of the second principal surface and to which the buried conductor is connected at the bottom portion of the trench, a second-conductivity-type second impurity region formed on the side of the first principal surface, and a second-conductivity-type buried region that is buried between the first impurity region and the second impurity region, and
the air gap is sandwiched between the buried region and the buried conductor in a lateral direction along the first principal surface.

7. The semiconductor device according to claim 6, wherein the side surface of the trench is formed in an arched shape that is convex outwardly from the trench in a cross-sectional view, and
a top portion of the side surface having the arched shape is sandwiched between the buried region and the buried conductor.

8. The semiconductor device according to claim 1, wherein the first insulating film is formed on both the side surface on one side of the trench and the side surface on one other side of the trench, and
the air gap is formed both between the buried conductor and the side surface on the one side of the trench and between the buried conductor and the side surface on the one other side of the trench.

9. The semiconductor device according to claim 1, wherein the first insulating film and the second insulating film are connected in an upper portion of the trench, and are not connected in a halfway portion in a depth direction of the trench.

10. The semiconductor device according to claim 1, wherein the buried conductor includes a protruding portion that protrudes toward the side of the second principal surface than the second insulating film, and
the air gap is located closer to the side of the first principal surface than a bottom wall of the protruding portion with regard to a depth direction of the trench.

11. The semiconductor device according to claim 1, wherein the bottom wall of the buried conductor is located closer to the side of the first principal surface than a lower end of the second insulating film and than a lower end of the air gap with regard to a depth direction of the trench.

12. A method of manufacturing a semiconductor device, the method comprising:
a first step of forming a first trench in a surface of a semiconductor wafer so as to demarcate an active region;
a second step of burying a buried conductor in the first trench;
a third step of forming a second trench having a first side surface formed by the buried conductor and a second side surface formed by a part of the semiconductor wafer on a lateral side of the buried conductor so as to inwardly expose a sidewall of the buried conductor; and
a fourth step of forming a first insulating film and a second insulating film on the first side surface and the second side surface, respectively, so as to face each other across an air gap formed by an internal space of the second trench.

13. The method of manufacturing a semiconductor device according to claim 12, wherein the third step includes a step of forming the second side surface of the second trench as an inclined surface with respect to the surface of the semiconductor wafer so that the air gap is formed in a tapered shape whose width becomes smaller from a bottom portion of the second trench toward the surface of the semiconductor wafer in a cross-sectional view.

14. The method of manufacturing a semiconductor device according to claim 12, wherein the third step includes a step of forming the second side surface of the second trench in an arched shape that is convex toward a side opposite to a side of the buried conductor in a cross-sectional view.

15. The method of manufacturing a semiconductor device according to claim 12, wherein the third step includes a step of forming the second trench at a shallower depth than the first trench.
